(19) United States
(12) Patent Application Publication
(10) Pub. No.: US 2024/0168382 A1
(43) Pub. Date: May 23, 2024

(54) RESIST COMPOSITION AND PATTERN FORMING PROCESS

(71) Applicant: Shin-Etsu Chemical Co., Ltd., Tokyo (JP)

(72) Inventors: Jun Hatakeyama, Joetsu-shi (JP); Tatsuya Yamahira, Joetsu-shi (JP); Yuki Suda, Joetsu-shi (JP)

(73) Assignee: Shin-Etsu Chemical Co., Ltd., Tokyo (JP)

(21) Appl. No.: 18/370,578

(22) Filed: Sep. 20, 2023

(30) Foreign Application Priority Data
Oct. 7, 2022 (JP) 2022-162323

(51) Int. Cl. G03F 7/039; C08F 212/14; C08F 220/18; C08F 220/22

(52) U.S. Cl. CPC G03F 7/0392; C08F 212/24; C08F 220/1806; C08F 220/22

(57) ABSTRACT

A resist composition comprising a base polymer comprising repeat units having a salt structure consisting of a sulfonic acid anion bonded to a polymer backbone and a sulfonium cation having formula (1).

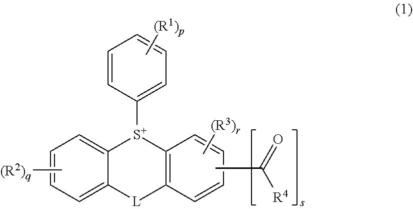

### CROSS-REFERENCE TO RELATED APPLICATIONS

This non-provisional application claims priority under 35 U.S.C. § 119(a) on Patent Application No. 2022-162323 filed in Japan on Oct. 7, 2022, the entire contents of which are hereby incorporated by reference.

### TECHNICAL FIELD

This invention relates to a resist composition and a pattern forming process.

### BACKGROUND ART

To meet the demand for higher integration density and operating speed of LSIs, the effort to reduce the pattern rule is in rapid progress. As the use of 5G high-speed communications and artificial intelligence (AI) is widely spreading, high-performance devices are needed for their processing. As the most advanced miniaturization technology, mass production of 5-nm node devices by extreme ultraviolet (EUV) lithography having a wavelength of 13.5 nm is performed. Studies are made on the application of EUV lithography to 3-nm node devices of the next generation and 2-nm node devices of the next-but-one generation. IMEC in Belgium announced its successful development of 1-nm and 0.7-nm node devices.

As the feature size reduces, image blurs due to acid diffusion become a problem. To ensure resolution for fine patterns of sub-45-nm size, not only an improvement in dissolution contrast is important as previously reported, but the control of acid diffusion is also important as reported in Non-Patent Document 1. Since chemically amplified resist compositions are designed such that sensitivity and contrast are enhanced by acid diffusion, an attempt to minimize acid diffusion by reducing the temperature and/or time of post exposure bake (PEB) fails, resulting in drastic reductions of sensitivity and contrast.

A triangular tradeoff relationship among sensitivity, resolution, and edge roughness (LWR) has been pointed out. Specifically, a resolution improvement requires to suppress acid diffusion whereas a short acid diffusion distance leads to a decline of sensitivity.

The addition of an acid generator capable of generating a bulky acid is an effective means for suppressing acid diffusion. It was then proposed to incorporate a repeat unit derived from an onium salt having a polymerizable unsaturated bond in a polymer. Since this polymer functions as an acid generator, it is referred to as polymer-bound acid generator. Patent Document 1 discloses a sulfonium or iodonium salt having a polymerizable unsaturated bond, capable of generating a specific sulfonic acid. Patent Document 2 discloses a sulfonium salt having a sulfonic acid directly attached to the backbone.

Patent Documents 3 to 5 propose a resist composition to which a sulfonium salt having a phenyldibenzothiophenium cation capable of generating a specific fluorosulfonic acid is added. The phenyldibenzothiophenium cation has high decomposition efficiency due to ring distortion and high acid diffusion controlling ability due to the ring structure. However, acquisition of properties of higher sensitivity and lower acid diffusion requires properties of higher decomposition efficiency and lower acid diffusion.

### CITATION LIST

Patent Document 1: JP-A 2006-45311
Patent Document 2: JP-A 2006-178317
Patent Document 3: JP-A 2020-75919
Patent Document 4: JP-A 2021-35935
Patent Document 5: JP-A 2021-35936
Non-Patent Document 1: SPIE Vol. 6520 65203L-1 (2007)

### SUMMARY OF THE INVENTION

For resist compositions, it is desired to have an acid generator capable of improving the LWR of line patterns or the critical dimension uniformity (CDU) of hole patterns and enhancing sensitivity. For this purpose, it is necessary to have high decomposition efficiency in exposure, suppress acid diffusion, and have high affinity to an alkaline developer.

An object of the present invention is to provide a resist composition, especially a positive resist composition which exhibits a high sensitivity and improved LWR or CDU, and a pattern forming process using the resist composition.

The inventors have found that use of a base polymer comprising repeat units having a salt structure consisting of a sulfonic acid anion bonded to a polymer backbone and a sulfonium cation having a specific structure having a hydrocarbylcarbonyl group or a hydrocarbyloxycarbonyl group provides high decomposition efficiency by exposure due to electron withdrawing properties of the hydrocarbylcarbonyl group or the hydrocarbyloxycarbonyl group, and at the same time, can suppress acid diffusion, and provides high affinity to an alkaline developer, so that properties of high sensitivity, low acid diffusion, high contrast, and low swell can be obtained, whereby a resist composition having improved LWR and CDU, high sensitivity, excellent resolution, and a wide process margin can be obtained.

Specifically, the present invention provides the following resist composition and pattern forming process.

In one aspect, the invention provides a resist composition comprising a base polymer comprising repeat units (a) having a salt structure consisting of a sulfonic acid anion bonded to a polymer backbone and a sulfonium cation having formula (1).

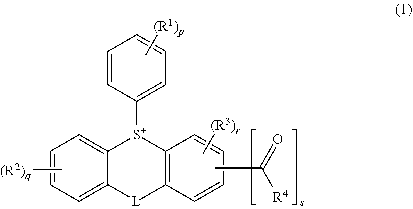

Herein p, q, and r are each independently an integer of 0 to 3, and s is 1 or 2, provided that 1≤r+s≤3.
R¹ and R² are each independently a halogen atom, a trifluoromethyl group, a trifluoromethoxy group, a trifluoromethylthio group, a nitro group, a cyano group, —C(═O)—R⁴, —O—C(═O)—R⁵, or —O—R⁵.
R³ is a halogen atom, a trifluoromethyl group, a trifluoromethoxy group, a trifluoromethylthio group, a nitro group, a cyano group, —O—C(═O)—R⁵, or —O—R⁵.
R⁴ is a C₁-C₁₀ hydrocarbyl group, a C₁-C₁₀ hydrocarbyloxy group, or —O—R^{4A}, and the hydrocarbyl group and the hydrocarbyloxy group may be substituted by a fluorine atom or a hydroxy group. R^{4A} is an acid labile group.
R⁵ is a C₁-C₁₀ hydrocarbyl group.
L is a single bond, an ether bond, a carbonyl group, —N(R)—, a sulfide bond, or a sulfonyl group. R is a hydrogen atom or a C₁-C₆ saturated hydrocarbyl group.

In a preferred embodiment, the repeat units (a) have formula (a1) or (a2).

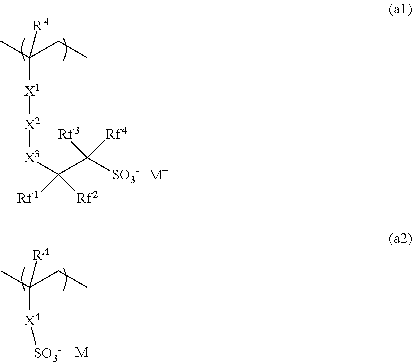

Herein R^{A} is each independently a hydrogen atom or a methyl group.
X¹ is a single bond or an ester bond.
X² is a single bond, —X²¹—C(═O)—O—, or —X²¹—O—. X²¹ is a C₁-C₁₂ hydrocarbylene group, a phenylene group, or a C₇-C₁₈ group obtained by combining the foregoing, which may contain a carbonyl group, a nitro group, a cyano group, an ester bond, an ether bond, a urethane bond, a fluorine atom, an iodine atom, or a bromine atom.
X³ is a single bond, a methylene group, or an ethylene group.
X⁴ is a single bond, a methylene group, an ethylene group, a phenylene group, a methylphenylene group, a dimethylphenylene group, a fluorinated phenylene group, a phenylene group substituted by a trifluoromethyl group, —O—X⁴¹—, —C(═O)—O—X⁴¹—, or —C(═O)—NH—X⁴¹—. X⁴¹ is a C₁-C₆ aliphatic hydrocarbylene group, a phenylene group, a methylphenylene group, a dimethylphenylene group, a fluorinated phenylene group, or a phenylene group substituted by a trifluoromethyl group, and may contain a carbonyl group, an ester bond, an ether bond, a hydroxy group, or a halogen atom.
Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf² may together form a carbonyl group.
M⁺ is a sulfonium cation having formula (1).

In a preferred embodiment, the base polymer further comprises repeat units having formula (b1) or repeat units having formula (b2).

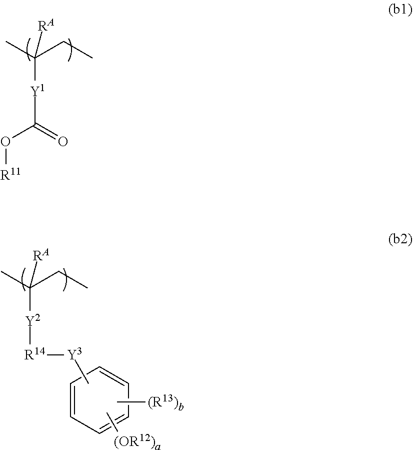

Herein R^{A} is each independently a hydrogen atom or a methyl group.
Y¹ is a single bond, a phenylene group, a naphthylene group, or a C₁-C₁₂ linking group containing at least one moiety selected from an ester bond, an ether bond, and a lactone ring.
Y² is a single bond or an ester bond.
Y³ is a single bond, an ether bond, or an ester bond.
R¹¹ and R¹² are each independently an acid labile group.
R³ is a fluorine atom, a trifluoromethyl group, a cyano group, a C₁-C₆ saturated hydrocarbyl group, a C₁-C₆ saturated hydrocarbyloxy group, a C₂-C₇ saturated hydrocarbylcarbonyl group, a C₂-C₇ saturated hydrocarbylcarbonyloxy group, or a C₂-C₇ saturated hydrocarbyloxycarbonyl group.
R¹⁴ is a single bond or a C₁-C₆ alkanediyl group in which some constituent —CH₂— may be substituted by an ether bond or an ester bond.
a is 1 or 2, b is an integer of 0 to 4, provided that 1≤a+b≤5.

The resist composition is typically a chemically amplified positive resist composition.

The resist composition may further comprise an organic solvent.

The resist composition may further comprise a surfactant.

In another aspect, the invention provides a pattern forming process comprising the steps of applying the resist composition defined herein onto a substrate to form a resist film thereon, exposing the resist film to high-energy radiation, and developing the exposed resist film in a developer.

Typically, the high-energy radiation is KrF excimer laser, ArF excimer laser, electron beam (EB), or EUV with a wavelength of 3 to 15 nm.

### Advantageous Effects of the Invention

In the resist composition comprising a base polymer comprising repeat units (a), when the base polymer further contains an acid labile group, an acid is generated upon exposure, and a polarity switch occurs due to the acid-catalyzed reaction whereby the alkali dissolution rate is increased. In the unexposed region, the repeat unit (a) itself is not dissolved in the developer. In the exposed region, a carboxy group is generated under the action of the acid generated by the repeat unit (a) whereby the alkali dissolution rate is increased. Accordingly, a resist composition having improved LWR or CDU is constructed.

### DETAILED DESCRIPTION OF THE INVENTION

Resist Composition

The resist composition of the invention comprises a base polymer comprising repeat units (a) having a salt structure consisting of a sulfonic acid anion bonded to a polymer backbone and a sulfonium cation having a specific structure having a hydrocarbylcarbonyl group or a hydrocarbyloxycarbonyl group. Since the repeat unit (a) functions as an acid generator, the base polymer is a polymer-bound acid generator.

Base Polymer

The sulfonium cation contained in the repeat units (a) is represented by formula (1).

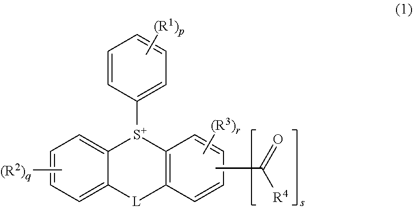

In formula (1), p, q, and r are each independently an integer of 0 to 3, and s is 1 or 2, provided that 1≤r+s≤3.

In formula (1), R¹ and R² are each independently a halogen atom, a trifluoromethyl group, a trifluoromethoxy group, a trifluoromethylthio group, a nitro group, a cyano group, —C(═O)—R⁴, —O—C(═O)—R⁵, or —O—R⁵.

In formula (1), R³ is a halogen atom, a trifluoromethyl group, a trifluoromethoxy group, a trifluoromethylthio group, a nitro group, a cyano group, —O—C(═O)—R⁵, or —O—R⁵.

In formula (1), R⁴ is a C₁-C₁₀ hydrocarbyl group, a C₁-C₁₀ hydrocarbyloxy group, or —O—R^{4A}, and the hydrocarbyl group and the hydrocarbyloxy group may be substituted by a fluorine atom or a hydroxy group. R^{4A} is an acid labile group.

In formula (1), R⁵ is a C₁-C₁₀ hydrocarbyl group.

The hydrocarbyl group represented by R⁴ and R⁵ and the hydrocarbyl moiety of the hydrocarbyloxy group represented by R⁴ may be saturated or unsaturated, and straight, branched, or cyclic. Specific examples thereof include C₁-C₁₀ alkyl groups such as a methyl group, an ethyl group, a n-propyl group, an isopropyl group, a n-butyl group, an isobutyl group, a sec-butyl group, a tert-butyl group, a n-pentyl group, an isopentyl group, a sec-pentyl group, a 3-pentyl group, a tert-pentyl group, a neopentyl group, a n-hexyl group, a n-octyl group, a n-nonyl group, and a n-decyl group; C₃-C₁₀ cyclic saturated hydrocarbyl groups such as a cyclopropyl group, a cyclobutyl group, a cyclopentyl group, a cyclohexyl group, an adamantyl group, a norbornyl group, a cyclopropylmethyl group, a cyclopropylethyl group, a cyclobutylmethyl group, a cyclobutylethyl group, a cyclopentylmethyl group, a cyclopentylethyl group, a cyclohexylmethyl group, a cyclohexylethyl group, a methylcyclopropyl group, a methylcyclobutyl group, a methylcyclopentyl group, a methylcyclohexyl group, an ethylcyclopropyl group, an ethylcyclobutyl group, an ethylcyclopentyl group, and an ethylcyclohexyl group; C₂-C₁₀ alkenyl groups such as a vinyl group, a 1-propenyl group, a 2-propenyl group, a butenyl group, a pentenyl group, a hexenyl group, a heptenyl group, a nonenyl group, and a decenyl group; C₂-C₁₀ alkynyl groups such as an ethynyl group, a propynyl group, a butynyl group, a pentynyl group, a hexynyl group, a heptynyl group, an octinyl group, a nonynyl group, and a decynyl group; C₃-C₁₀ cyclic unsaturated aliphatic hydrocarbyl groups such as a cyclopentenyl group, a cyclohexenyl group, a methylcyclopentenyl group, a methylcyclohexenyl group, an ethylcyclopentenyl group, an ethylcyclohexenyl group, and a norbornenyl group; C₆-C₁₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, and a naphthyl group; C₇-C₁₀ aralkyl groups such as a benzyl group, a phenethyl group, a phenylpropyl group, and a phenylbutyl group; and groups obtained by combining these groups.

Examples of the acid labile group represented by R^{4A} include acid labile groups having formulae (AL-1) to (AL-3) described later.

In formula (1), L is a single bond, an ether bond, a carbonyl group, —N(R)—, a sulfide bond, or a sulfonyl group. R is a hydrogen atom or a C₁-C₆ saturated hydrocarbyl group.

Examples of the sulfonium cation having formula (1) are shown below, but not limited thereto.

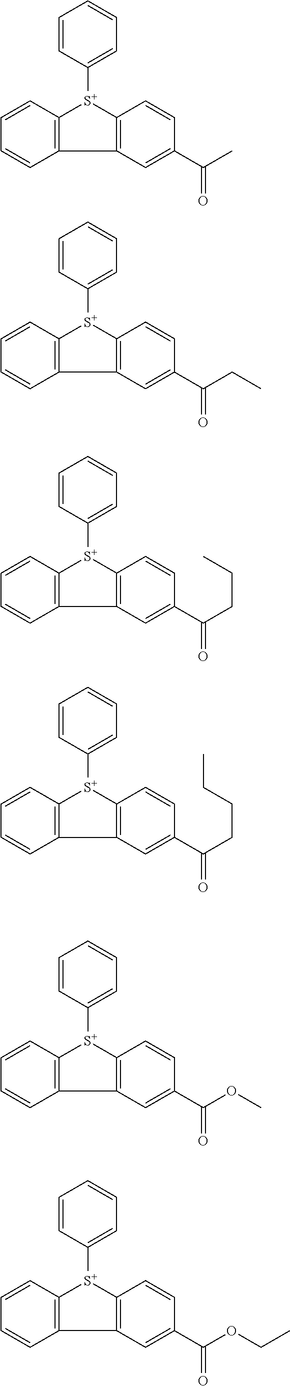 [SMILES: CC(=O)c1ccc2c(c1)c1ccccc1[s+]2-c1ccccc1 ; CCC(=O)c1ccc2c(c1)c1ccccc1[s+]2-c1ccccc1 ; CCCC(=O)c1ccc2c(c1)c1ccccc1[s+]2-c1ccccc1 ; CCCCC(=O)c1ccc2c(c1)c1ccccc1[s+]2-c1ccccc1 ; COC(=O)c1ccc2c(c1)c1ccccc1[s+]2-c1ccccc1 ; CCOC(=O)c1ccc2c(c1)c1ccccc1[s+]2-c1ccccc1]

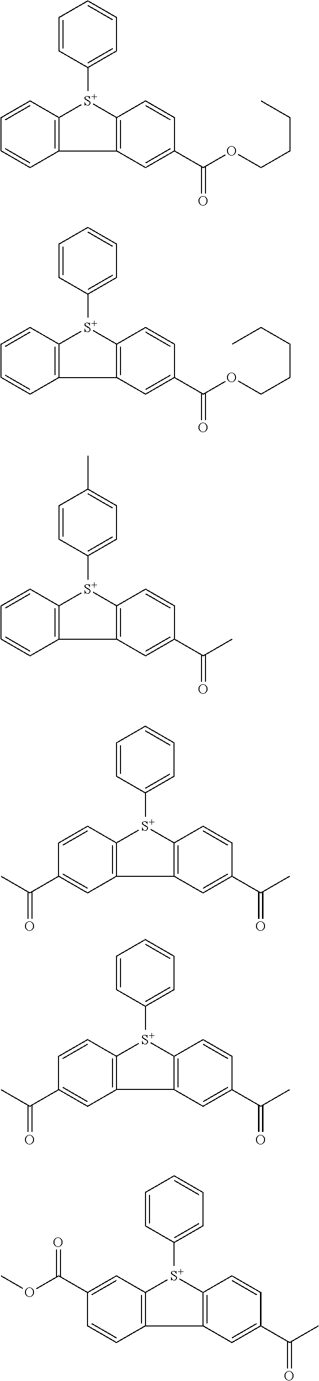

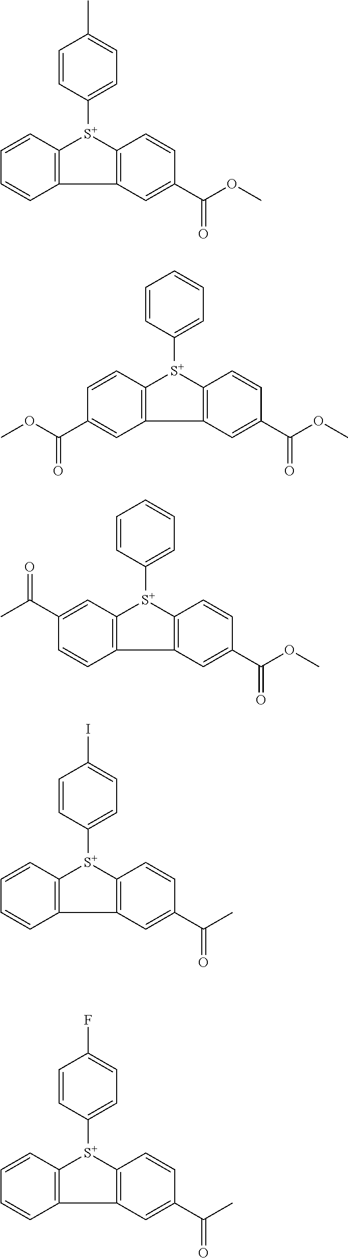

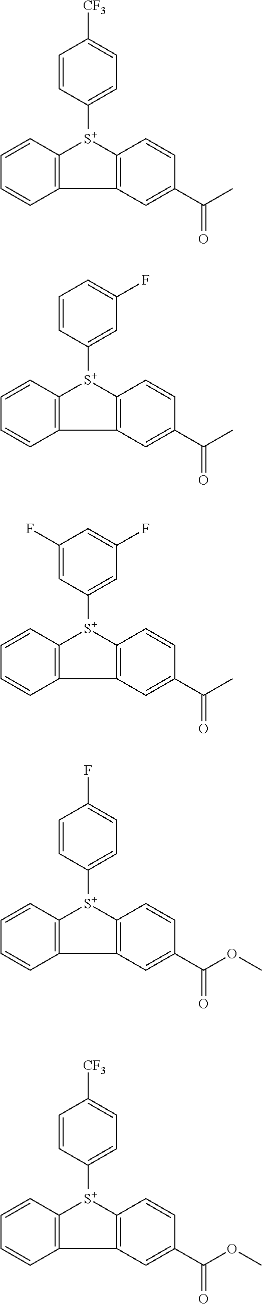 [SMILES: CC(=O)c1ccc2c(c1)c1ccccc1[s+]2-c1ccc(C(F)(F)F)cc1 ; CC(=O)c1ccc2c(c1)c1ccccc1[s+]2-c1cccc(F)c1 ; CC(=O)c1ccc2c(c1)c1ccccc1[s+]2-c1cc(F)cc(F)c1 ; COC(=O)c1ccc2c(c1)c1ccccc1[s+]2-c1ccc(F)cc1 ; COC(=O)c1ccc2c(c1)c1ccccc1[s+]2-c1ccc(C(F)(F)F)cc1]

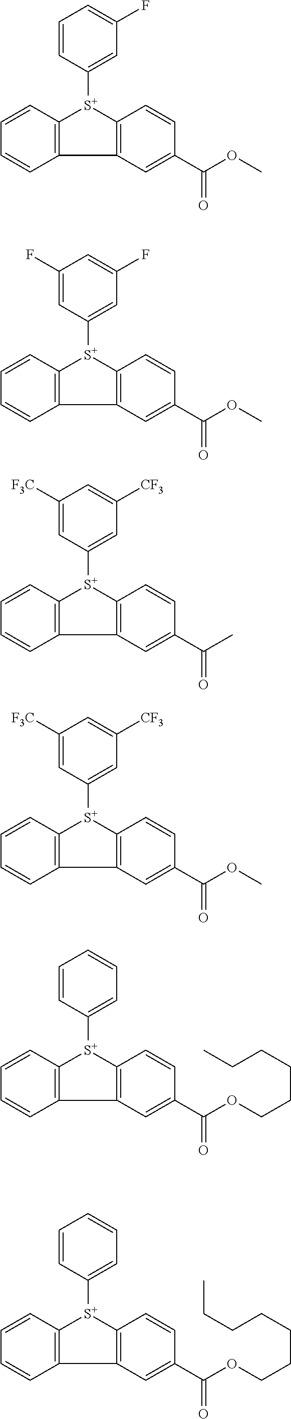 [SMILES: COC(=O)c1ccc2c(c1)c1ccccc1[s+]2-c1cccc(F)c1 ; COC(=O)c1ccc2c(c1)c1ccccc1[s+]2-c1cc(F)cc(F)c1 ; CC(=O)c1ccc2c(c1)c1ccccc1[s+]2-c1cc(C(F)(F)F)cc(C(F)(F)F)c1 ; COC(=O)c1ccc2c(c1)c1ccccc1[s+]2-c1cc(C(F)(F)F)cc(C(F)(F)F)c1 ; CCCCCCOC(=O)c1ccc2c(c1)c1ccccc1[s+]2-c1ccccc1 ; CCCCCCCOC(=O)c1ccc2c(c1)c1ccccc1[s+]2-c1ccccc1]

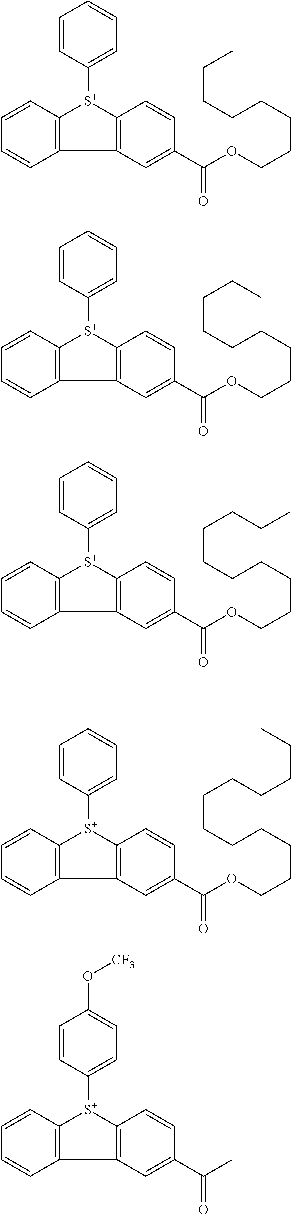 [SMILES: CCCCCCCCOC(=O)c1ccc2c(c1)c1ccccc1[s+]2-c1ccccc1 ; CCCCCCCCCOC(=O)c1ccc2c(c1)c1ccccc1[s+]2-c1ccccc1 ; CCCCCCCCCCOC(=O)c1ccc2c(c1)c1ccccc1[s+]2-c1ccccc1 ; CCCCCCCCCCCCOC(=O)c1ccc2c(c1)c1ccccc1[s+]2-c1ccccc1 ; CC(=O)c1ccc2c(c1)c1ccccc1[s+]2-c1ccc(OC(F)(F)F)cc1]

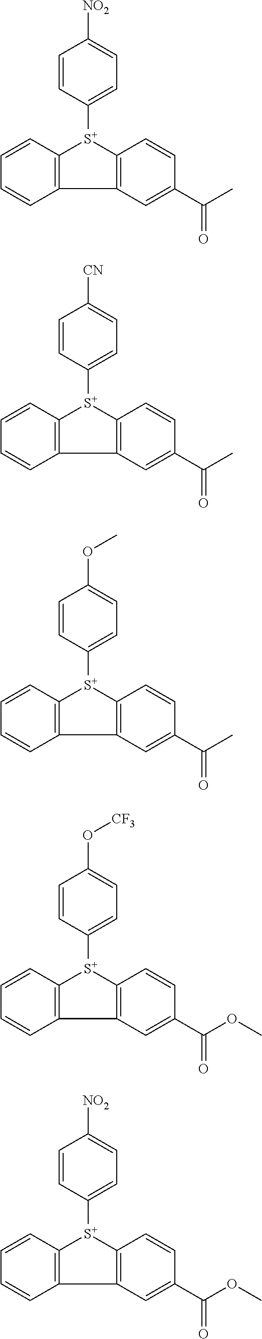 [SMILES: CC(=O)c1ccc2c(c1)c1ccccc1[s+]2-c1ccc([N+](=O)[O-])cc1 ; CC(=O)c1ccc2c(c1)c1ccccc1[s+]2-c1ccc(C#N)cc1 ; COc1ccc(-[s+]2c3ccccc3c3cc(C(C)=O)ccc32)cc1 ; COC(=O)c1ccc2c(c1)c1ccccc1[s+]2-c1ccc(OC(F)(F)F)cc1 ; COC(=O)c1ccc2c(c1)c1ccccc1[s+]2-c1ccc([N+](=O)[O-])cc1]

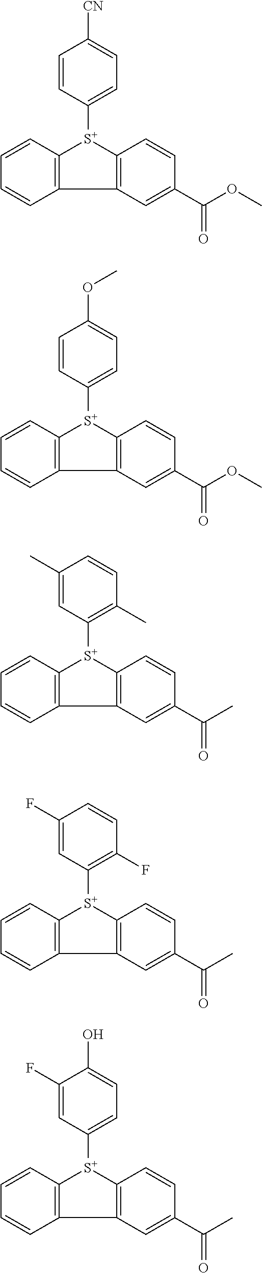 [SMILES: COC(=O)c1ccc2c(c1)c1ccccc1[s+]2-c1ccc(C#N)cc1 ; COC(=O)c1ccc2c(c1)c1ccccc1[s+]2-c1ccc(OC)cc1 ; CC(=O)c1ccc2c(c1)c1ccccc1[s+]2-c1cc(C)ccc1C ; CC(=O)c1ccc2c(c1)c1ccccc1[s+]2-c1cc(F)ccc1F ; CC(=O)c1ccc2c(c1)c1ccccc1[s+]2-c1ccc(O)c(F)c1]

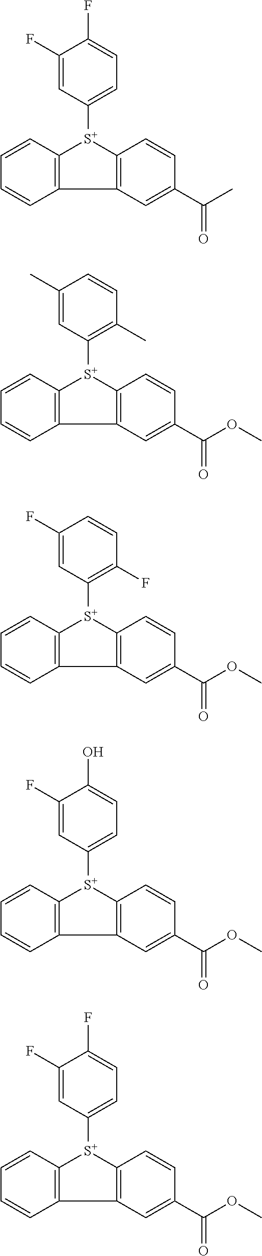 [SMILES: CC(=O)c1ccc2c(c1)c1ccccc1[s+]2-c1ccc(F)c(F)c1 ; COC(=O)c1ccc2c(c1)c1ccccc1[s+]2-c1cc(C)ccc1C ; COC(=O)c1ccc2c(c1)c1ccccc1[s+]2-c1cc(F)ccc1F ; COC(=O)c1ccc2c(c1)c1ccccc1[s+]2-c1ccc(O)c(F)c1 ; COC(=O)c1ccc2c(c1)c1ccccc1[s+]2-c1ccc(F)c(F)c1]

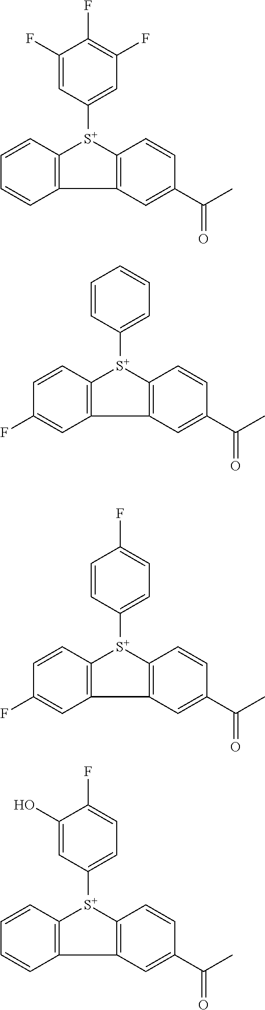 [SMILES: CC(=O)c1ccc2c(c1)c1ccccc1[s+]2-c1cc(F)c(F)c(F)c1 ; CC(=O)c1ccc2c(c1)c1cc(F)ccc1[s+]2-c1ccccc1 ; CC(=O)c1ccc2c(c1)c1cc(F)ccc1[s+]2-c1ccc(F)cc1 ; CC(=O)c1ccc2c(c1)c1ccccc1[s+]2-c1ccc(F)c(O)c1]

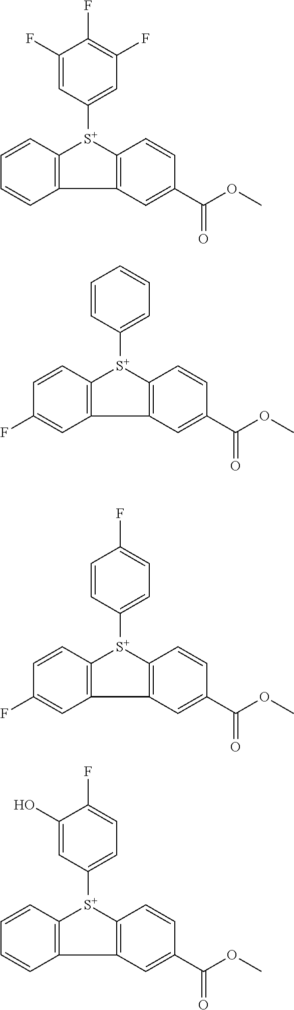 [SMILES: COC(=O)c1ccc2c(c1)c1ccccc1[s+]2-c1cc(F)c(F)c(F)c1 ; COC(=O)c1ccc2c(c1)c1cc(F)ccc1[s+]2-c1ccccc1 ; COC(=O)c1ccc2c(c1)c1cc(F)ccc1[s+]2-c1ccc(F)cc1 ; COC(=O)c1ccc2c(c1)c1ccccc1[s+]2-c1ccc(F)c(O)c1]

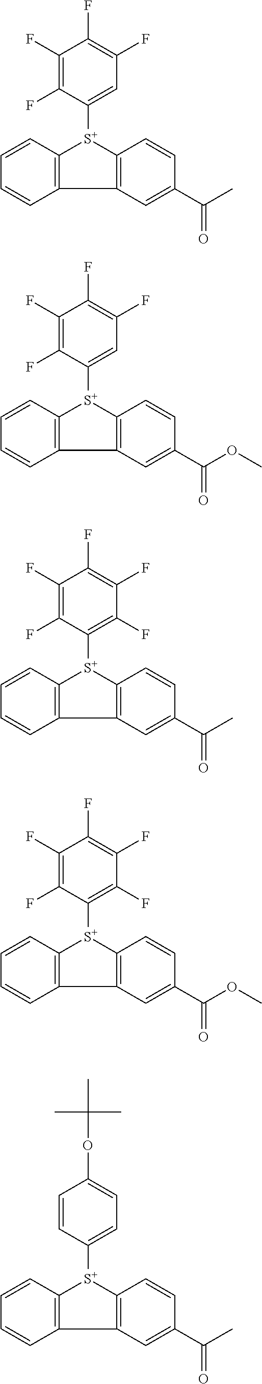 [SMILES: CC(=O)c1ccc2c(c1)c1ccccc1[s+]2-c1cc(F)c(F)c(F)c1F ; COC(=O)c1ccc2c(c1)c1ccccc1[s+]2-c1cc(F)c(F)c(F)c1F ; CC(=O)c1ccc2c(c1)c1ccccc1[s+]2-c1c(F)c(F)c(F)c(F)c1F ; COC(=O)c1ccc2c(c1)c1ccccc1[s+]2-c1c(F)c(F)c(F)c(F)c1F ; CC(=O)c1ccc2c(c1)c1ccccc1[s+]2-c1ccc(OC(C)(C)C)cc1]

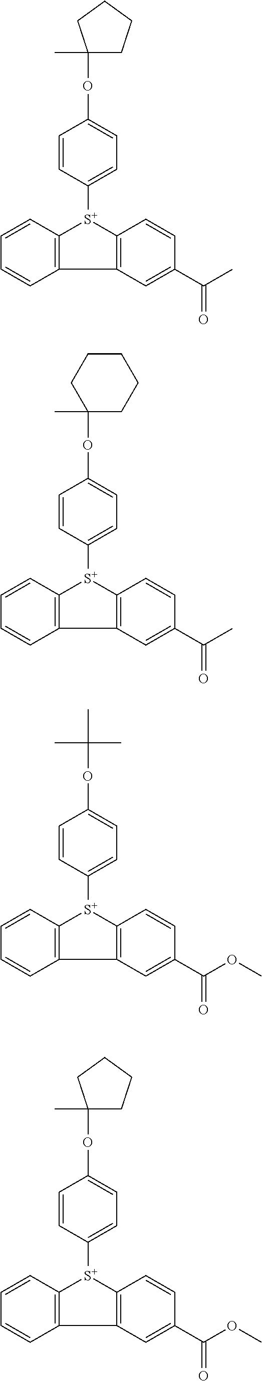 [SMILES: CC(=O)c1ccc2c(c1)c1ccccc1[s+]2-c1ccc(OC2(C)CCCC2)cc1 ; CC(=O)c1ccc2c(c1)c1ccccc1[s+]2-c1ccc(OC2(C)CCCCC2)cc1 ; COC(=O)c1ccc2c(c1)c1ccccc1[s+]2-c1ccc(OC(C)(C)C)cc1 ; COC(=O)c1ccc2c(c1)c1ccccc1[s+]2-c1ccc(OC2(C)CCCC2)cc1]

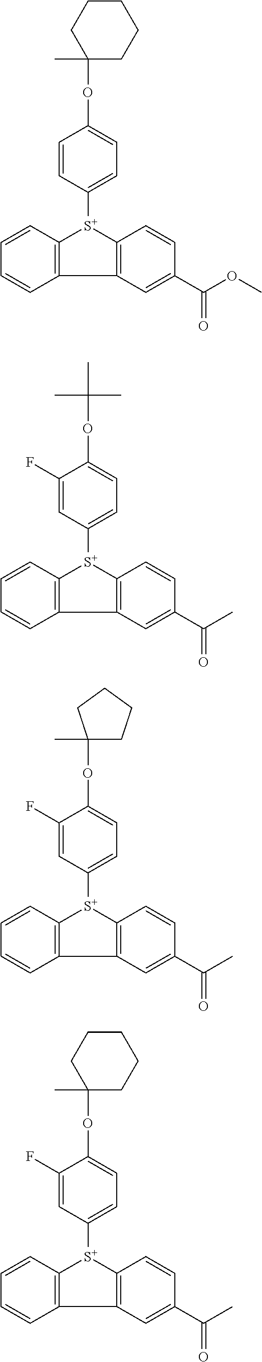 [SMILES: COC(=O)c1ccc2c(c1)c1ccccc1[s+]2-c1ccc(OC2(C)CCCCC2)cc1 ; CC(=O)c1ccc2c(c1)c1ccccc1[s+]2-c1ccc(OC(C)(C)C)c(F)c1 ; CC(=O)c1ccc2c(c1)c1ccccc1[s+]2-c1ccc(OC2(C)CCCC2)c(F)c1 ; CC(=O)c1ccc2c(c1)c1ccccc1[s+]2-c1ccc(OC2(C)CCCCC2)c(F)c1]

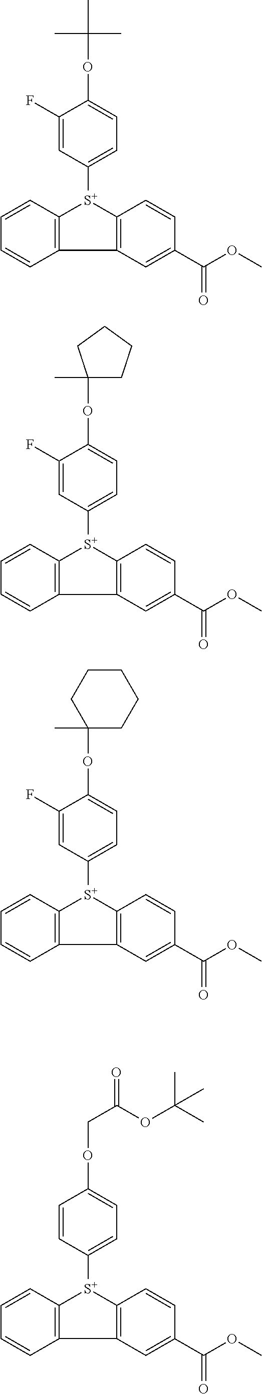 [SMILES: COC(=O)c1ccc2c(c1)c1ccccc1[s+]2-c1ccc(OC(C)(C)C)c(F)c1 ; COC(=O)c1ccc2c(c1)c1ccccc1[s+]2-c1ccc(OC2(C)CCCC2)c(F)c1 ; COC(=O)c1ccc2c(c1)c1ccccc1[s+]2-c1ccc(OC2(C)CCCCC2)c(F)c1 ; COC(=O)c1ccc2c(c1)c1ccccc1[s+]2-c1ccc(OCC(=O)OC(C)(C)C)cc1]

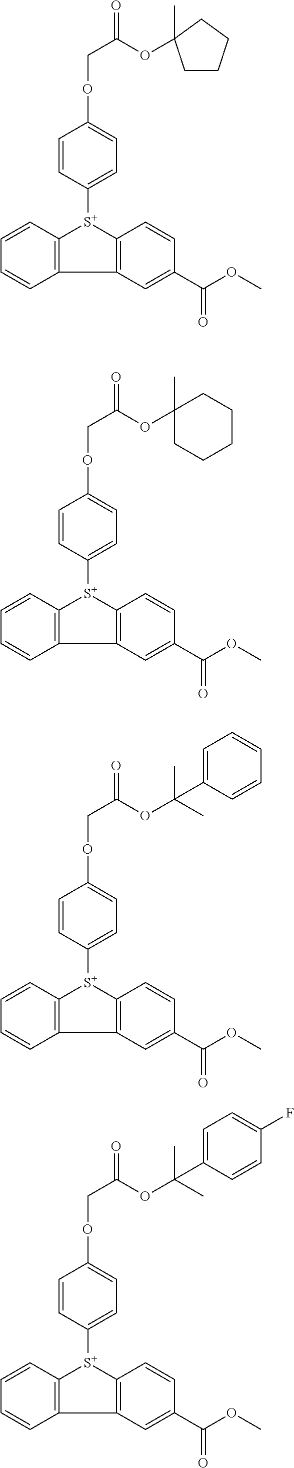 [SMILES: COC(=O)c1ccc2c(c1)c1ccccc1[s+]2-c1ccc(OCC(=O)OC2(C)CCCC2)cc1 ; COC(=O)c1ccc2c(c1)c1ccccc1[s+]2-c1ccc(OCC(=O)OC2(C)CCCCC2)cc1 ; COC(=O)c1ccc2c(c1)c1ccccc1[s+]2-c1ccc(OCC(=O)OC(C)(C)c2ccccc2)cc1 ; COC(=O)c1ccc2c(c1)c1ccccc1[s+]2-c1ccc(OCC(=O)OC(C)(C)c2ccc(F)cc2)cc1]

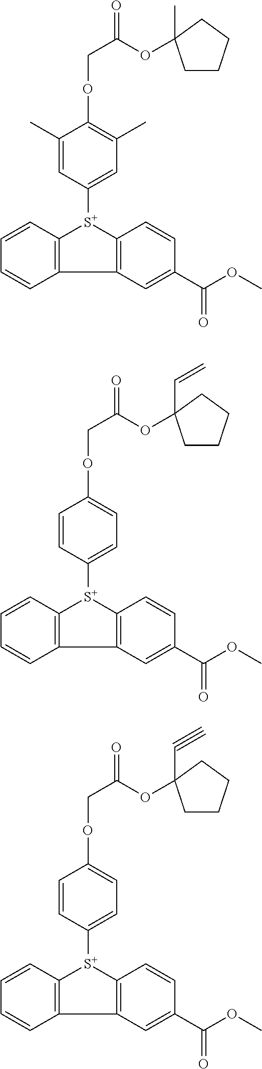 [SMILES: COC(=O)c1ccc2c(c1)c1ccccc1[s+]2-c1cc(C)c(OCC(=O)OC2(C)CCCC2)c(C)c1 ; C=CC1(OC(=O)COc2ccc(-[s+]3c4ccccc4c4cc(C(=O)OC)ccc43)cc2)CCCC1 ; C#CC1(OC(=O)COc2ccc(-[s+]3c4ccccc4c4cc(C(=O)OC)ccc43)cc2)CCCC1]

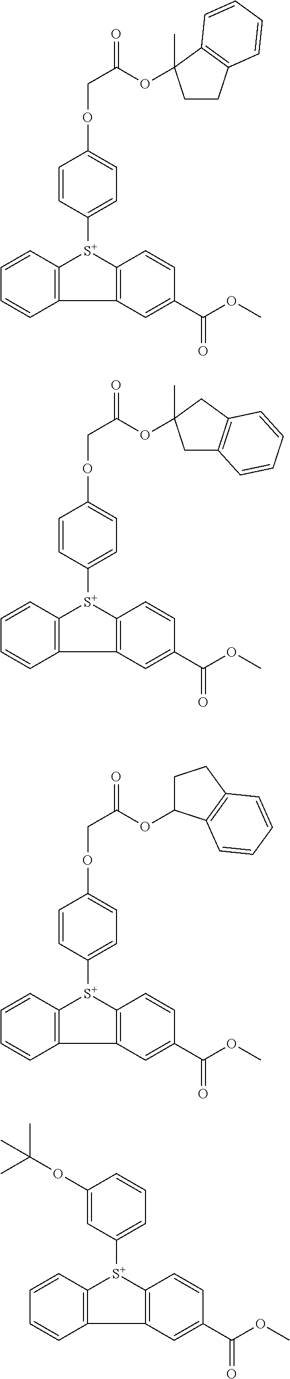 [SMILES: COC(=O)c1ccc2c(c1)c1ccccc1[s+]2-c1ccc(OCC(=O)OC2(C)CCc3ccccc32)cc1 ; COC(=O)c1ccc2c(c1)c1ccccc1[s+]2-c1ccc(OCC(=O)OC2(C)Cc3ccccc3C2)cc1 ; COC(=O)c1ccc2c(c1)c1ccccc1[s+]2-c1ccc(OCC(=O)OC2CCc3ccccc32)cc1 ; COC(=O)c1ccc2c(c1)c1ccccc1[s+]2-c1cccc(OC(C)(C)C)c1]

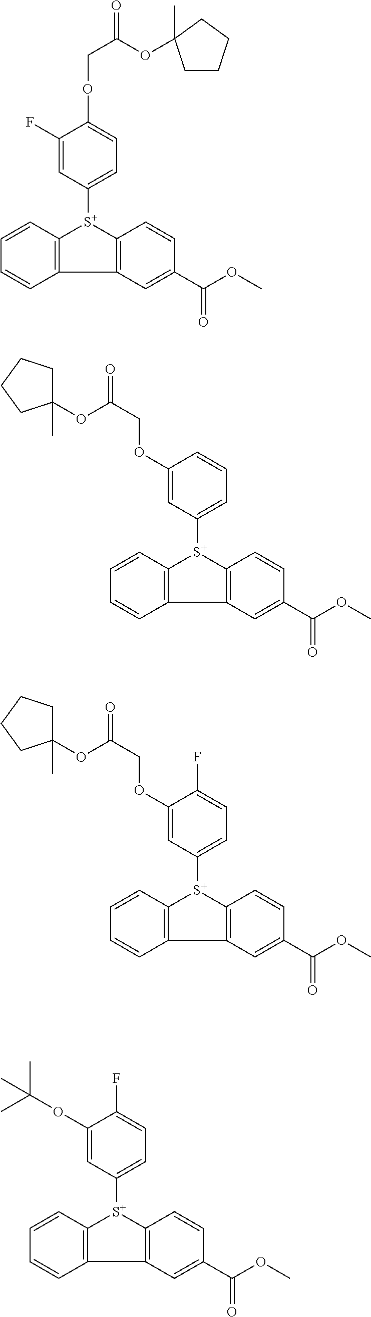

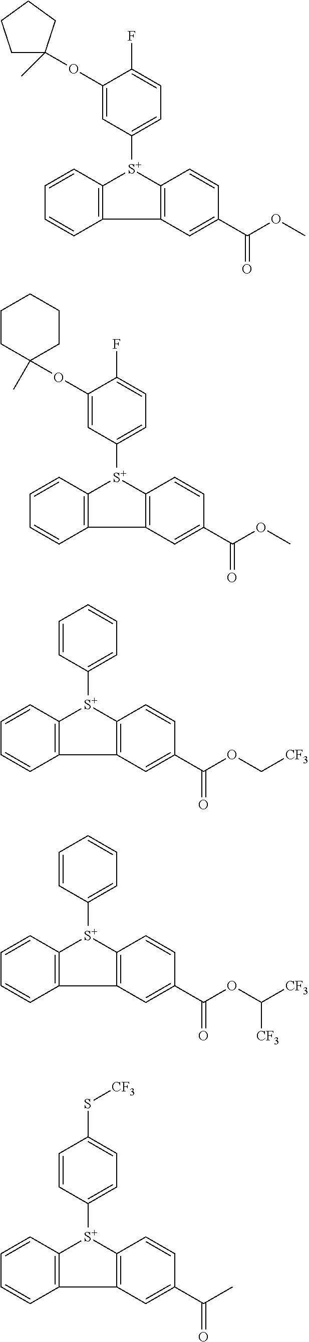 [SMILES: COC(=O)c1ccc2c(c1)c1ccccc1[s+]2-c1ccc(F)c(OC2(C)CCCC2)c1 ; COC(=O)c1ccc2c(c1)c1ccccc1[s+]2-c1ccc(F)c(OC2(C)CCCCC2)c1 ; O=C(OCC(F)(F)F)c1ccc2c(c1)c1ccccc1[s+]2-c1ccccc1 ; O=C(OC(C(F)(F)F)C(F)(F)F)c1ccc2c(c1)c1ccccc1[s+]2-c1ccccc1 ; CC(=O)c1ccc2c(c1)c1ccccc1[s+]2-c1ccc(SC(F)(F)F)cc1]

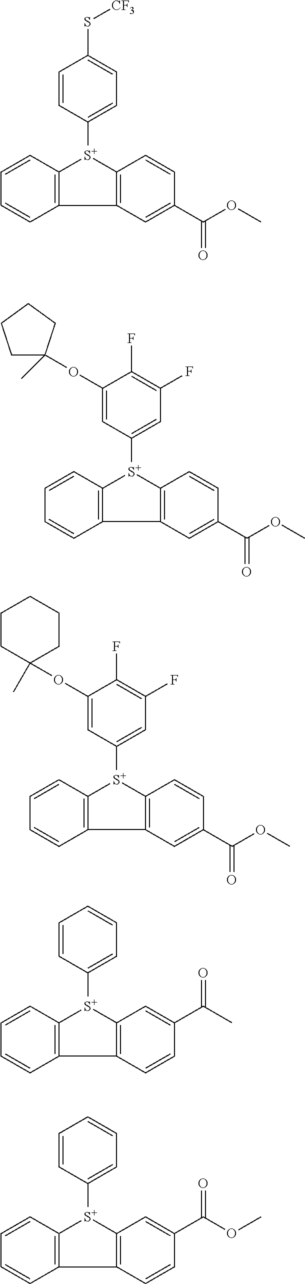 [SMILES: COC(=O)c1ccc2c(c1)c1ccccc1[s+]2-c1ccc(SC(F)(F)F)cc1 ; COC(=O)c1ccc2c(c1)c1ccccc1[s+]2-c1cc(F)c(F)c(OC2(C)CCCC2)c1 ; COC(=O)c1ccc2c(c1)c1ccccc1[s+]2-c1cc(F)c(F)c(OC2(C)CCCCC2)c1 ; CC(=O)c1ccc2c3ccccc3[s+](-c3ccccc3)c2c1 ; COC(=O)c1ccc2c3ccccc3[s+](-c3ccccc3)c2c1]

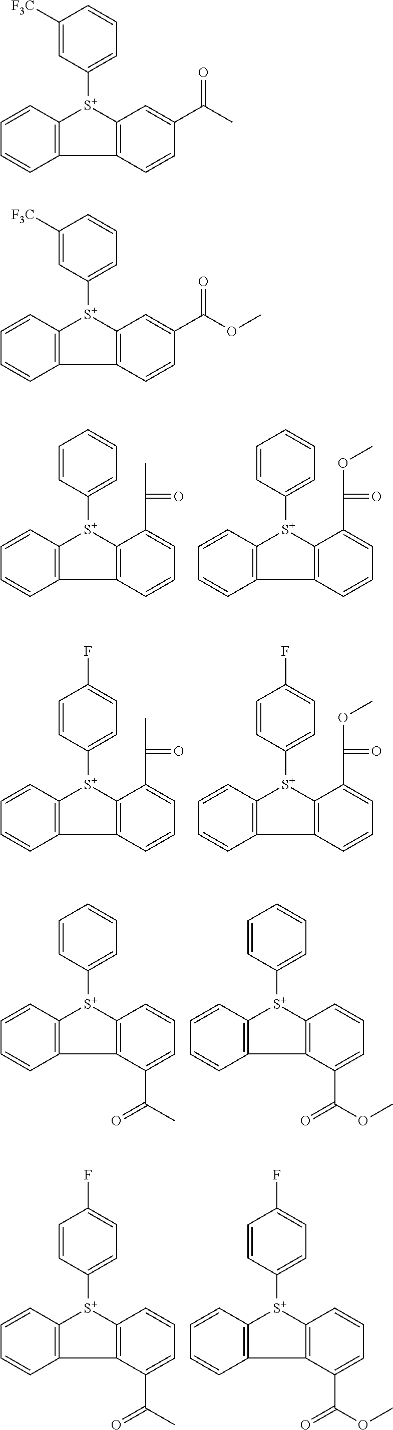

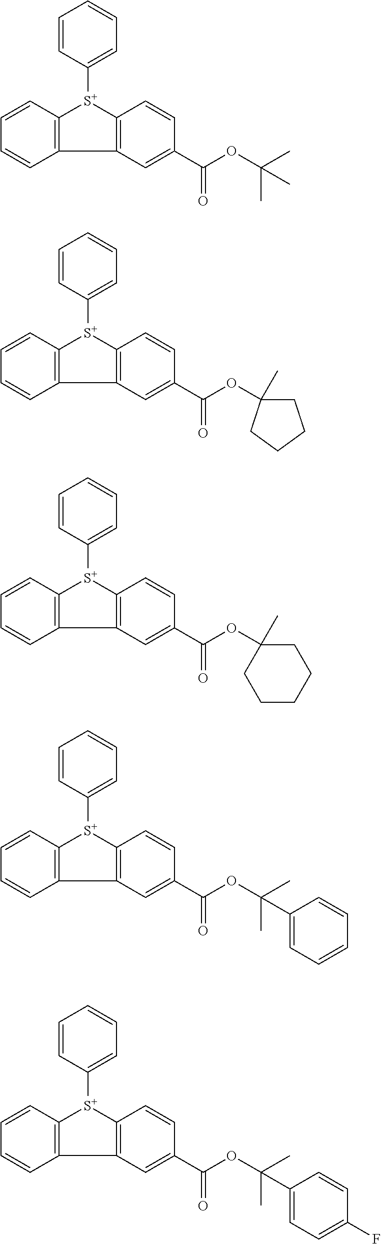 [SMILES: CC(C)(C)OC(=O)c1ccc2c(c1)c1ccccc1[s+]2-c1ccccc1 ; CC1(OC(=O)c2ccc3c(c2)c2ccccc2[s+]3-c2ccccc2)CCCC1 ; CC1(OC(=O)c2ccc3c(c2)c2ccccc2[s+]3-c2ccccc2)CCCCC1 ; CC(C)(OC(=O)c1ccc2c(c1)c1ccccc1[s+]2-c1ccccc1)c1ccccc1 ; CC(C)(OC(=O)c1ccc2c(c1)c1ccccc1[s+]2-c1ccccc1)c1ccc(F)cc1]

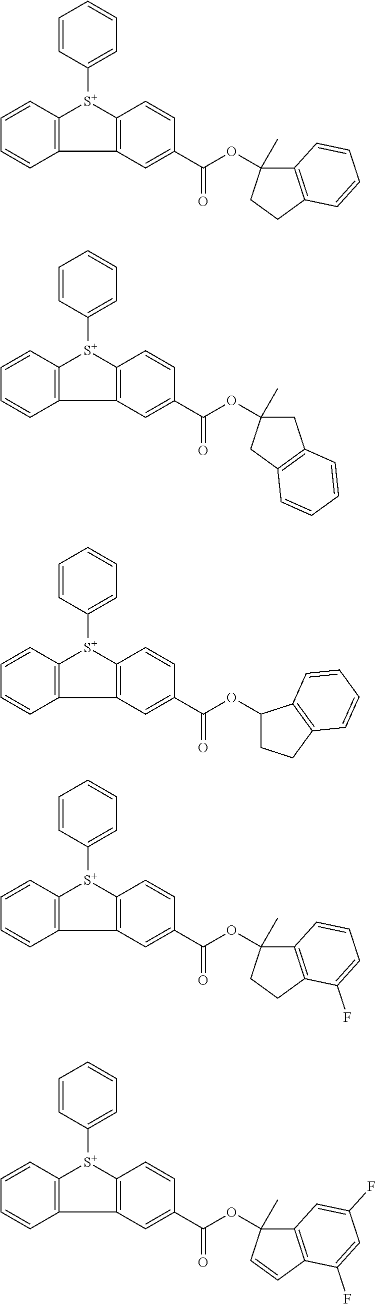 [SMILES: CC1(OC(=O)c2ccc3c(c2)c2ccccc2[s+]3-c2ccccc2)CCc2ccccc21 ; CC1(OC(=O)c2ccc3c(c2)c2ccccc2[s+]3-c2ccccc2)Cc2ccccc2C1 ; O=C(OC1CCc2ccccc21)c1ccc2c(c1)c1ccccc1[s+]2-c1ccccc1 ; CC1(OC(=O)c2ccc3c(c2)c2ccccc2[s+]3-c2ccccc2)CCc2c(F)cccc21 ; CC1(OC(=O)c2ccc3c(c2)c2ccccc2[s+]3-c2ccccc2)C=Cc2c(F)cc(F)cc21]

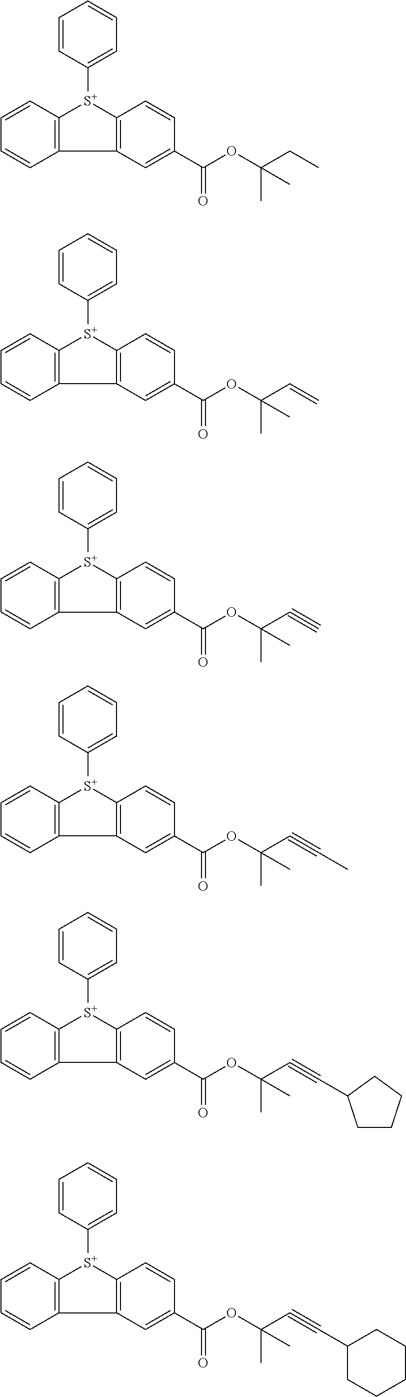 [SMILES: CCC(C)(C)OC(=O)c1ccc2c(c1)c1ccccc1[s+]2-c1ccccc1 ; C=CC(C)(C)OC(=O)c1ccc2c(c1)c1ccccc1[s+]2-c1ccccc1 ; C#CC(C)(C)OC(=O)c1ccc2c(c1)c1ccccc1[s+]2-c1ccccc1 ; CC#CC(C)(C)OC(=O)c1ccc2c(c1)c1ccccc1[s+]2-c1ccccc1 ; CC(C)(C#CC1CCCC1)OC(=O)c1ccc2c(c1)c1ccccc1[s+]2-c1ccccc1 ; CC(C)(C#CC1CCCCC1)OC(=O)c1ccc2c(c1)c1ccccc1[s+]2-c1ccccc1]

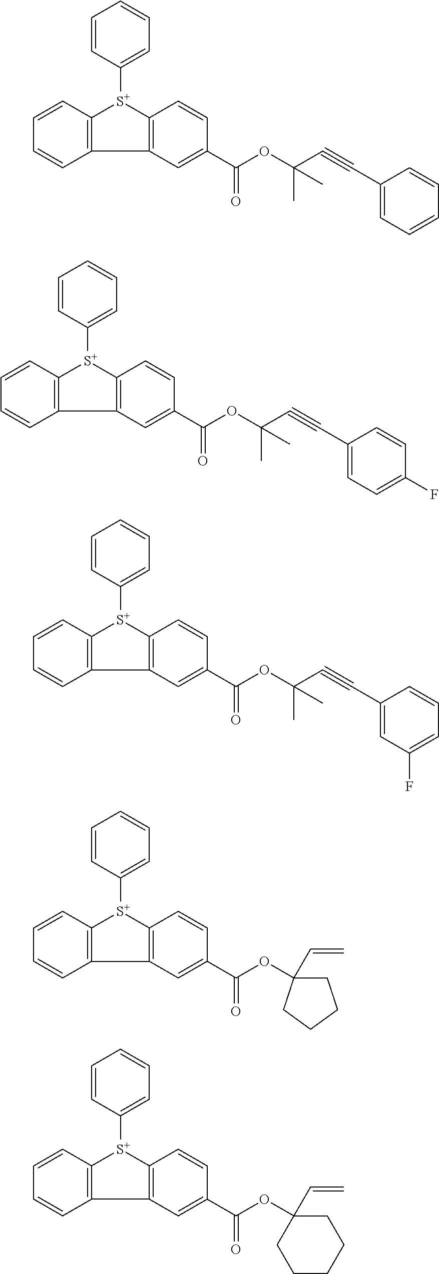 [SMILES: CC(C)(C#Cc1ccccc1)OC(=O)c1ccc2c(c1)c1ccccc1[s+]2-c1ccccc1 ; CC(C)(C#Cc1ccc(F)cc1)OC(=O)c1ccc2c(c1)c1ccccc1[s+]2-c1ccccc1 ; CC(C)(C#Cc1cccc(F)c1)OC(=O)c1ccc2c(c1)c1ccccc1[s+]2-c1ccccc1 ; C=CC1(OC(=O)c2ccc3c(c2)c2ccccc2[s+]3-c2ccccc2)CCCC1 ; C=CC1(OC(=O)c2ccc3c(c2)c2ccccc2[s+]3-c2ccccc2)CCCCC1]

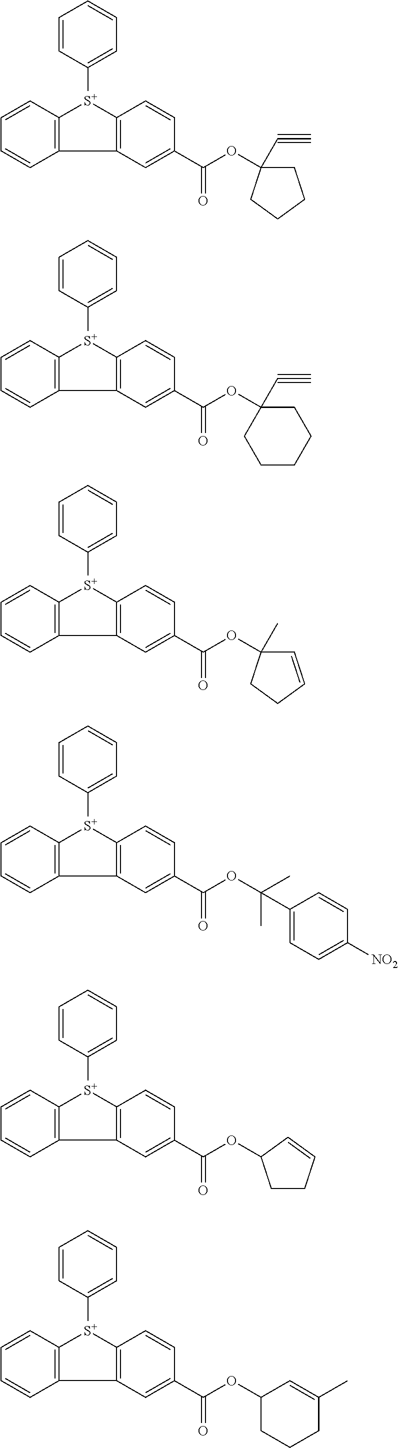 [SMILES: C#CC1(OC(=O)c2ccc3c(c2)c2ccccc2[s+]3-c2ccccc2)CCCC1 ; C#CC1(OC(=O)c2ccc3c(c2)c2ccccc2[s+]3-c2ccccc2)CCCCC1 ; CC1(OC(=O)c2ccc3c(c2)c2ccccc2[s+]3-c2ccccc2)C=CCC1 ; CC(C)(OC(=O)c1ccc2c(c1)c1ccccc1[s+]2-c1ccccc1)c1ccc([N+](=O)[O-])cc1 ; O=C(OC1C=CCC1)c1ccc2c(c1)c1ccccc1[s+]2-c1ccccc1 ; CC1=CC(OC(=O)c2ccc3c(c2)c2ccccc2[s+]3-c2ccccc2)CCC1]

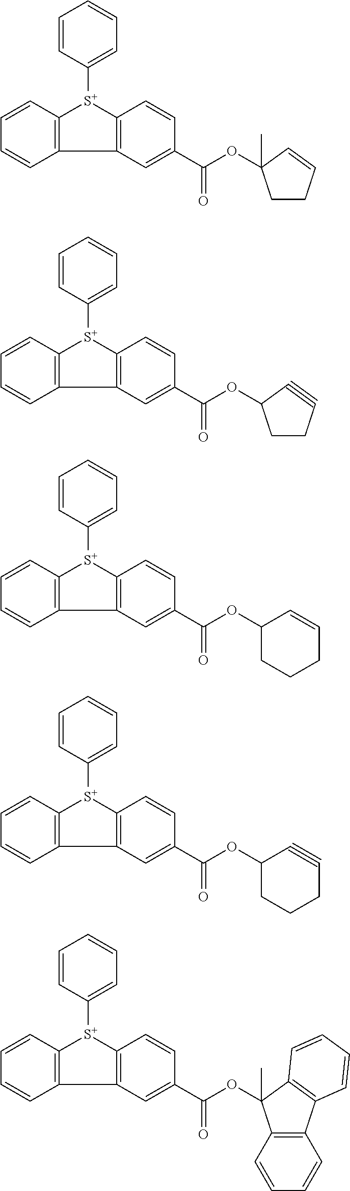 [SMILES: CC1(OC(=O)c2ccc3c(c2)c2ccccc2[s+]3-c2ccccc2)C=CCC1 ; O=C(OC1C#CCC1)c1ccc2c(c1)c1ccccc1[s+]2-c1ccccc1 ; O=C(OC1C=CCCC1)c1ccc2c(c1)c1ccccc1[s+]2-c1ccccc1 ; O=C(OC1C#CCCC1)c1ccc2c(c1)c1ccccc1[s+]2-c1ccccc1 ; CC1(OC(=O)c2ccc3c(c2)c2ccccc2[s+]3-c2ccccc2)c2ccccc2-c2ccccc21]

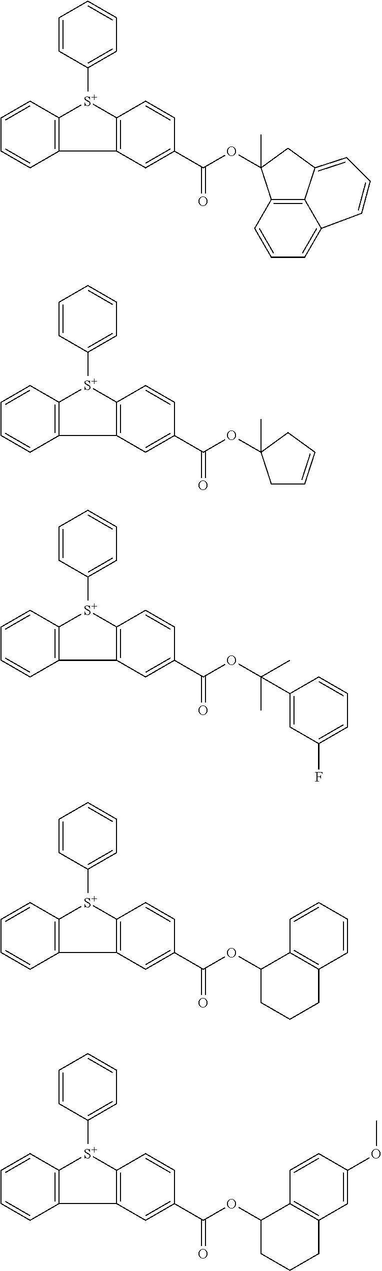 [SMILES: CC1(OC(=O)c2ccc3c(c2)c2ccccc2[s+]3-c2ccccc2)Cc2cccc3cccc1c23 ; CC1(OC(=O)c2ccc3c(c2)c2ccccc2[s+]3-c2ccccc2)CC=CC1 ; CC(C)(OC(=O)c1ccc2c(c1)c1ccccc1[s+]2-c1ccccc1)c1cccc(F)c1 ; O=C(OC1CCCc2ccccc21)c1ccc2c(c1)c1ccccc1[s+]2-c1ccccc1 ; COc1ccc2c(c1)CCCC2OC(=O)c1ccc2c(c1)c1ccccc1[s+]2-c1ccccc1]

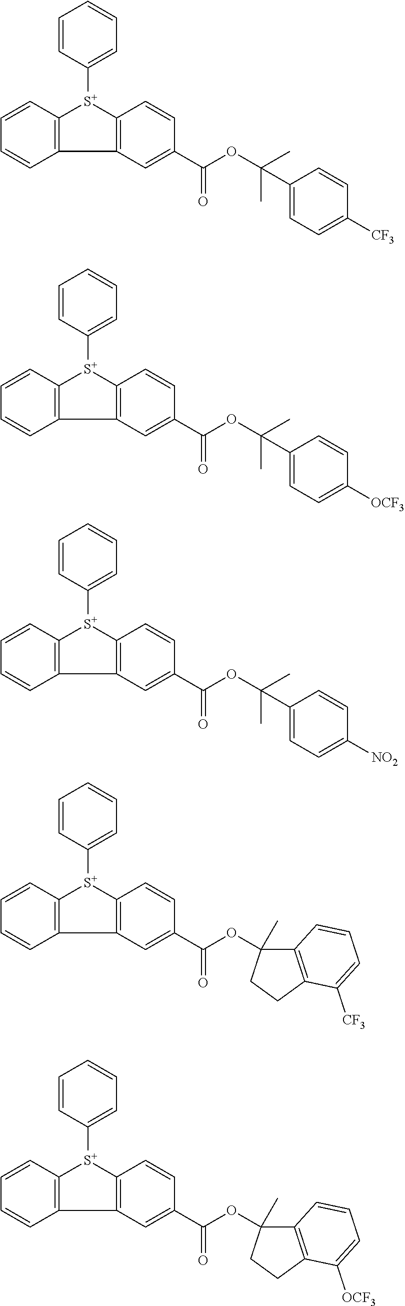 [SMILES: CC(C)(OC(=O)c1ccc2c(c1)c1ccccc1[s+]2-c1ccccc1)c1ccc(C(F)(F)F)cc1 ; CC(C)(OC(=O)c1ccc2c(c1)c1ccccc1[s+]2-c1ccccc1)c1ccc(OC(F)(F)F)cc1 ; CC(C)(OC(=O)c1ccc2c(c1)c1ccccc1[s+]2-c1ccccc1)c1ccc([N+](=O)[O-])cc1 ; CC1(OC(=O)c2ccc3c(c2)c2ccccc2[s+]3-c2ccccc2)CCc2c(C(F)(F)F)cccc21 ; CC1(OC(=O)c2ccc3c(c2)c2ccccc2[s+]3-c2ccccc2)CCc2c(OC(F)(F)F)cccc21]

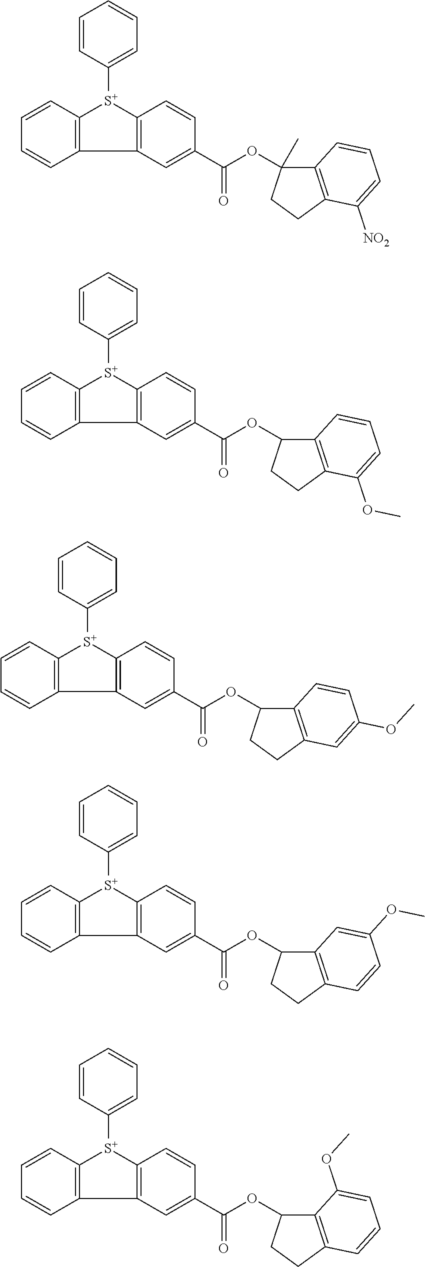 [SMILES: CC1(OC(=O)c2ccc3c(c2)c2ccccc2[s+]3-c2ccccc2)CCc2c([N+](=O)[O-])cccc21 ; COc1cccc2c1CCC2OC(=O)c1ccc2c(c1)c1ccccc1[s+]2-c1ccccc1 ; COc1ccc2c(c1)CCC2OC(=O)c1ccc2c(c1)c1ccccc1[s+]2-c1ccccc1 ; COc1ccc2c(c1)C(OC(=O)c1ccc3c(c1)c1ccccc1[s+]3-c1ccccc1)CC2 ; COc1cccc2c1C(OC(=O)c1ccc3c(c1)c1ccccc1[s+]3-c1ccccc1)CC2]

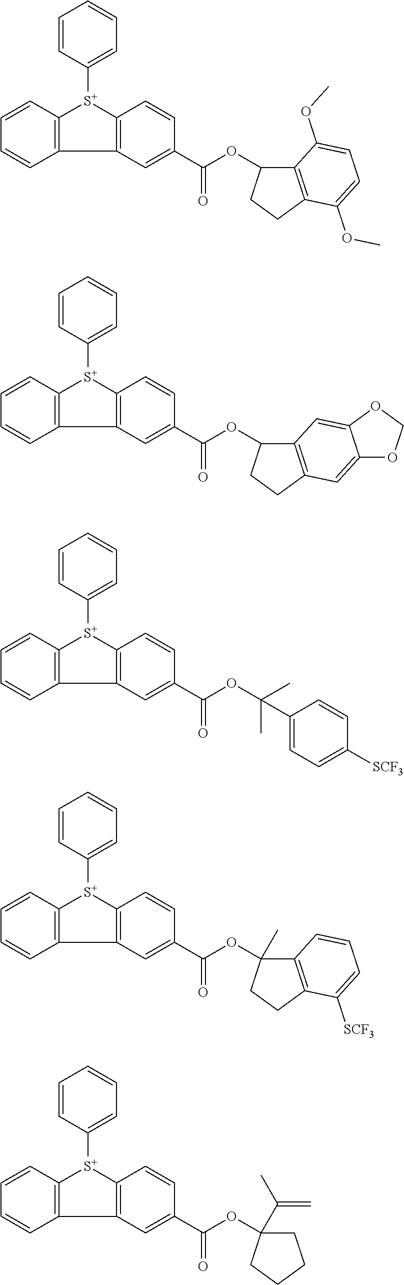

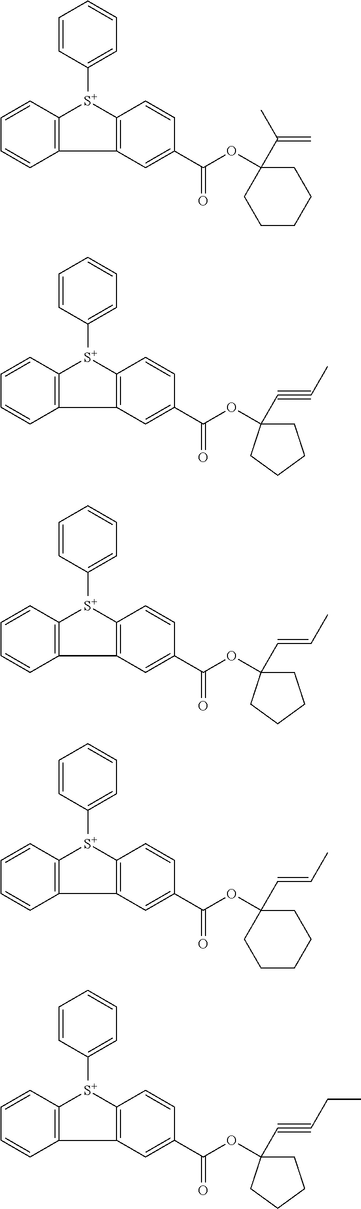 [SMILES: C=C(C)C1(OC(=O)c2ccc3c(c2)c2ccccc2[s+]3-c2ccccc2)CCCCC1 ; CC#CC1(OC(=O)c2ccc3c(c2)c2ccccc2[s+]3-c2ccccc2)CCCC1 ; C/C=C/C1(OC(=O)c2ccc3c(c2)c2ccccc2[s+]3-c2ccccc2)CCCC1 ; C/C=C/C1(OC(=O)c2ccc3c(c2)c2ccccc2[s+]3-c2ccccc2)CCCCC1 ; CCC#CC1(OC(=O)c2ccc3c(c2)c2ccccc2[s+]3-c2ccccc2)CCCC1]

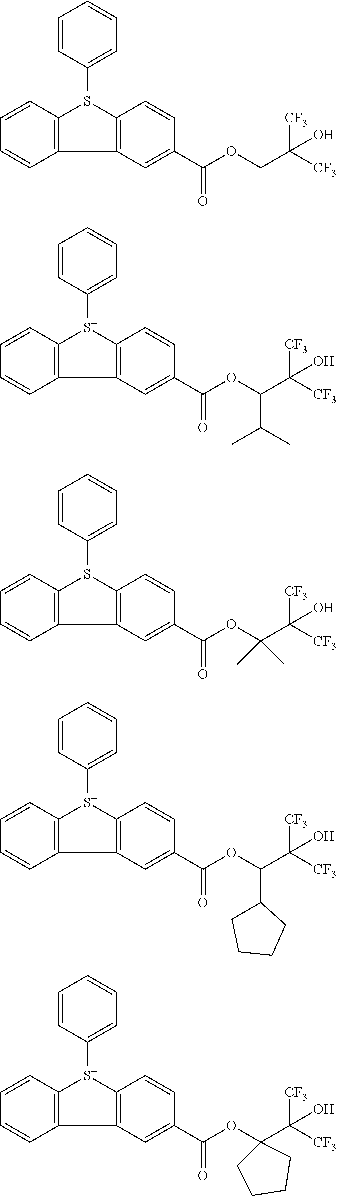 [SMILES: O=C(OCC(O)(C(F)(F)F)C(F)(F)F)c1ccc2c(c1)c1ccccc1[s+]2-c1ccccc1 ; CC(C)C(OC(=O)c1ccc2c(c1)c1ccccc1[s+]2-c1ccccc1)C(O)(C(F)(F)F)C(F)(F)F ; CC(C)(OC(=O)c1ccc2c(c1)c1ccccc1[s+]2-c1ccccc1)C(O)(C(F)(F)F)C(F)(F)F ; O=C(OC(C1CCCC1)C(O)(C(F)(F)F)C(F)(F)F)c1ccc2c(c1)c1ccccc1[s+]2-c1ccccc1 ; O=C(OC1(C(O)(C(F)(F)F)C(F)(F)F)CCCC1)c1ccc2c(c1)c1ccccc1[s+]2-c1ccccc1]

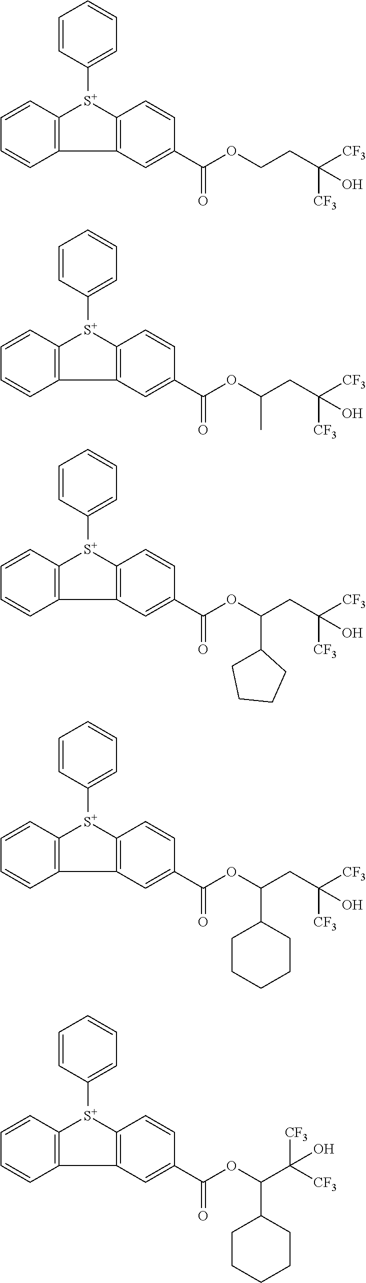 [SMILES: O=C(OCCC(O)(C(F)(F)F)C(F)(F)F)c1ccc2c(c1)c1ccccc1[s+]2-c1ccccc1 ; CC(CC(O)(C(F)(F)F)C(F)(F)F)OC(=O)c1ccc2c(c1)c1ccccc1[s+]2-c1ccccc1 ; O=C(OC(CC(O)(C(F)(F)F)C(F)(F)F)C1CCCC1)c1ccc2c(c1)c1ccccc1[s+]2-c1ccccc1 ; O=C(OC(CC(O)(C(F)(F)F)C(F)(F)F)C1CCCCC1)c1ccc2c(c1)c1ccccc1[s+]2-c1ccccc1 ; O=C(OC(C1CCCCC1)C(O)(C(F)(F)F)C(F)(F)F)c1ccc2c(c1)c1ccccc1[s+]2-c1ccccc1]

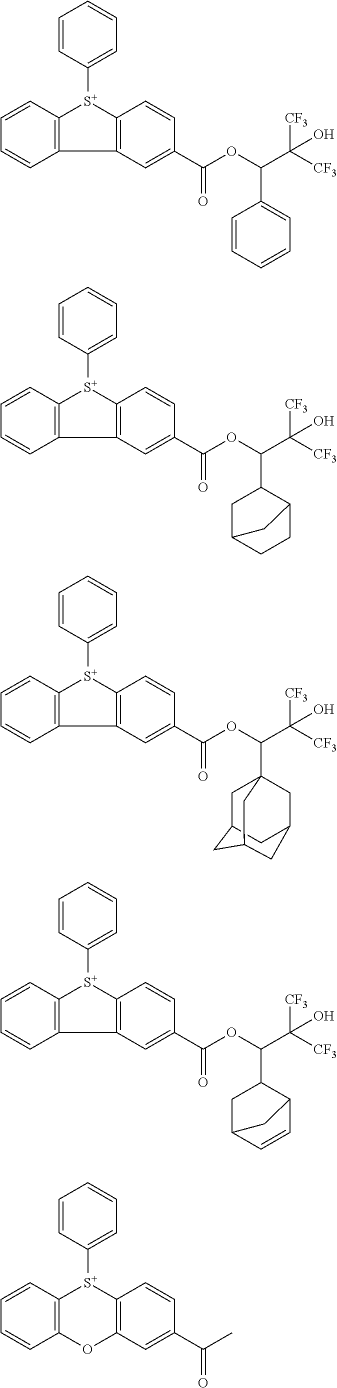 [SMILES: O=C(OC(c1ccccc1)C(O)(C(F)(F)F)C(F)(F)F)c1ccc2c(c1)c1ccccc1[s+]2-c1ccccc1 ; O=C(OC(C1CC2CCC1C2)C(O)(C(F)(F)F)C(F)(F)F)c1ccc2c(c1)c1ccccc1[s+]2-c1ccccc1 ; O=C(OC(C12CC3CC(CC(C3)C1)C2)C(O)(C(F)(F)F)C(F)(F)F)c1ccc2c(c1)c1ccccc1[s+]2-c1ccccc1 ; O=C(OC(C1CC2C=CC1C2)C(O)(C(F)(F)F)C(F)(F)F)c1ccc2c(c1)c1ccccc1[s+]2-c1ccccc1 ; CC(=O)c1ccc2c(c1)Oc1ccccc1[S+]2c1ccccc1]

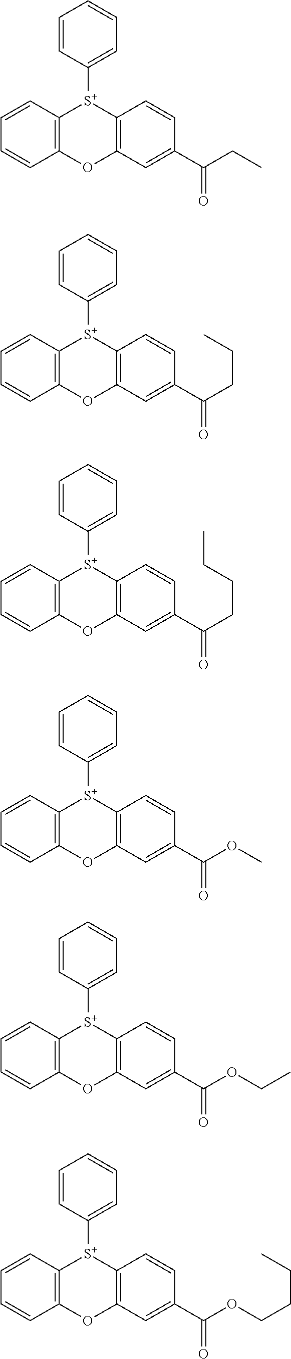 [SMILES: CCC(=O)c1ccc2c(c1)Oc1ccccc1[S+]2c1ccccc1 ; CCCC(=O)c1ccc2c(c1)Oc1ccccc1[S+]2c1ccccc1 ; CCCCC(=O)c1ccc2c(c1)Oc1ccccc1[S+]2c1ccccc1 ; COC(=O)c1ccc2c(c1)Oc1ccccc1[S+]2c1ccccc1 ; CCOC(=O)c1ccc2c(c1)Oc1ccccc1[S+]2c1ccccc1 ; CCCCOC(=O)c1ccc2c(c1)Oc1ccccc1[S+]2c1ccccc1]

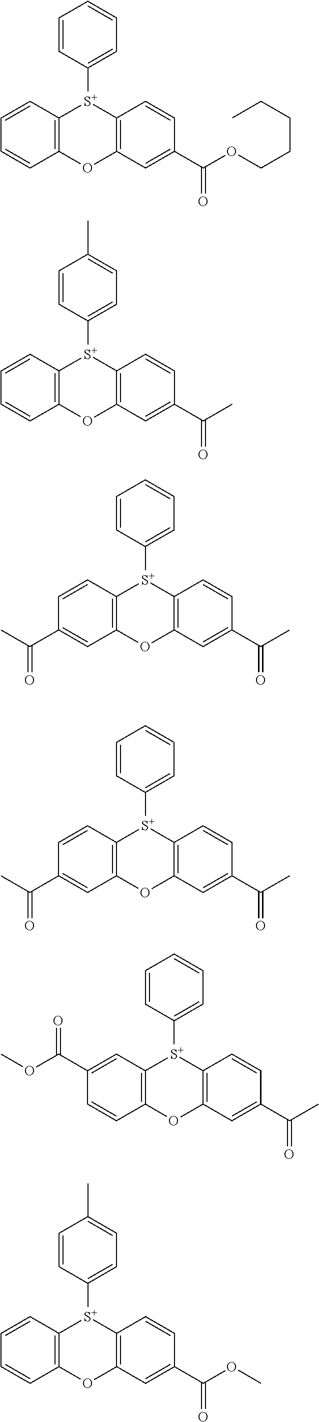

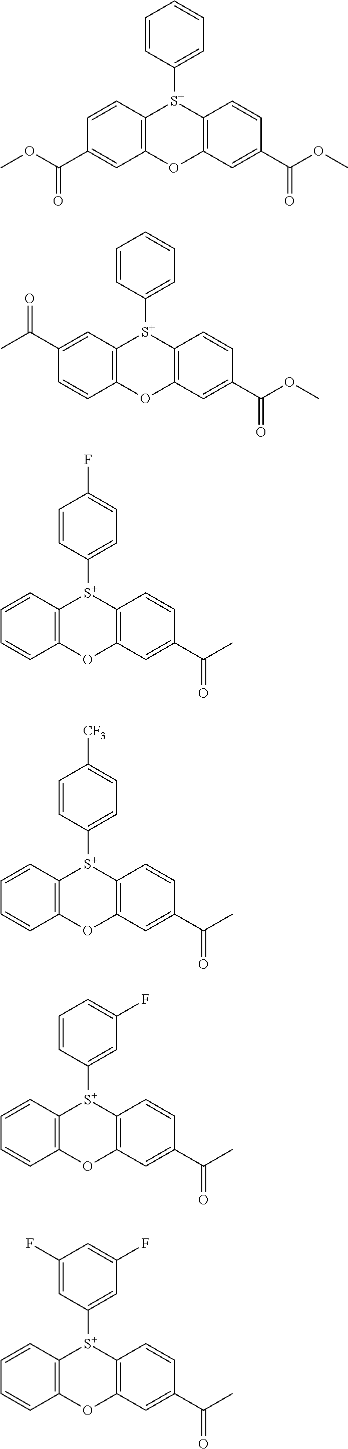

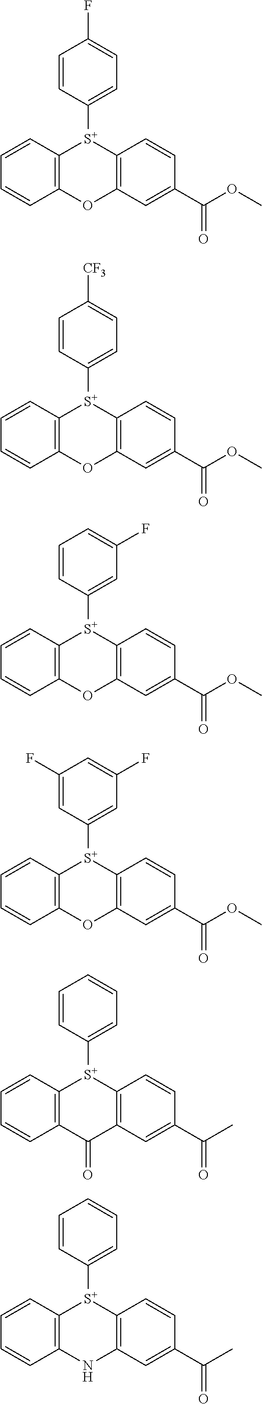 [SMILES: COC(=O)c1ccc2c(c1)Oc1ccccc1[S+]2c1ccc(F)cc1 ; COC(=O)c1ccc2c(c1)Oc1ccccc1[S+]2c1ccc(C(F)(F)F)cc1 ; COC(=O)c1ccc2c(c1)Oc1ccccc1[S+]2c1cccc(F)c1 ; COC(=O)c1ccc2c(c1)Oc1ccccc1[S+]2c1cc(F)cc(F)c1 ; CC(=O)c1ccc2c(c1)c(=O)c1ccccc1[s+]2-c1ccccc1 ; CC(=O)c1ccc2c(c1)Nc1ccccc1[S+]2c1ccccc1]

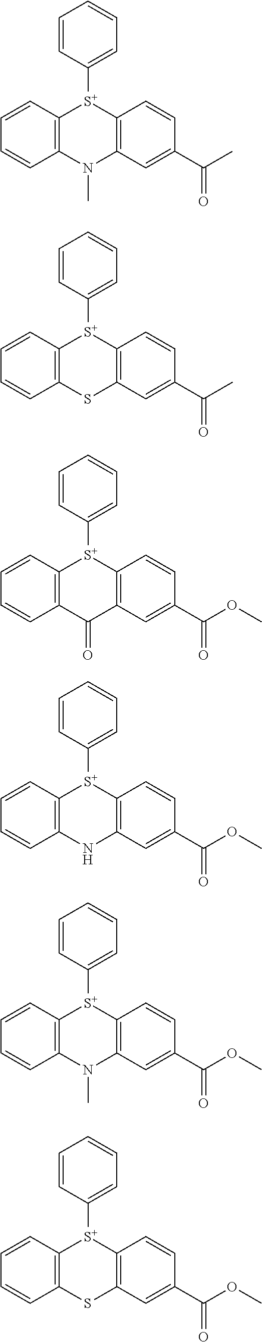 [SMILES: CC(=O)c1ccc2c(c1)N(C)c1ccccc1[S+]2c1ccccc1 ; CC(=O)c1ccc2c(c1)Sc1ccccc1[S+]2c1ccccc1 ; COC(=O)c1ccc2c(c1)c(=O)c1ccccc1[s+]2-c1ccccc1 ; COC(=O)c1ccc2c(c1)Nc1ccccc1[S+]2c1ccccc1 ; COC(=O)c1ccc2c(c1)N(C)c1ccccc1[S+]2c1ccccc1 ; COC(=O)c1ccc2c(c1)Sc1ccccc1[S+]2c1ccccc1]

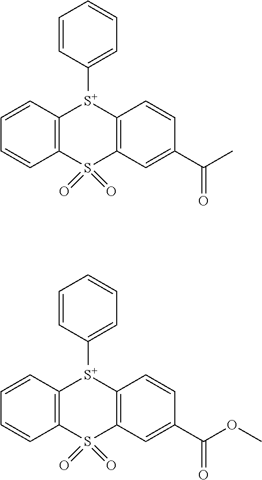 [SMILES: CC(=O)c1ccc2c(c1)S(=O)(=O)c1ccccc1[S+]2c1ccccc1 ; COC(=O)c1ccc2c(c1)S(=O)(=O)c1ccccc1[S+]2c1ccccc1]

In a preferred embodiment, the repeat units (a) are repeat units having formula (a1) (hereinafter also referred to as repeat units (a1)) or repeat units having formula (a2) (hereinafter also referred to as repeat units (a2)).

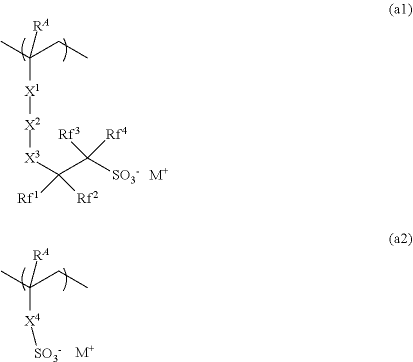

In formulae (a1) and (a2), R^{A} is each independently a hydrogen atom or a methyl group. X¹ is a single bond or an ester bond. X² is a single bond, —X²¹—C(═O)—O—, or —X²¹—O—. X²¹ is a C₁-C₁₂ hydrocarbylene group, a phenylene group, or a C₇-C₁₈ group obtained by combining the foregoing, which may contain a carbonyl group, a nitro group, a cyano group, an ester bond, an ether bond, a urethane bond, a fluorine atom, an iodine atom, or a bromine atom. X is a single bond, a methylene group, or an ethylene group. X⁴ is a single bond, a methylene group, an ethylene group, a phenylene group, a methylphenylene group, a dimethylphenylene group, a fluorinated phenylene group, a phenylene group substituted by a trifluoromethyl group, —O—X⁴¹—, —C(═O)—O—X⁴¹—, or —C(═O)—NH—X⁴¹—. X⁴¹ is a C₁-C₆ aliphatic hydrocarbylene group, a phenylene group, a methylphenylene group, a dimethylphenylene group, a fluorinated phenylene group, or a phenylene group substituted by a trifluoromethyl group, and may contain a carbonyl group, an ester bond, an ether bond, a hydroxy group, or a halogen atom. Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf² may together form a carbonyl group. M⁺ is a sulfonium cation having formula (1).

Examples of the anion in the monomer from which the repeat units (a1) are derived are shown below, but not limited thereto. Herein R^{A} is as defined above.

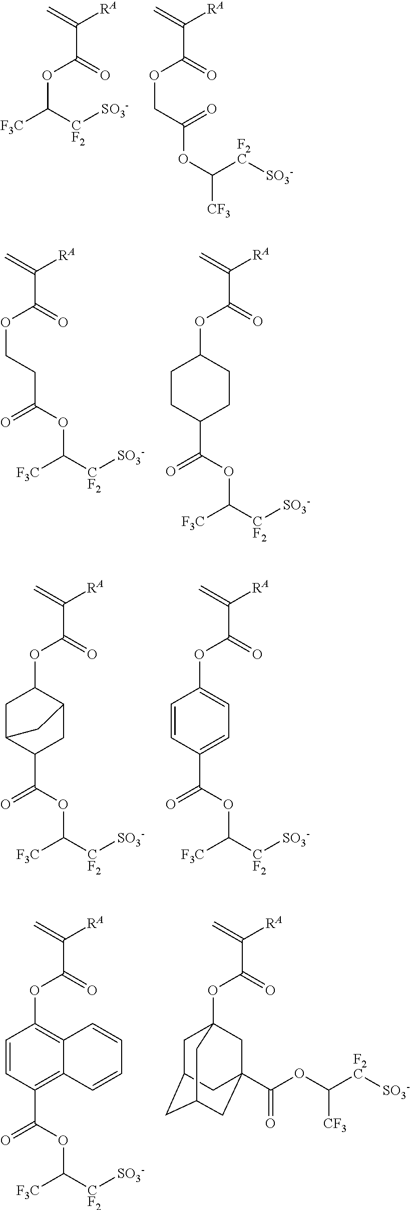

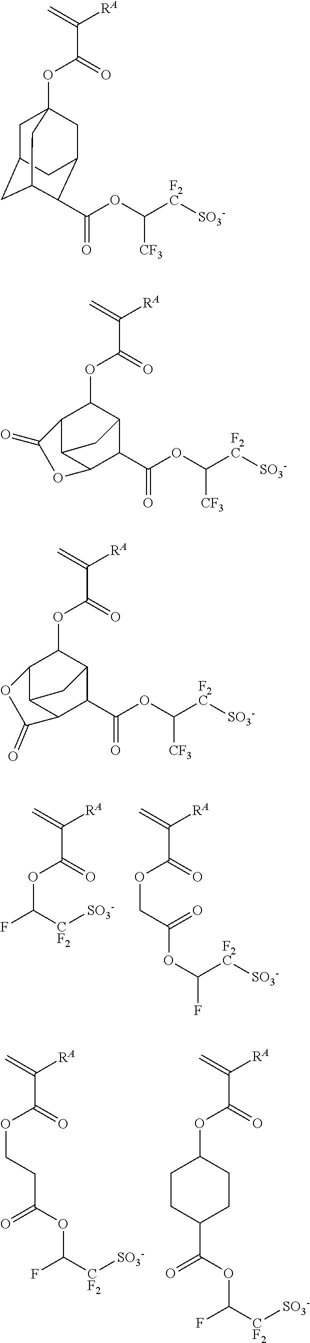

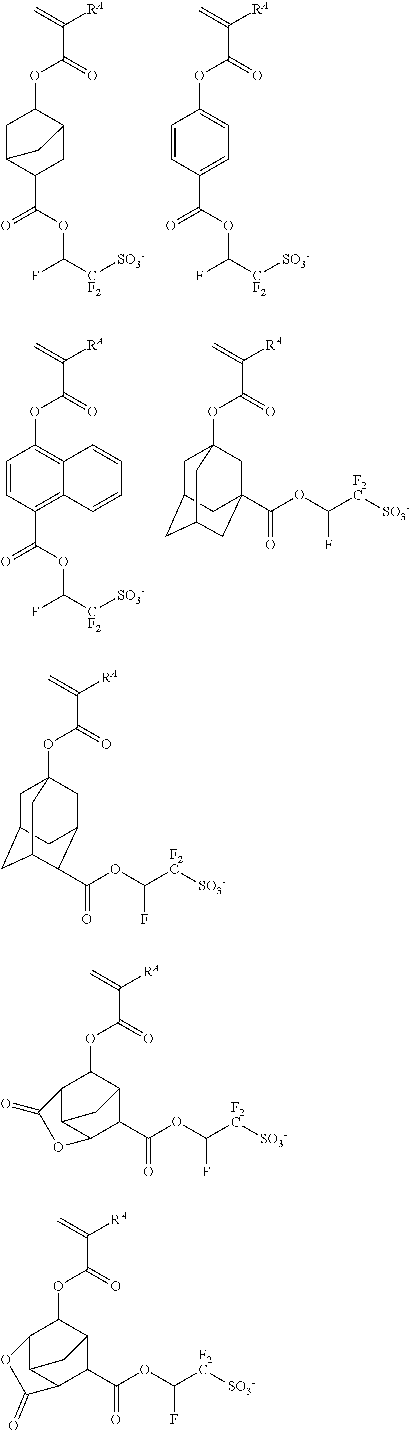

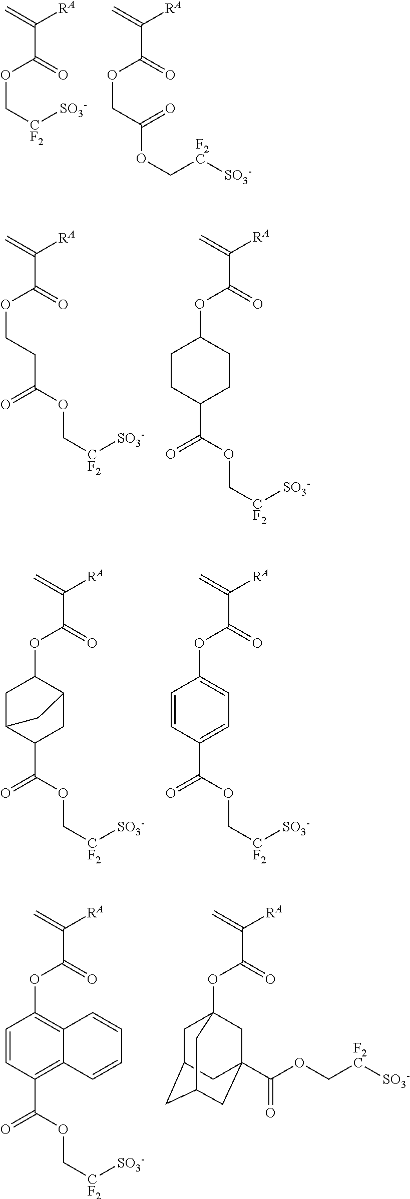

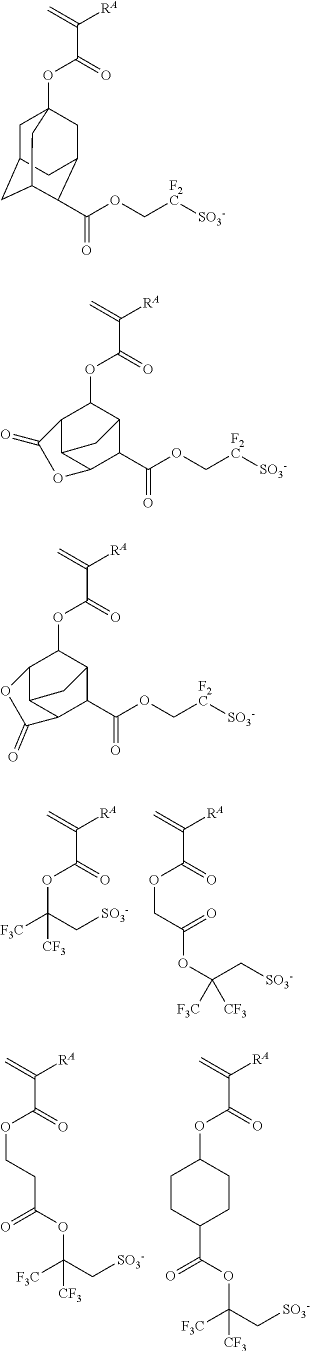

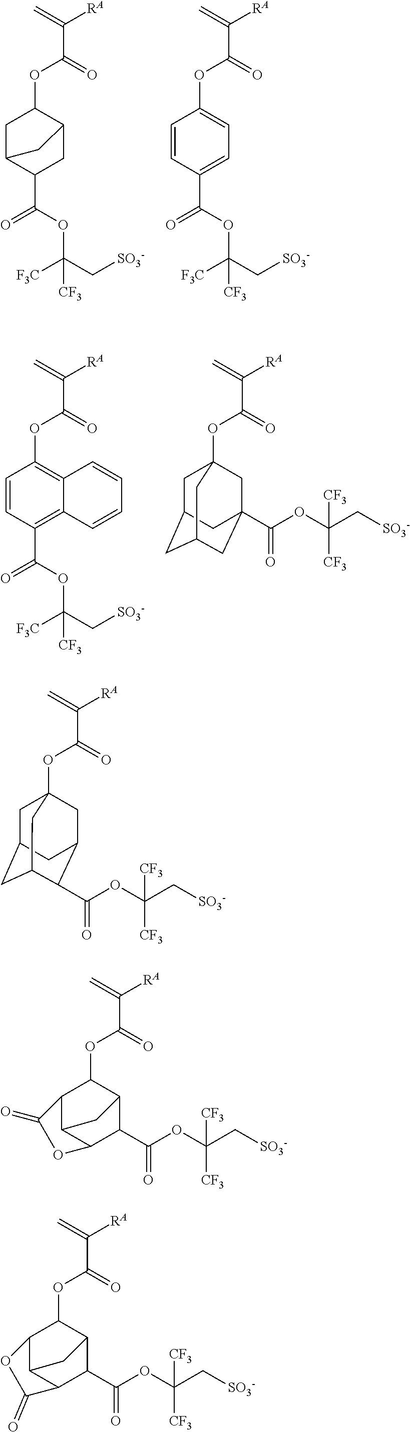

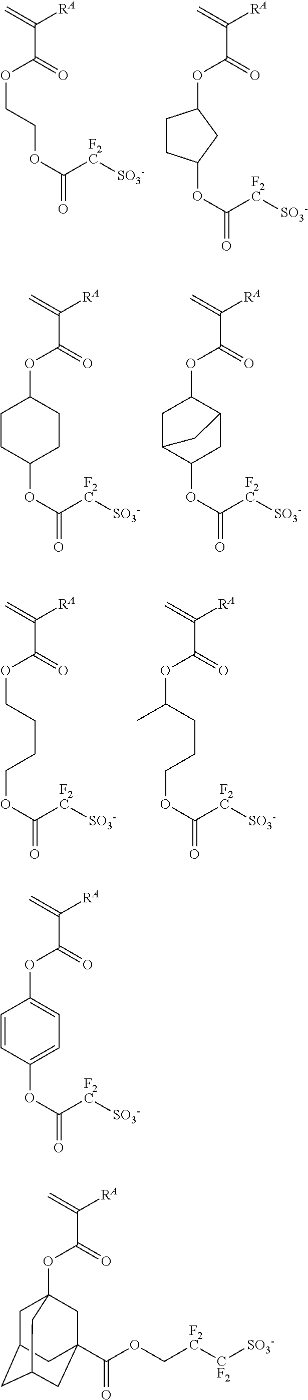

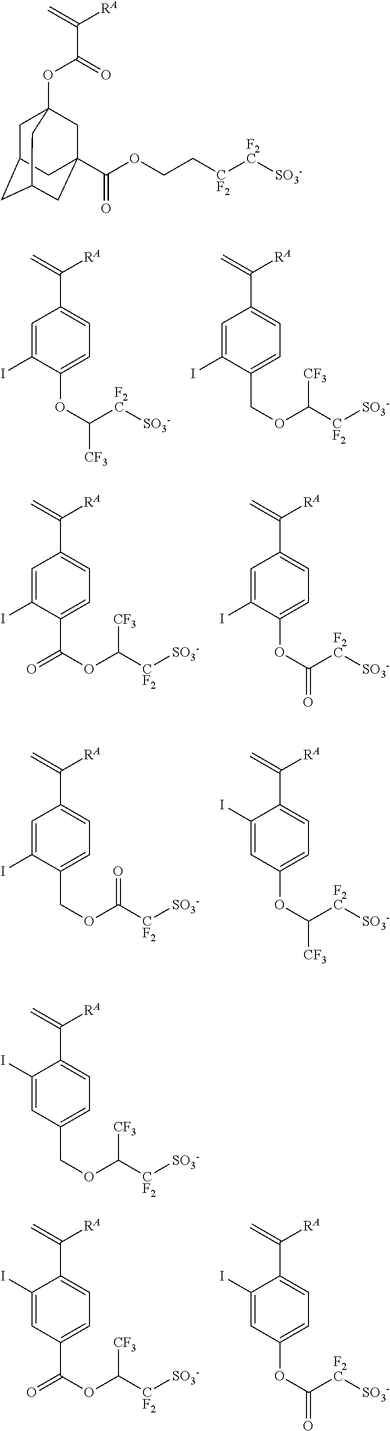

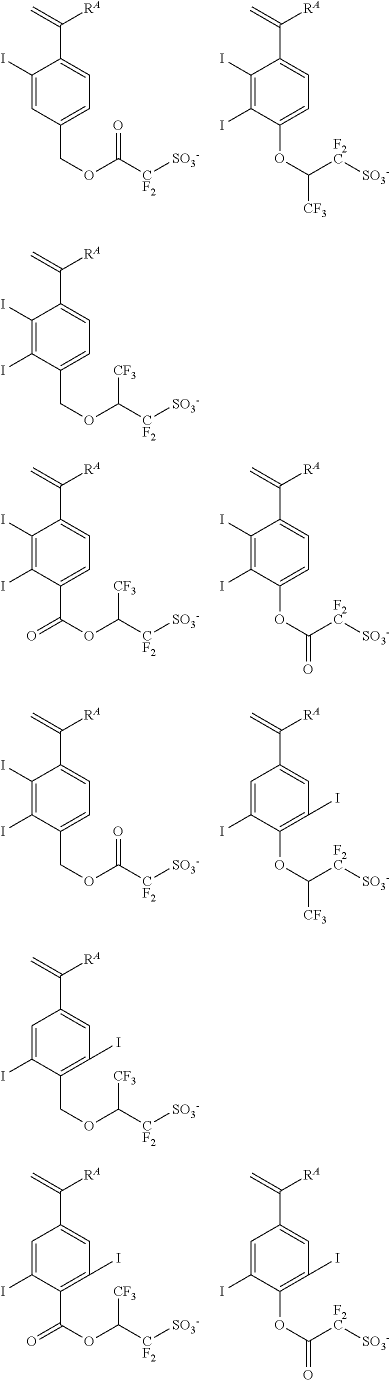

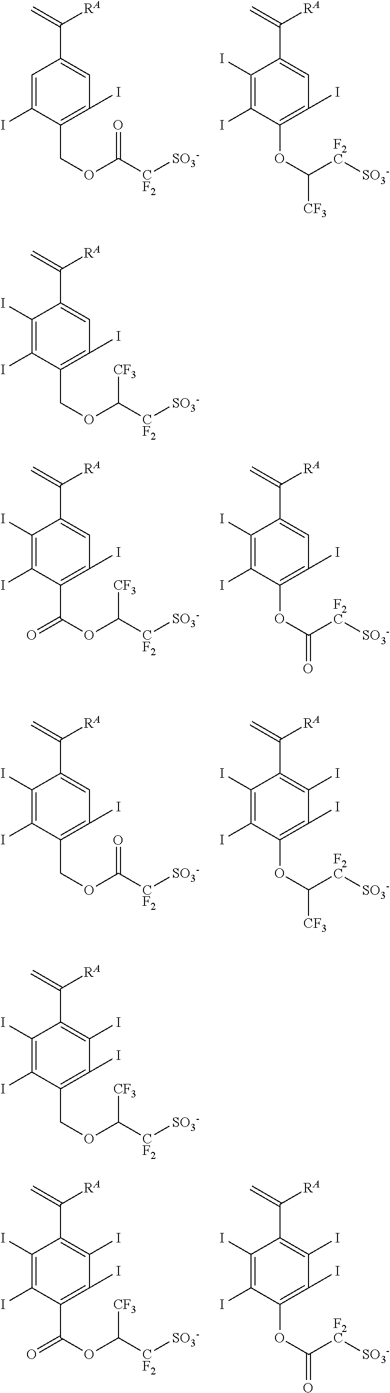

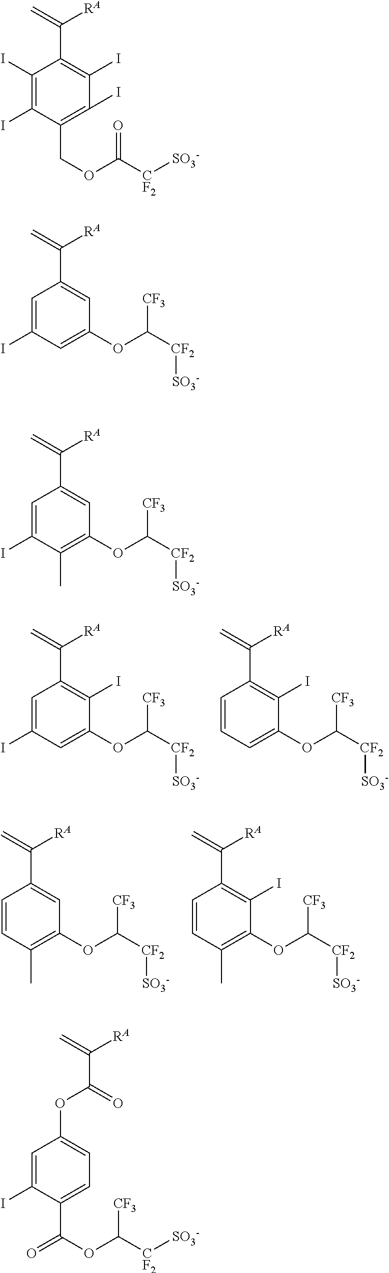

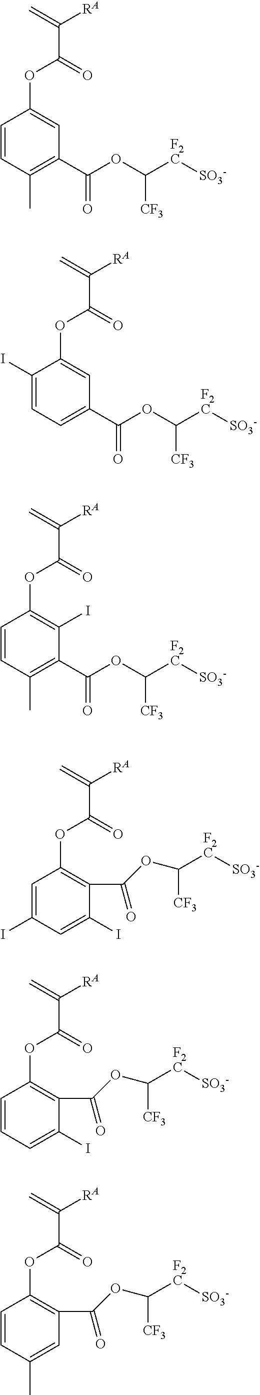

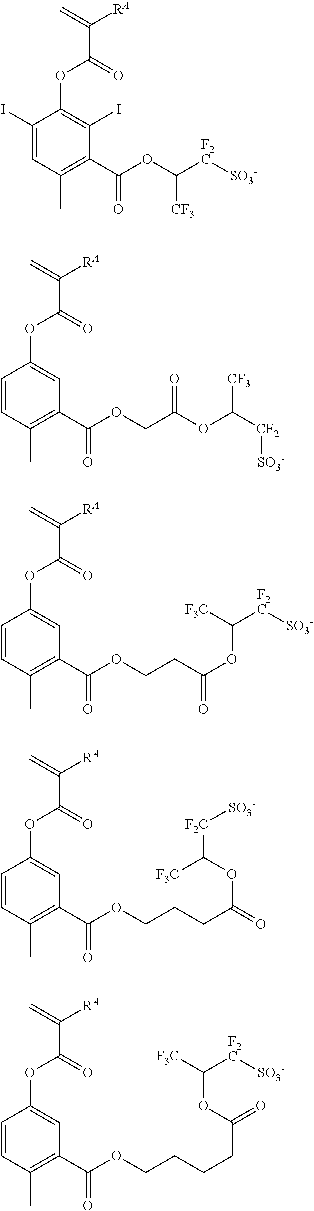

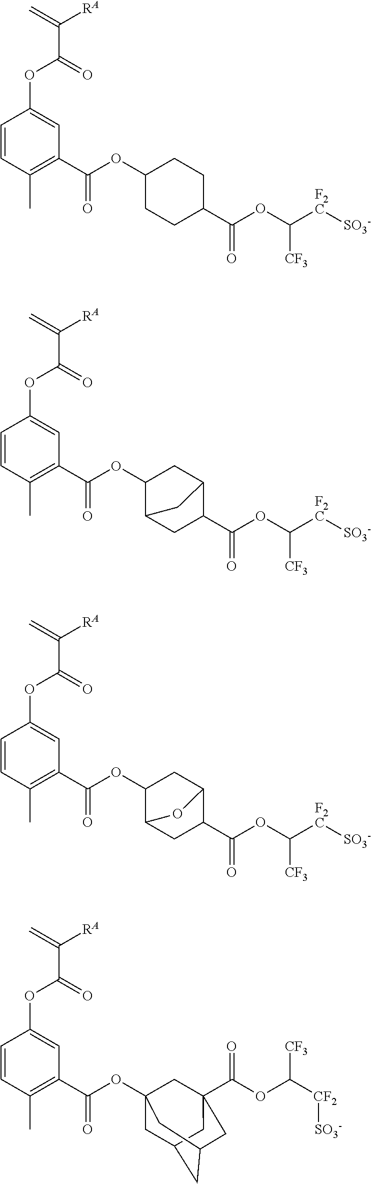

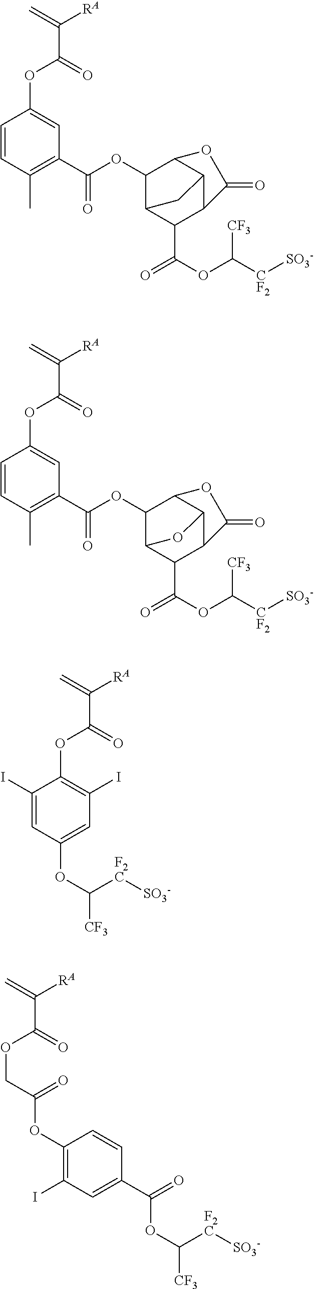

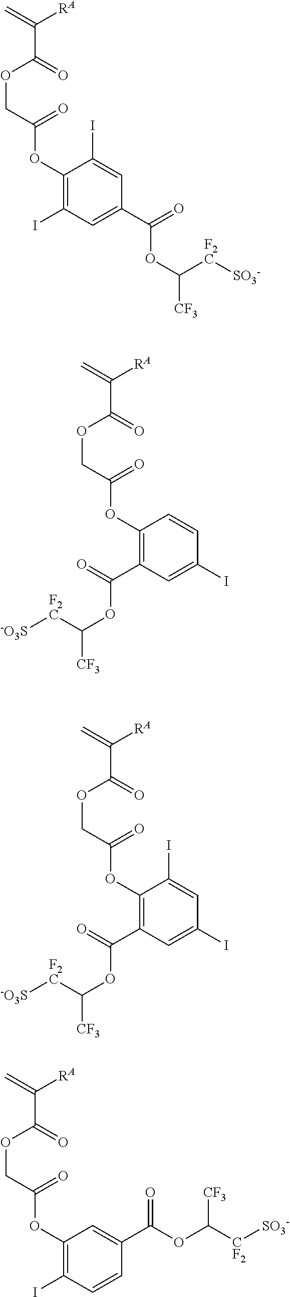

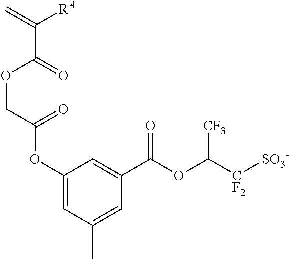

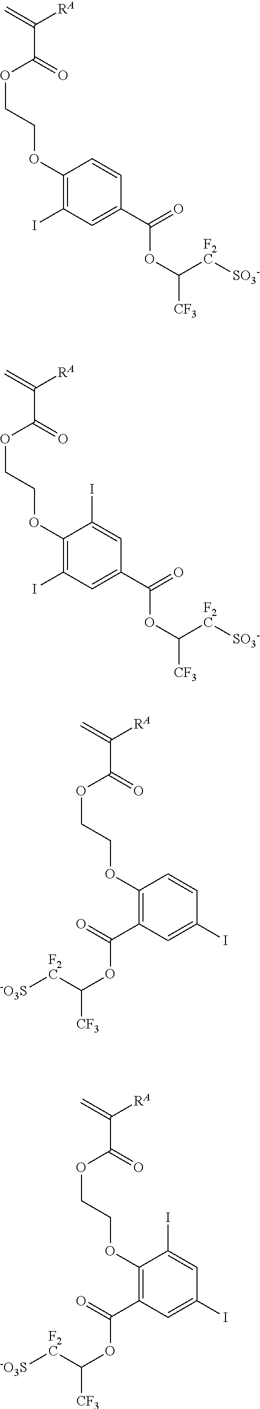

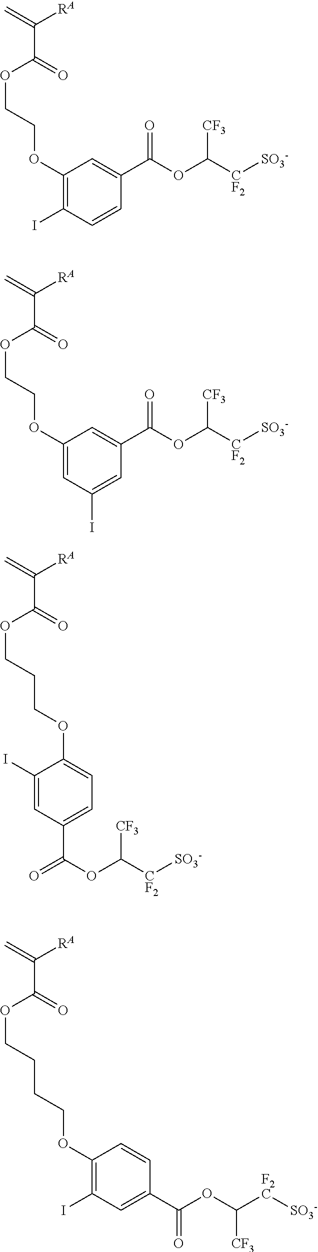

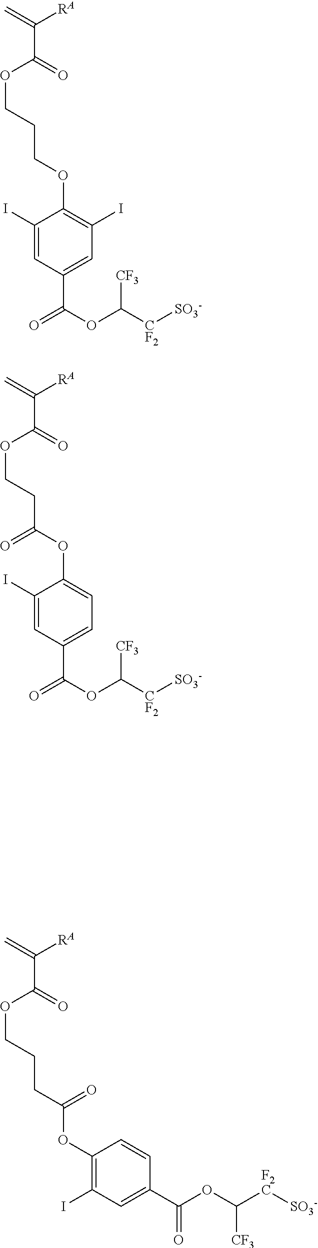

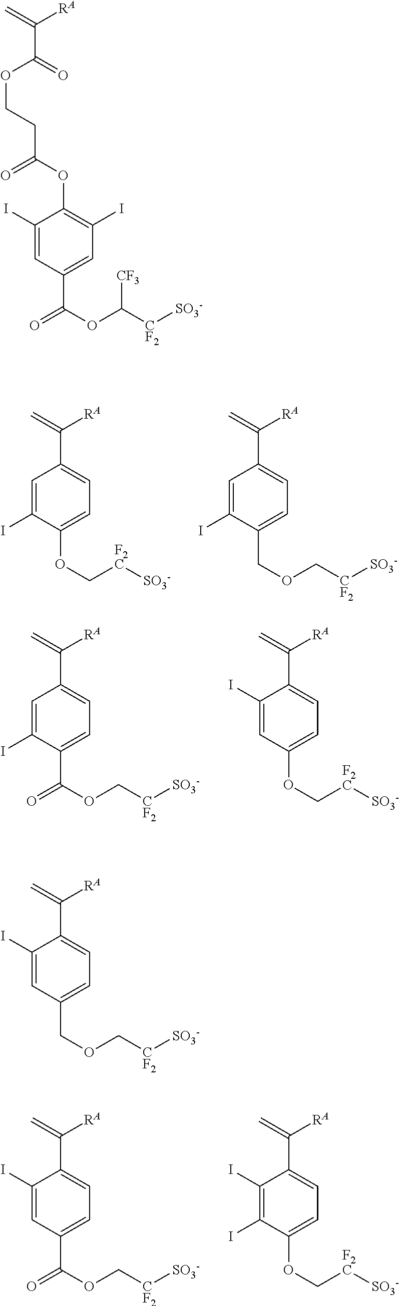

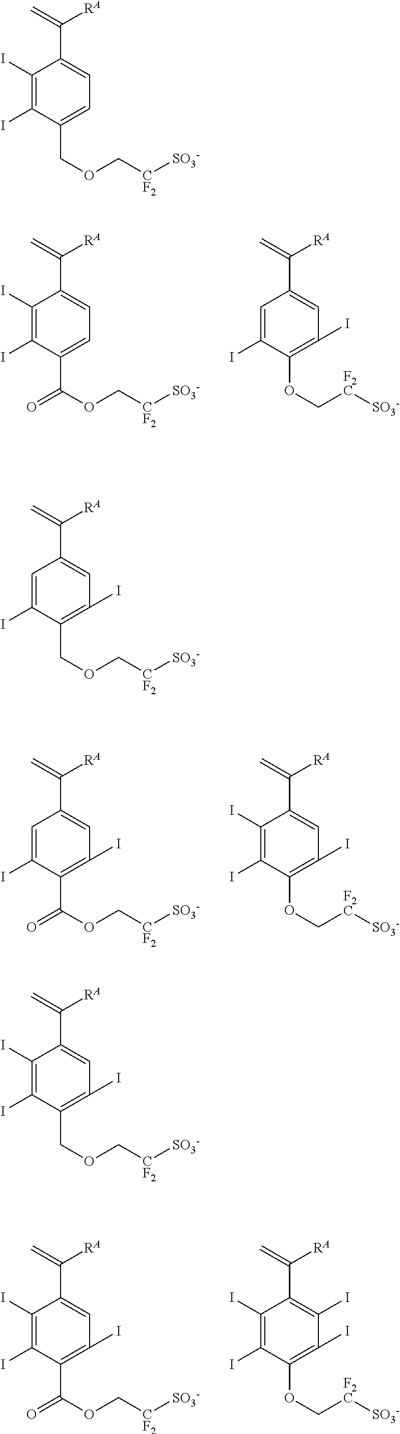

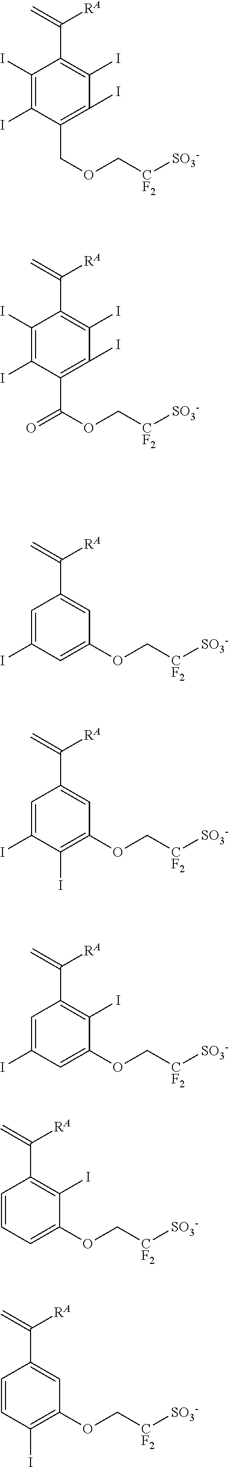

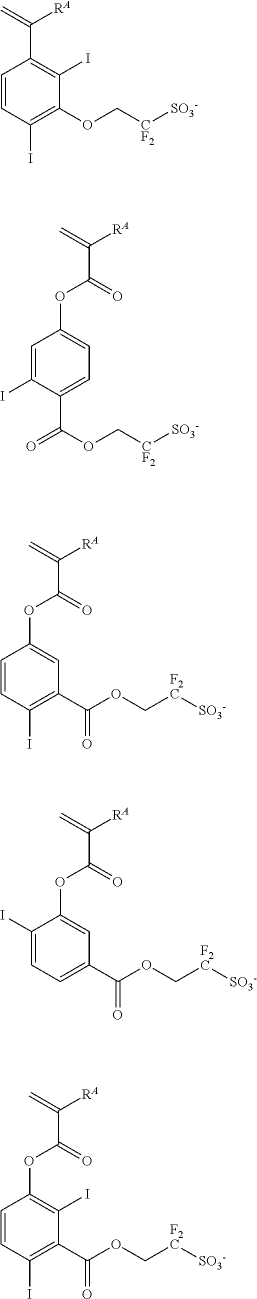

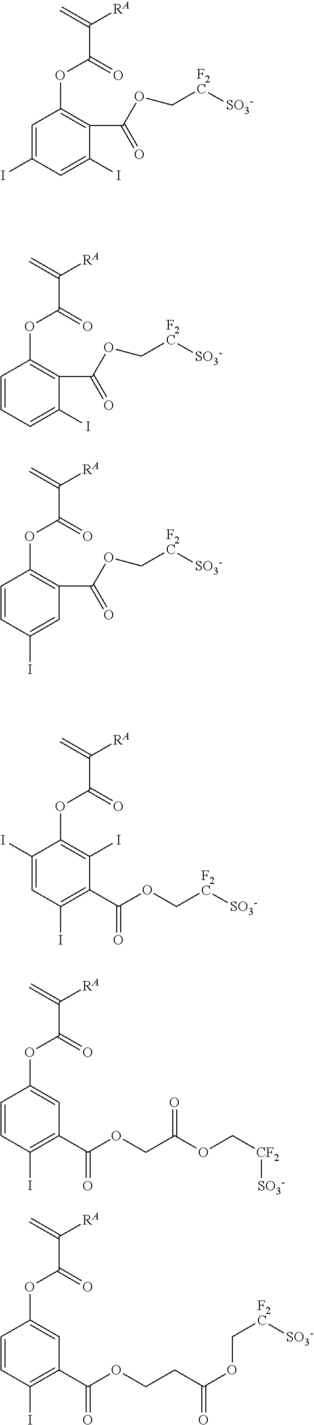

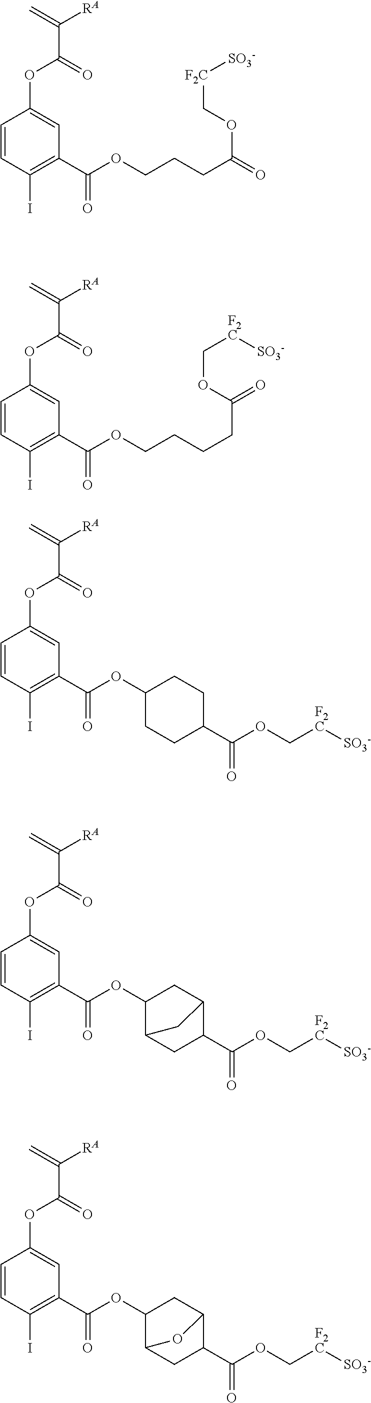

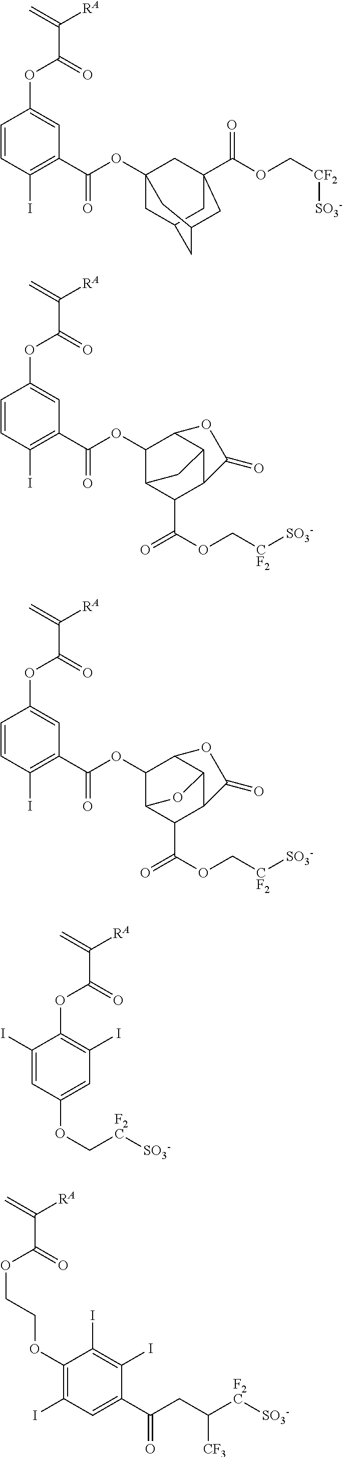

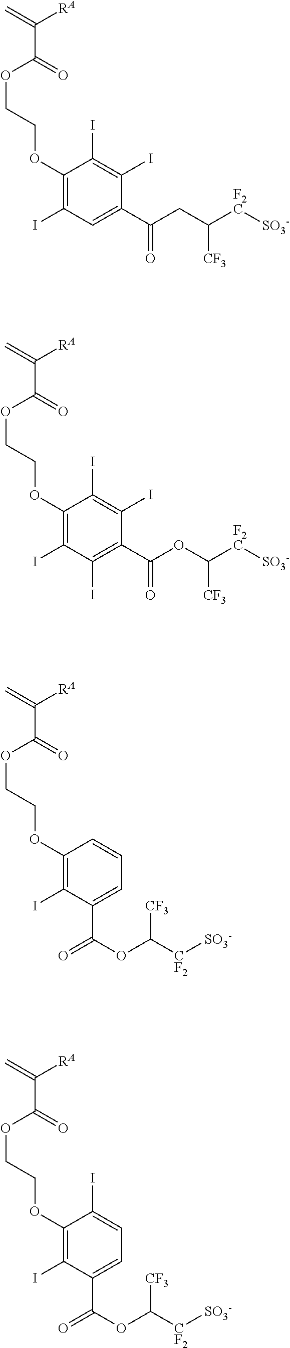

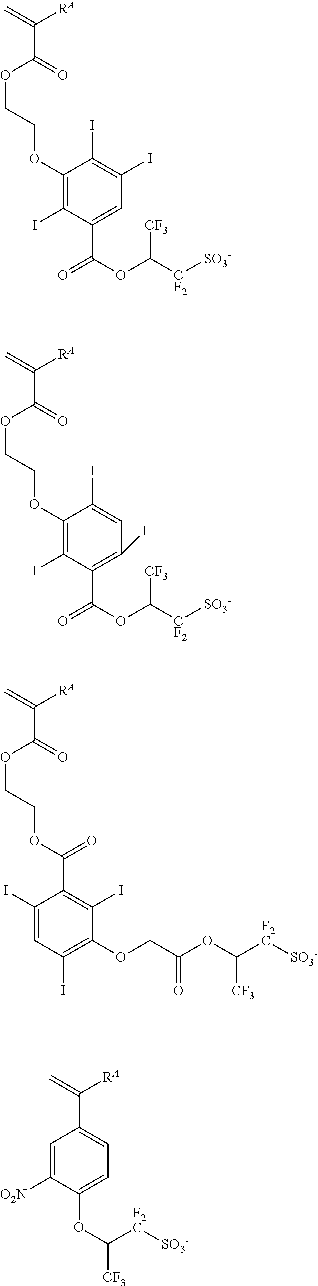

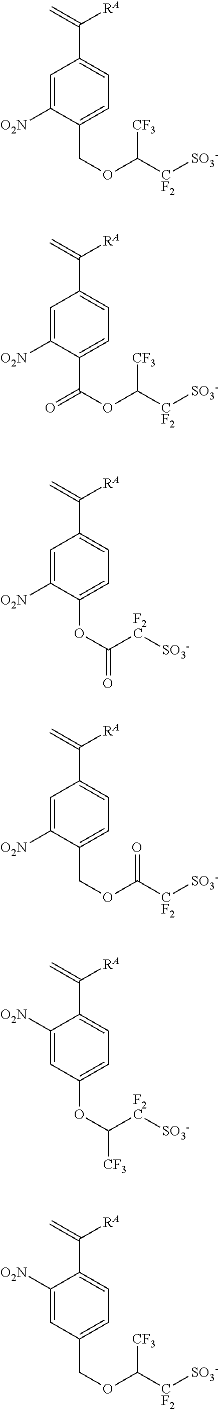

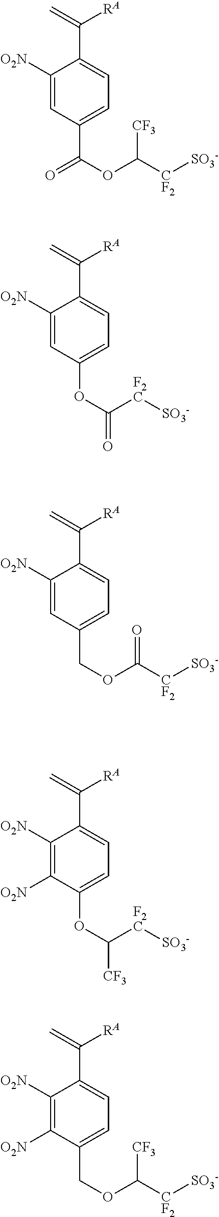

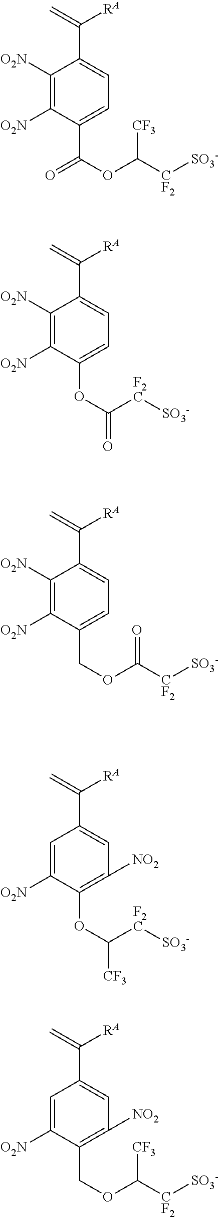

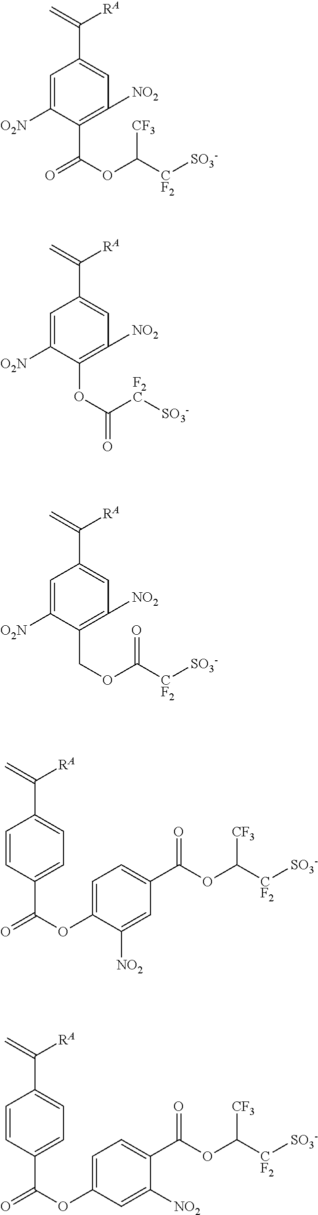

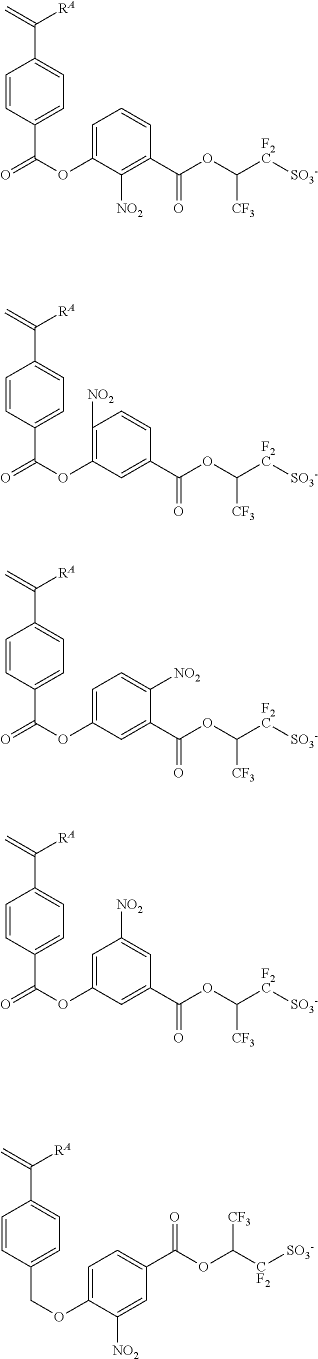

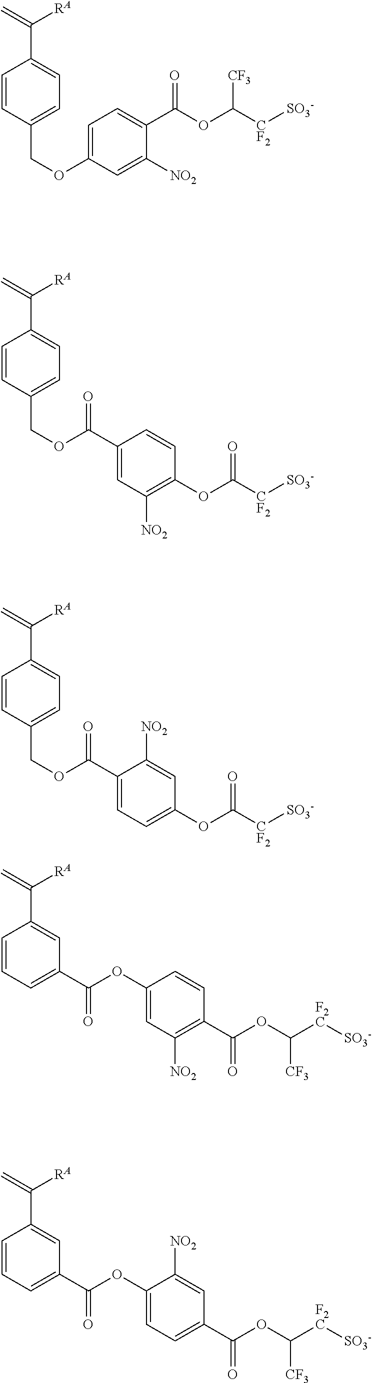

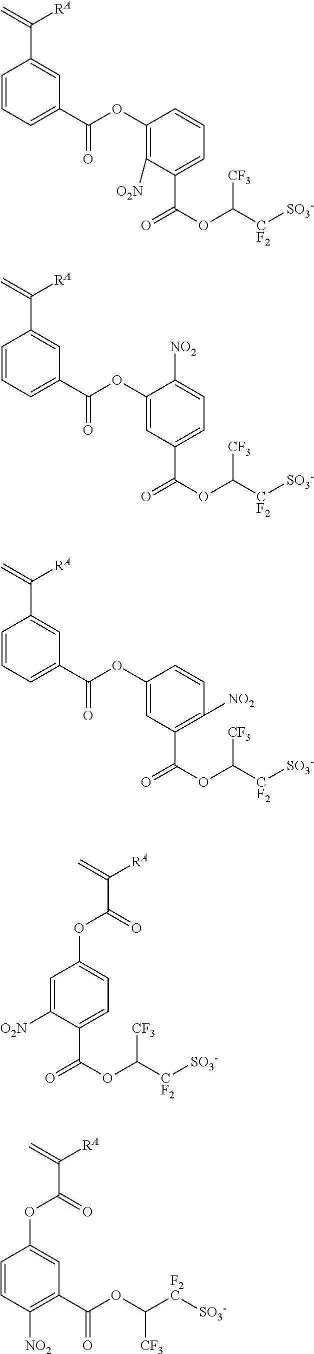

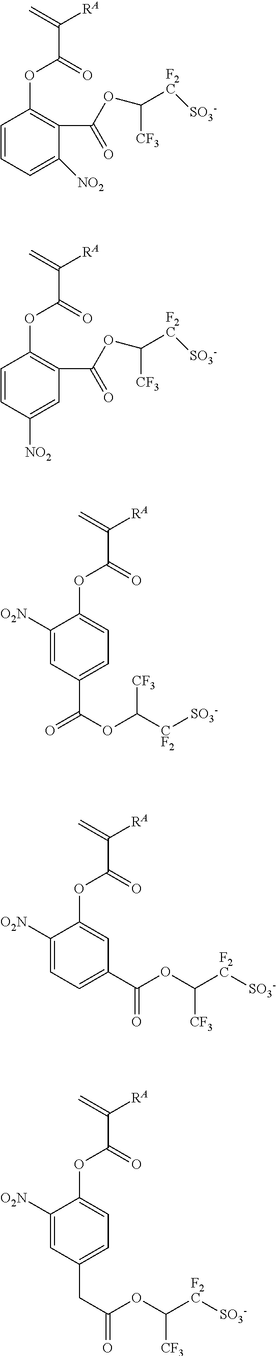

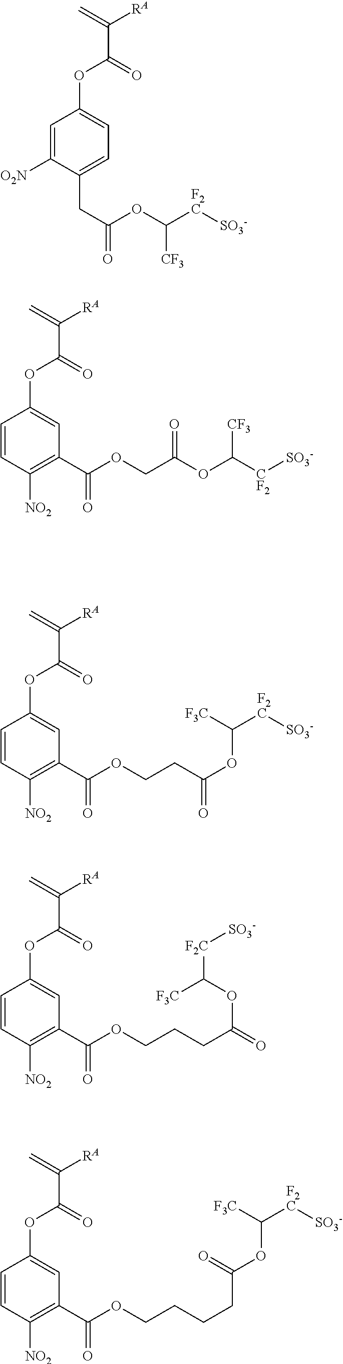

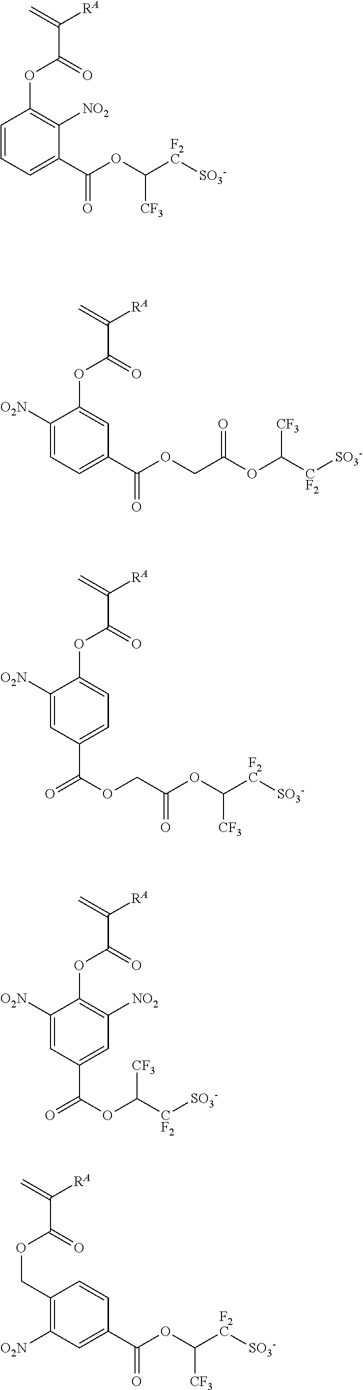

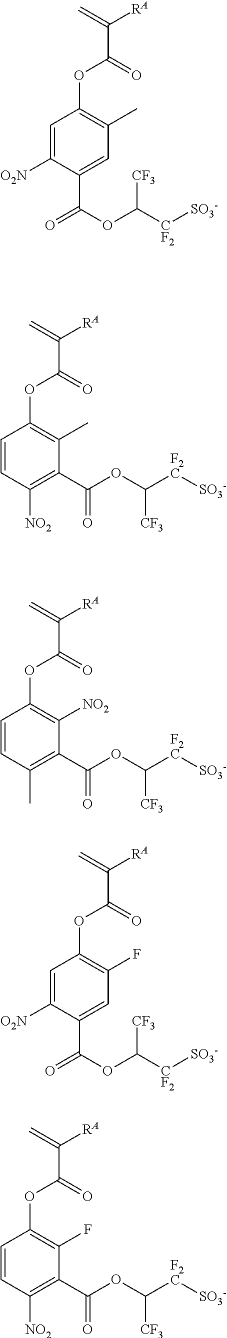

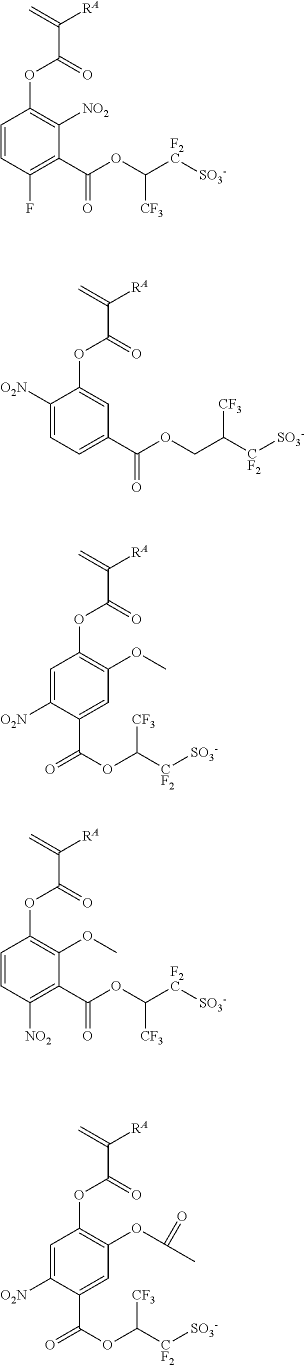

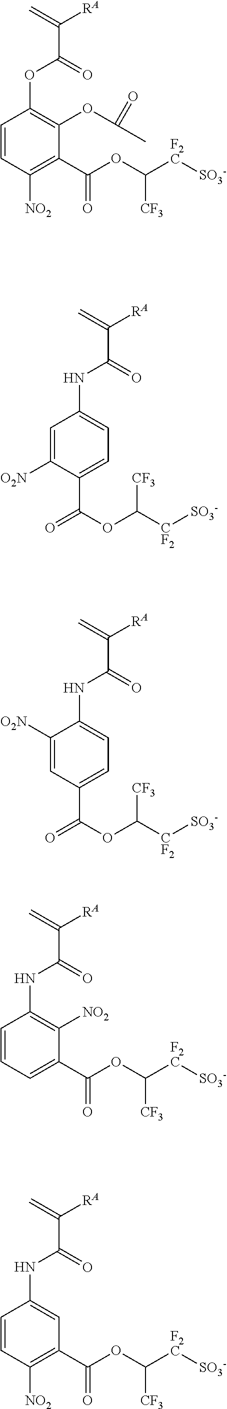

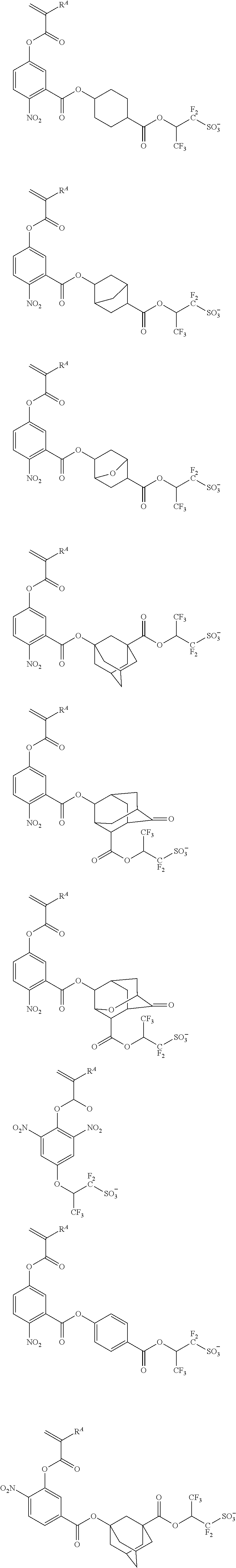

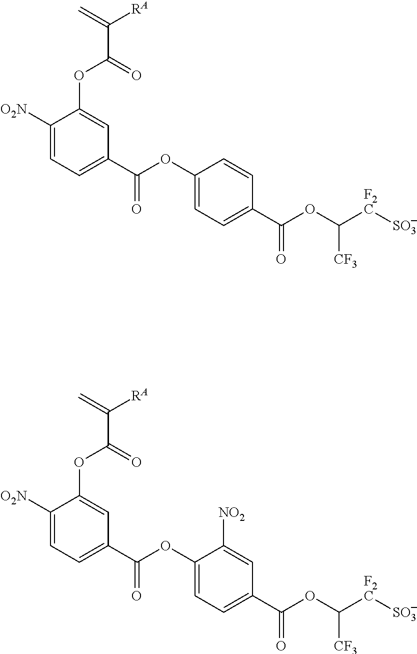

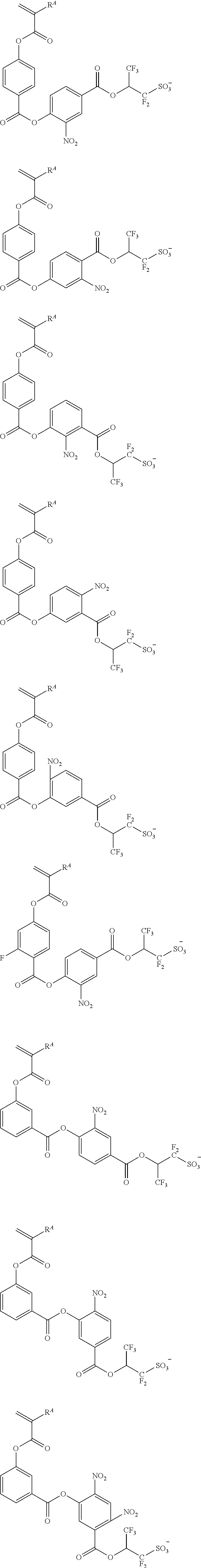

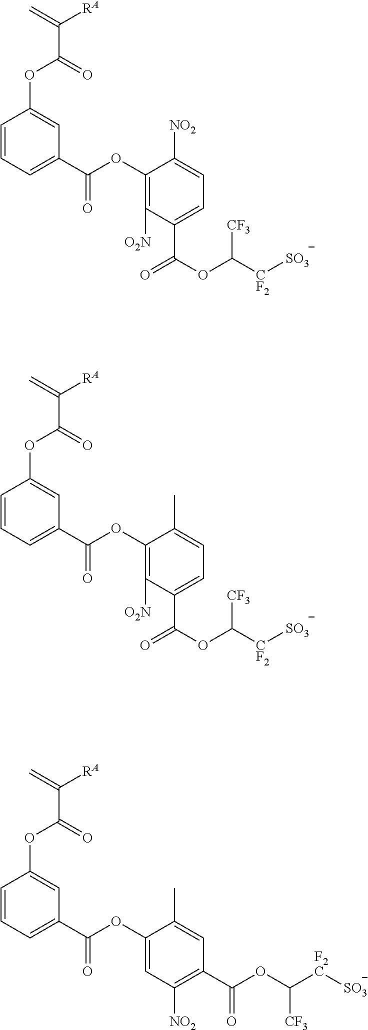

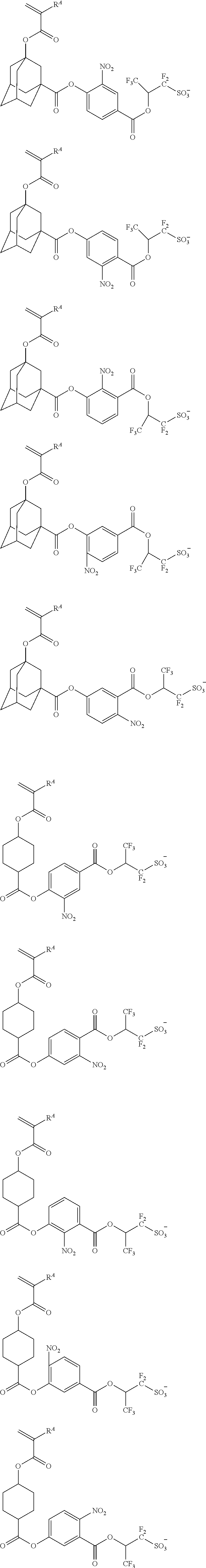

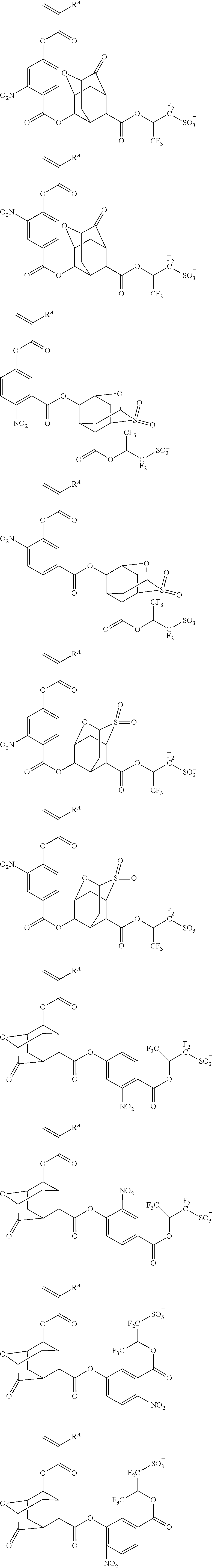

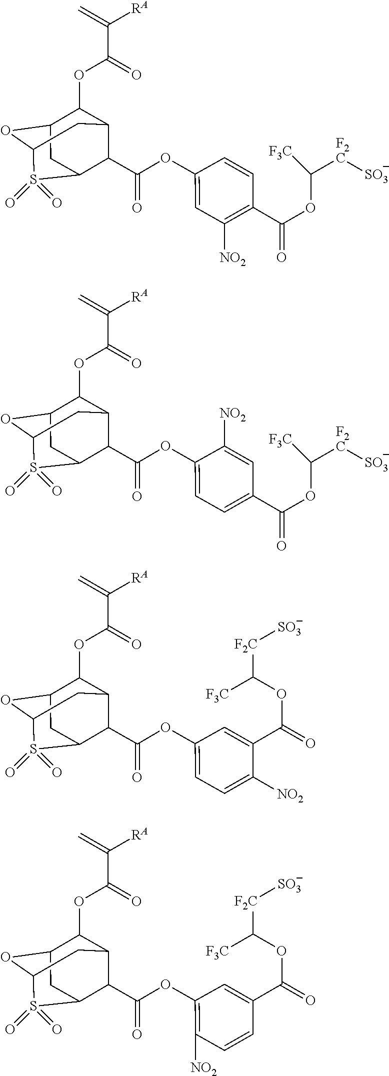

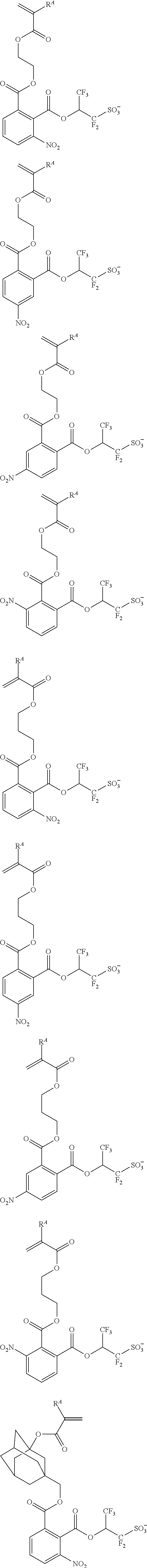

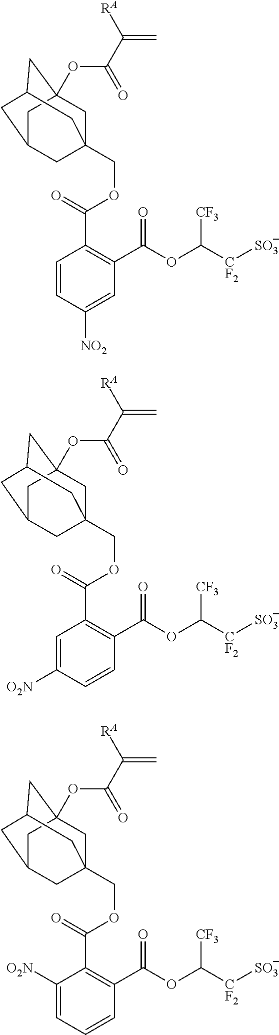

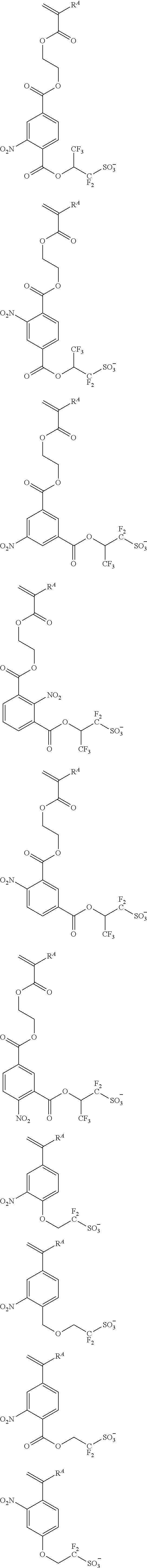

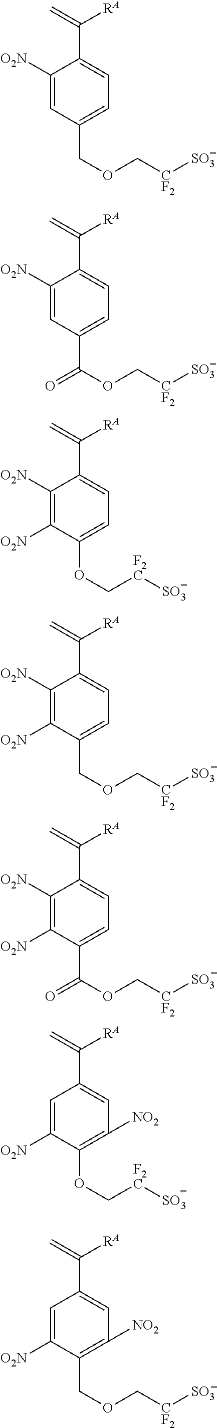

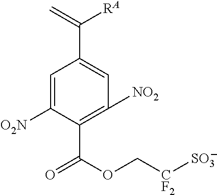

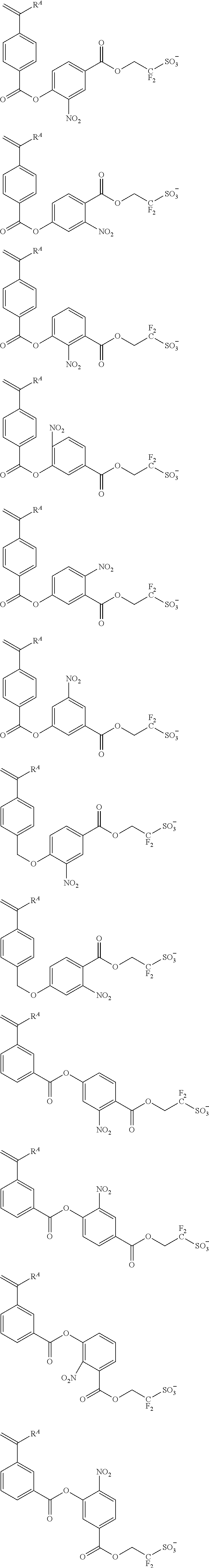

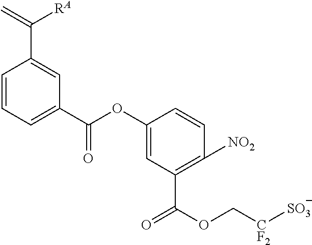

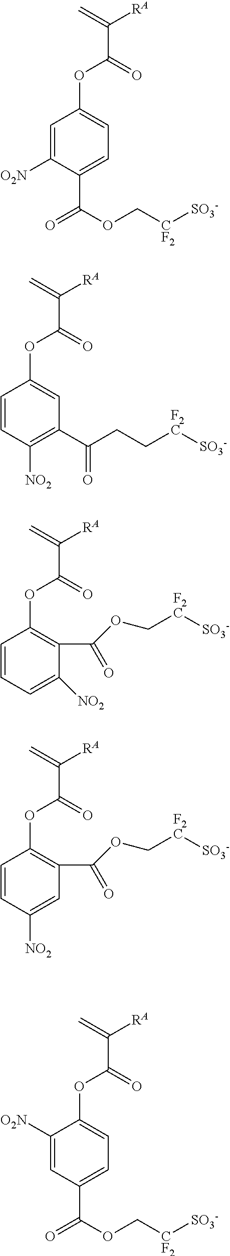

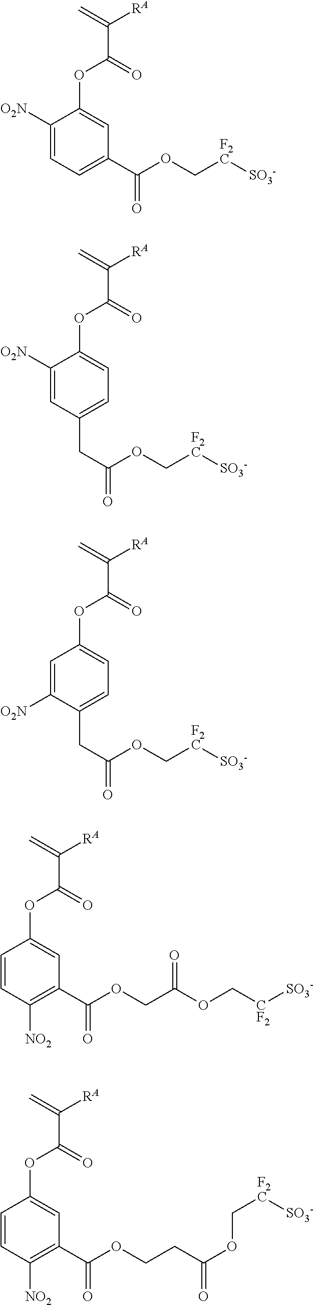

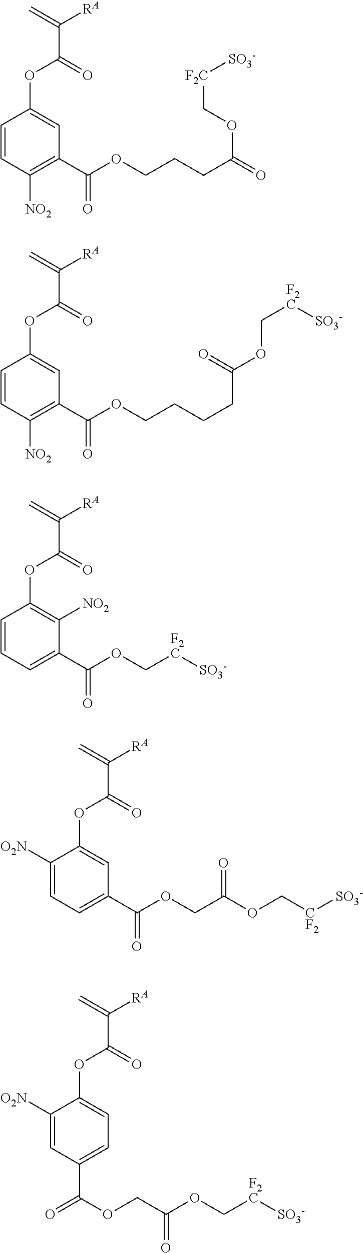

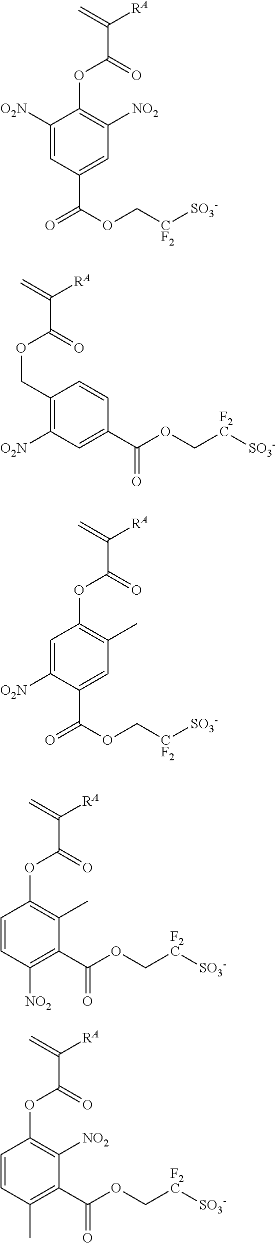

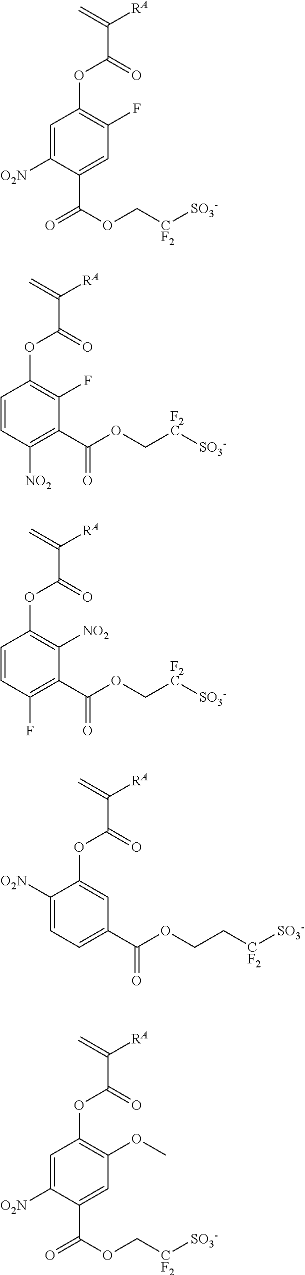

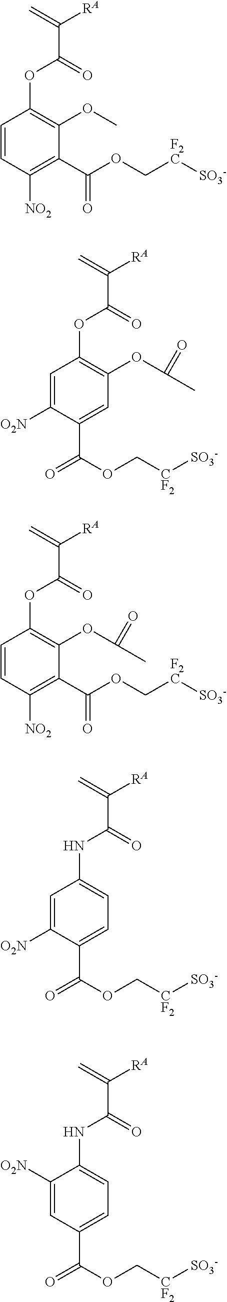

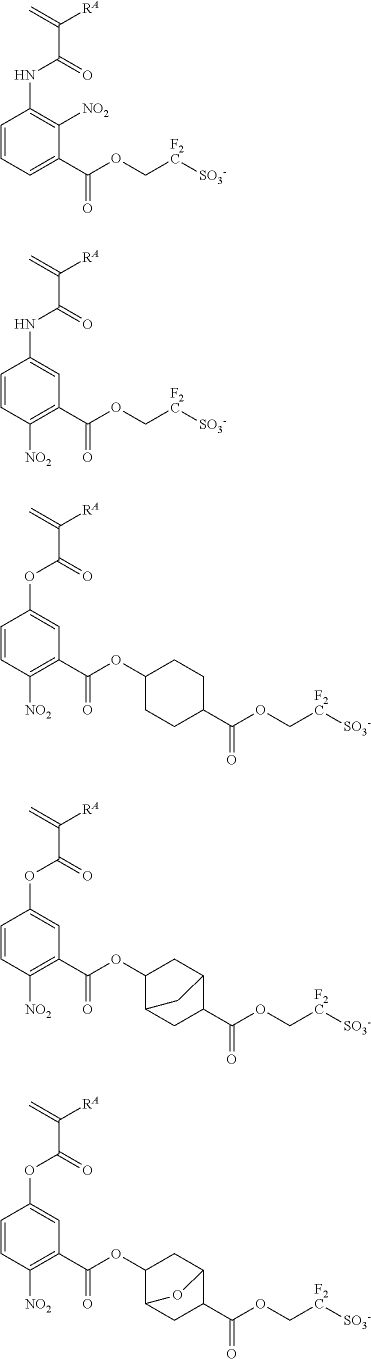

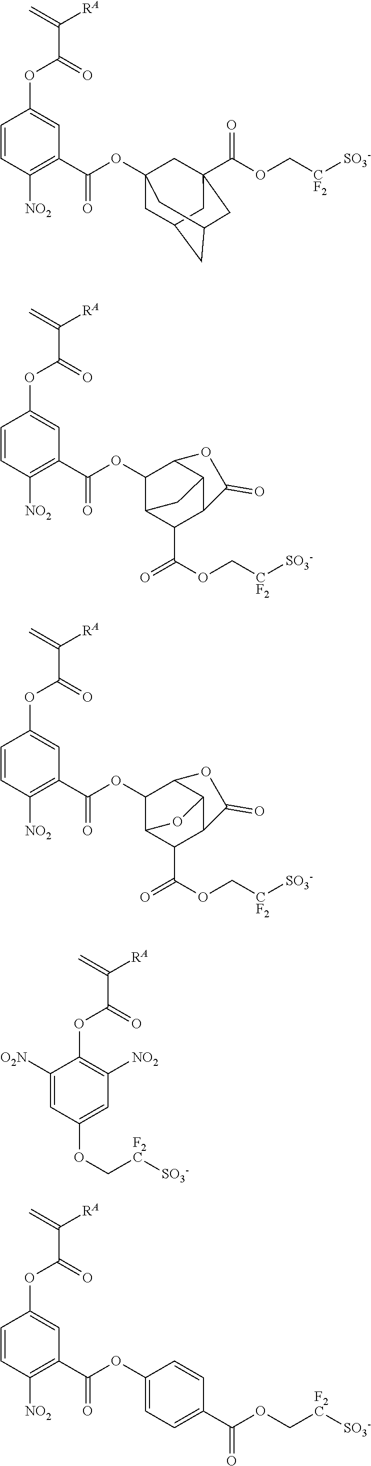

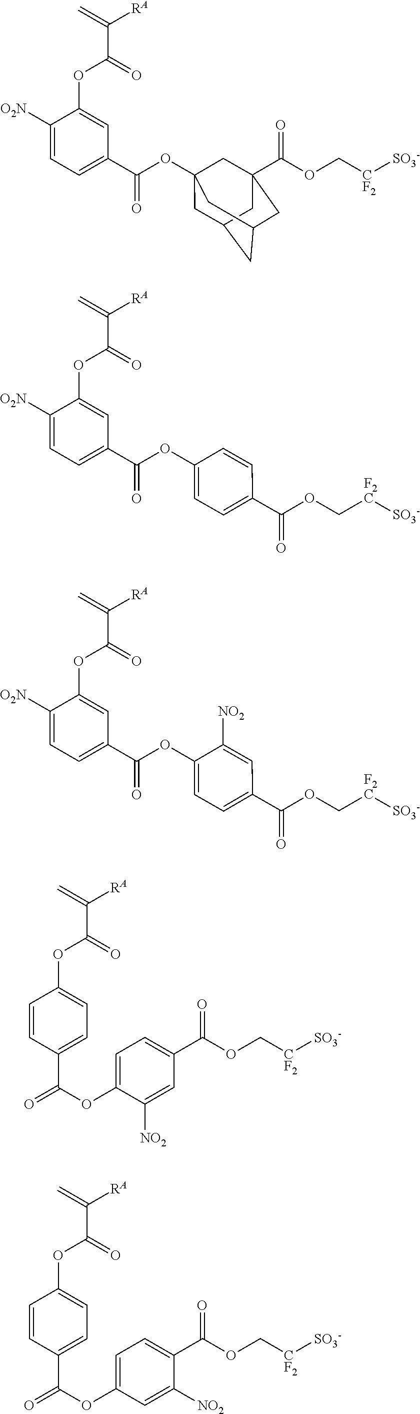

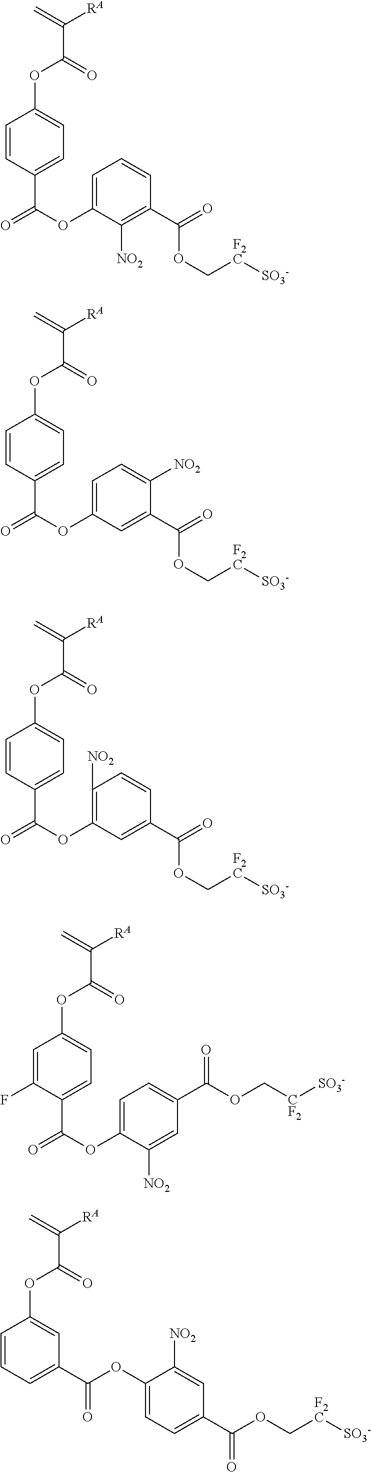

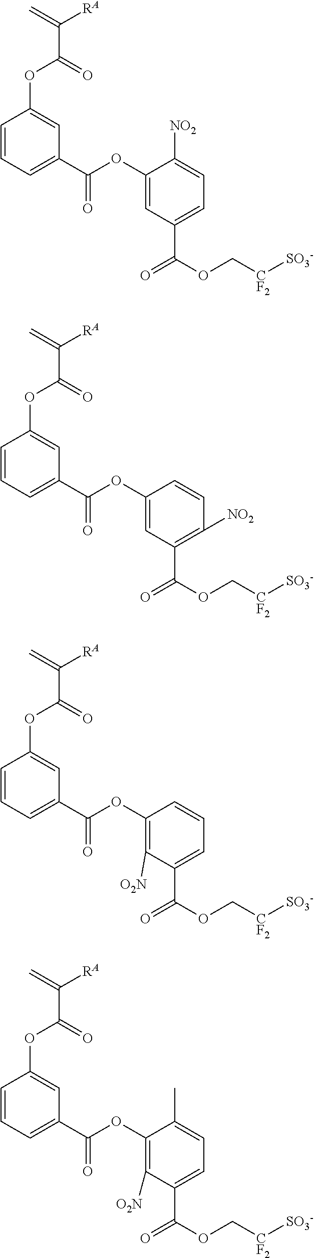

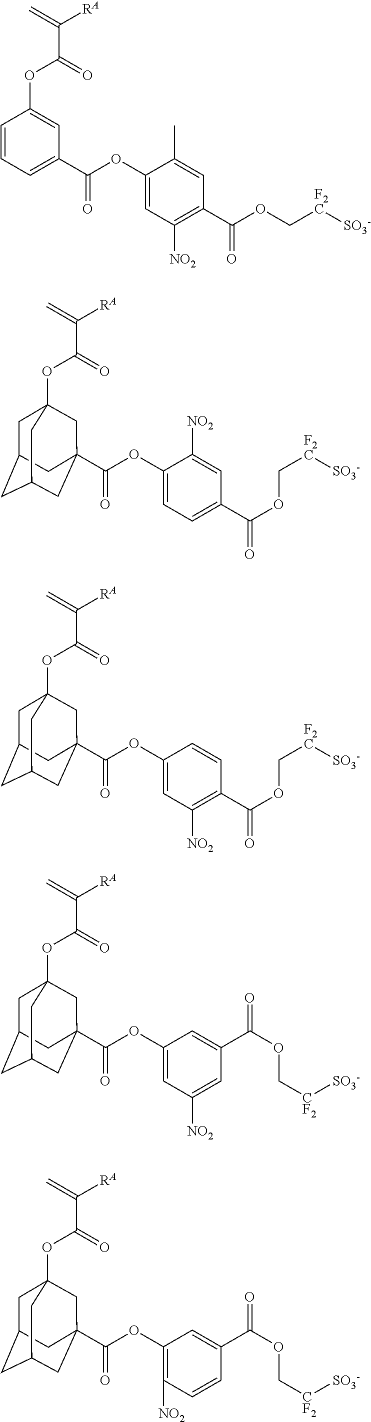

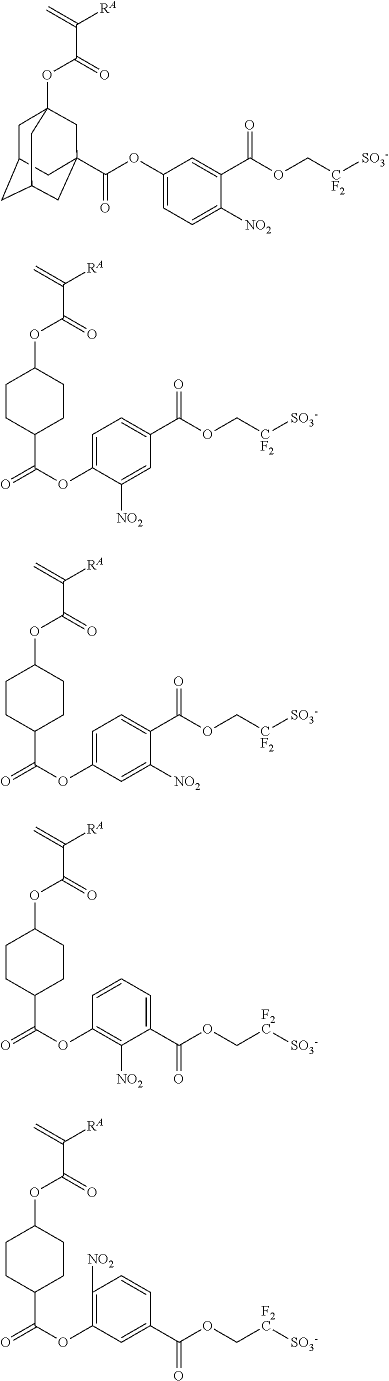

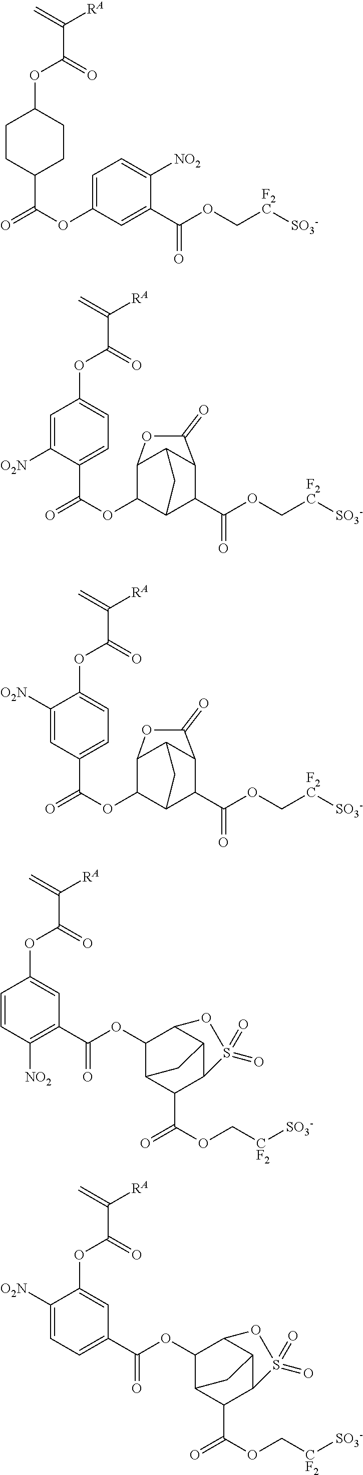

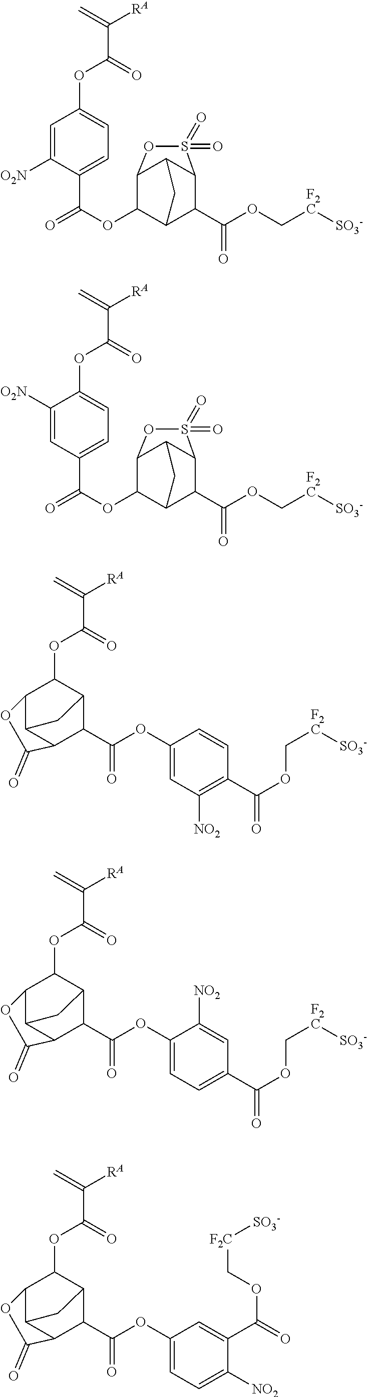

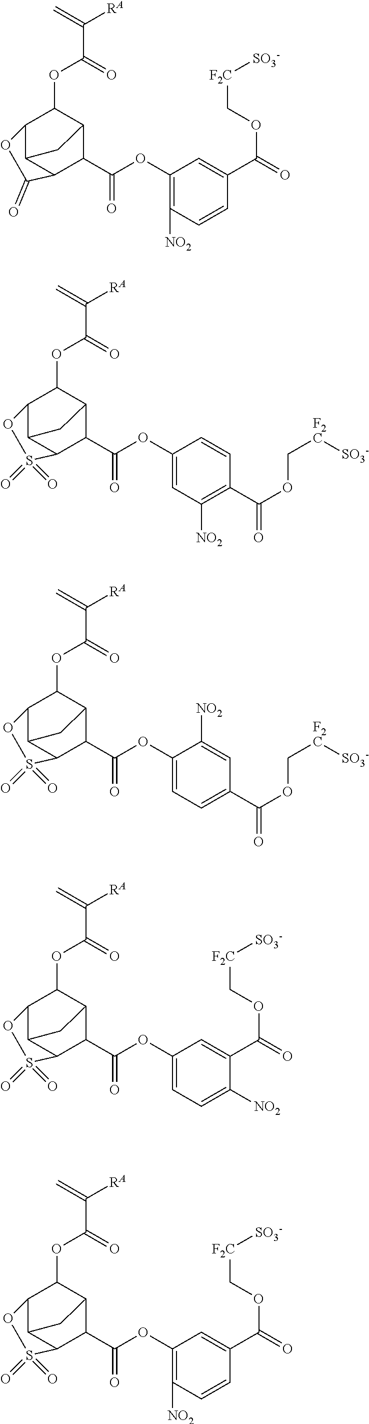

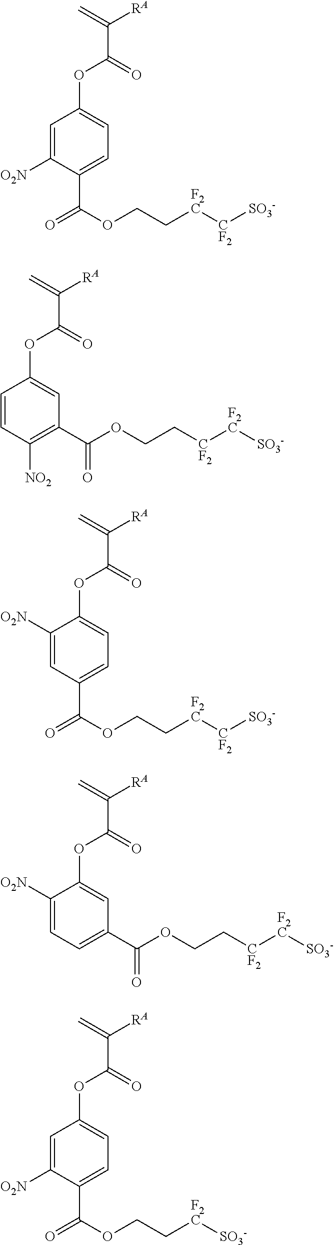

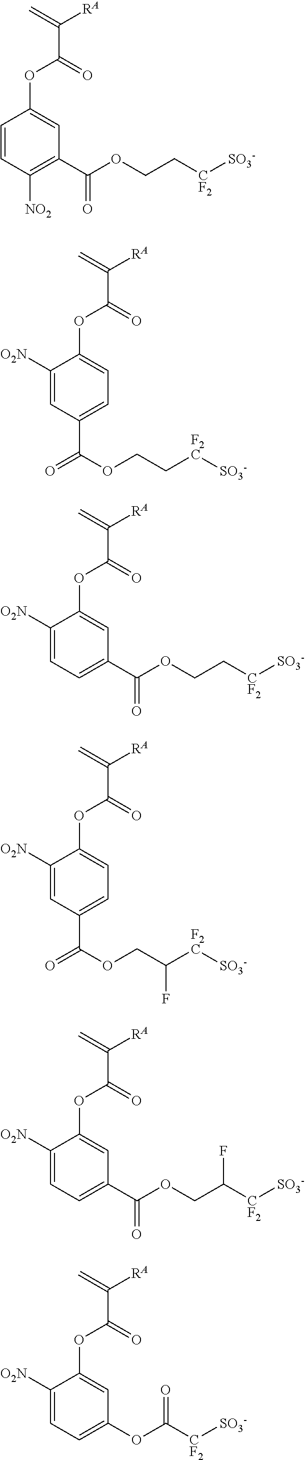

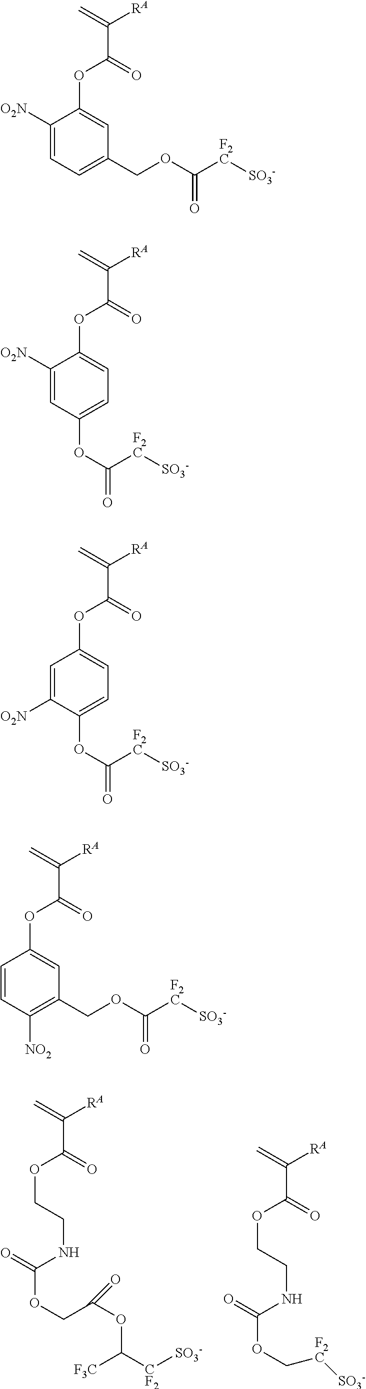

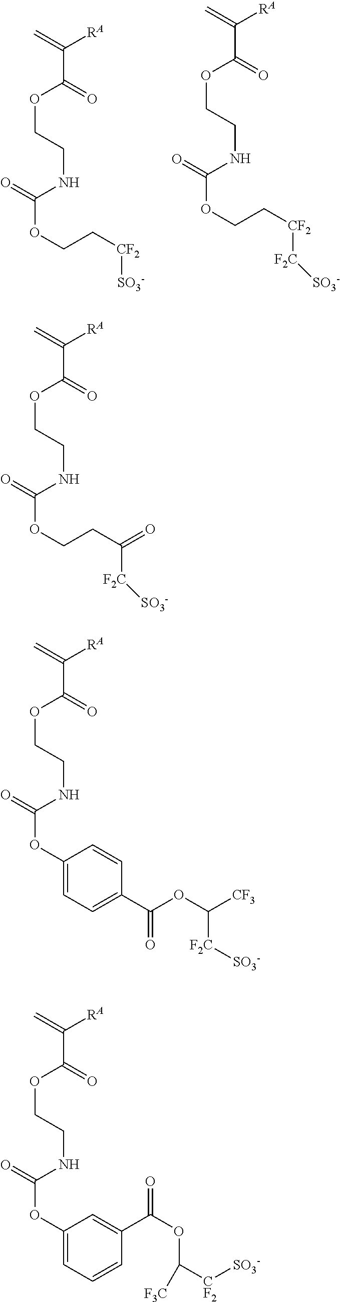

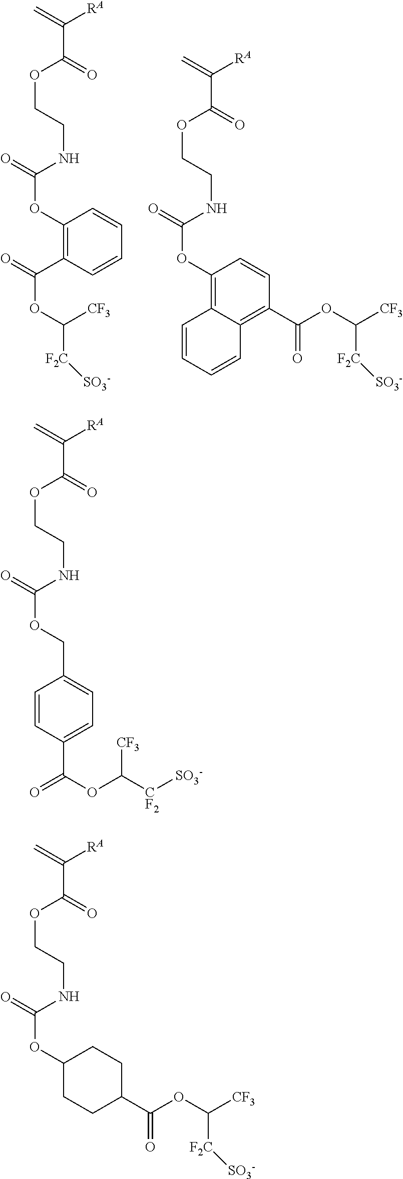

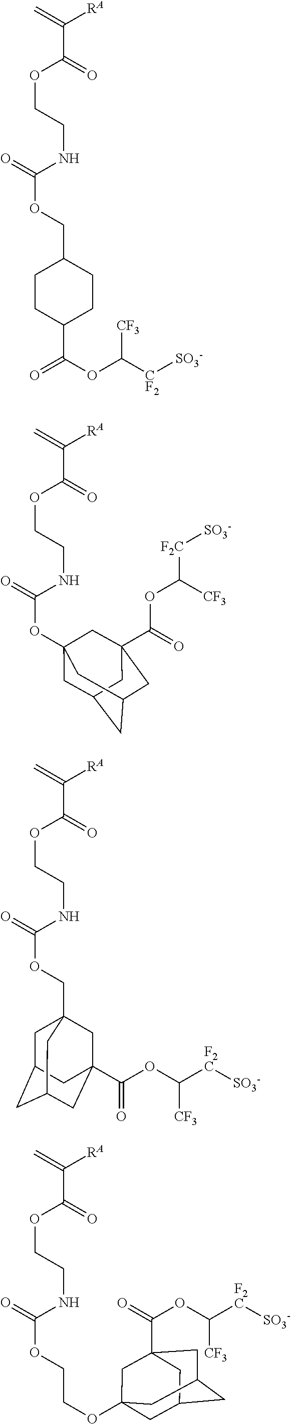

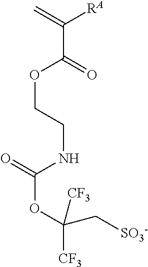

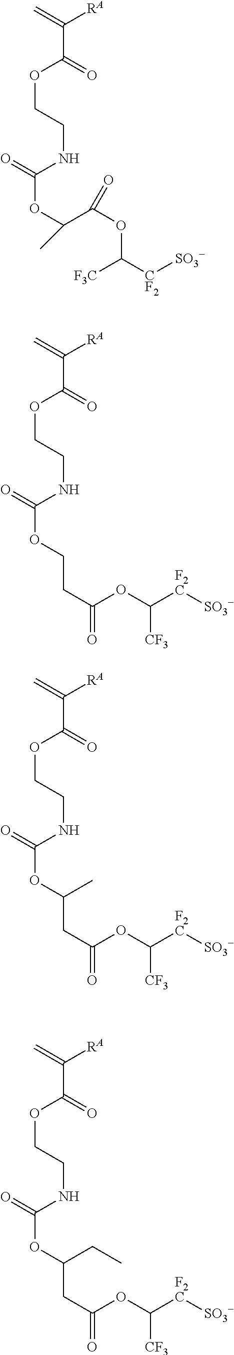

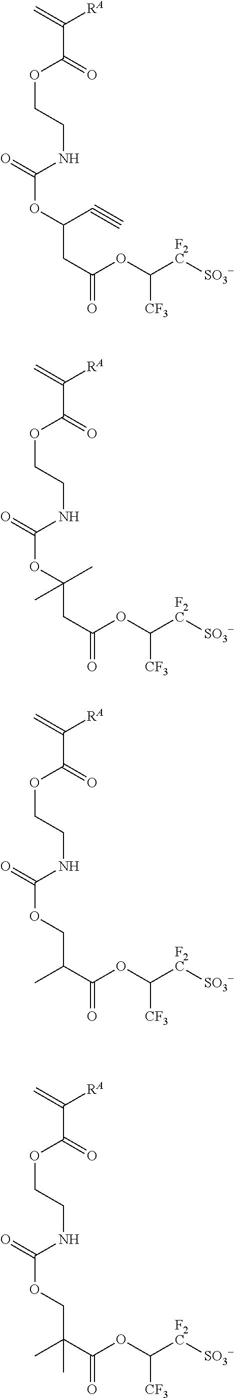

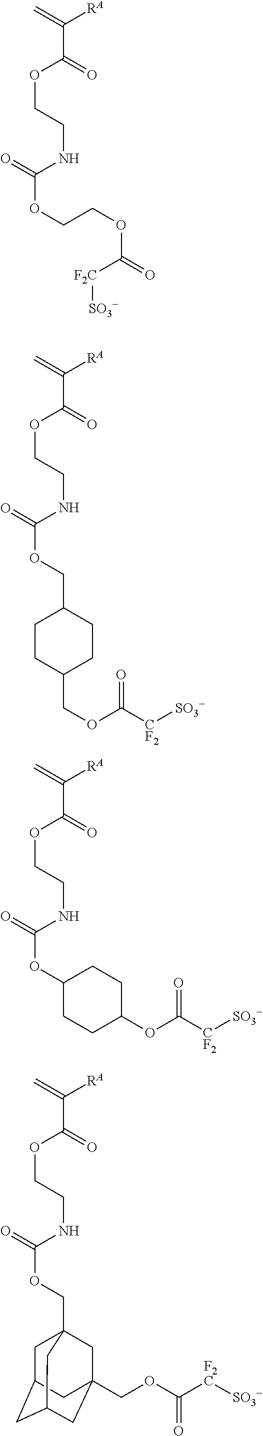

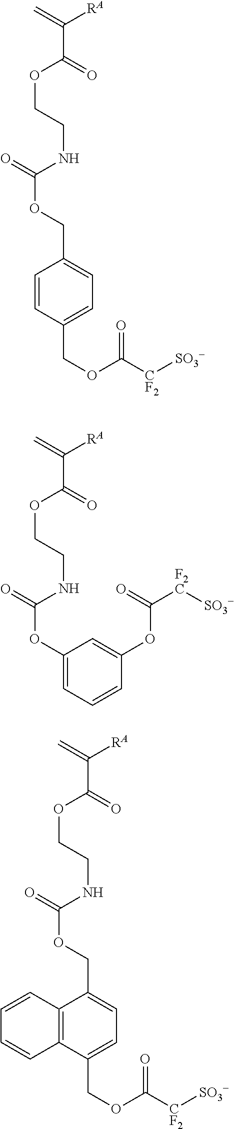

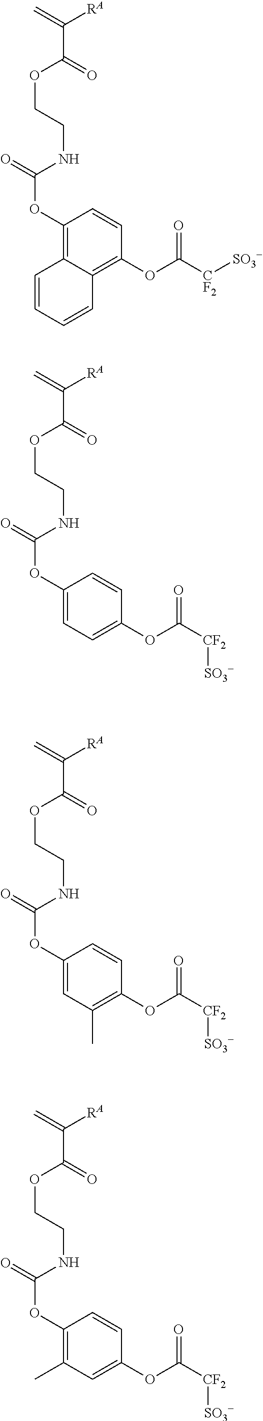

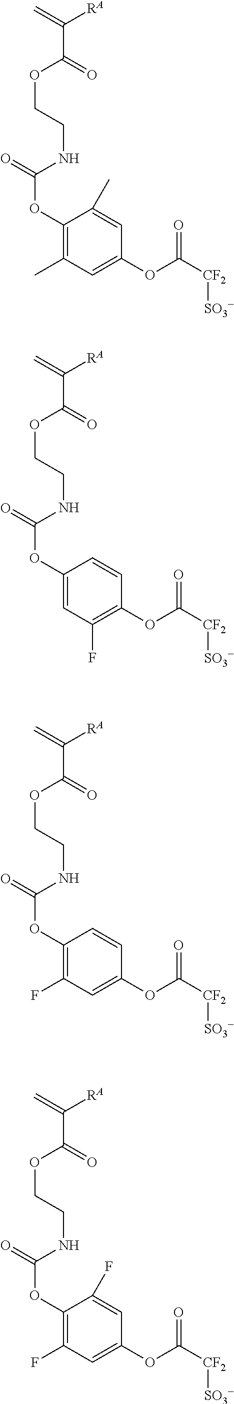

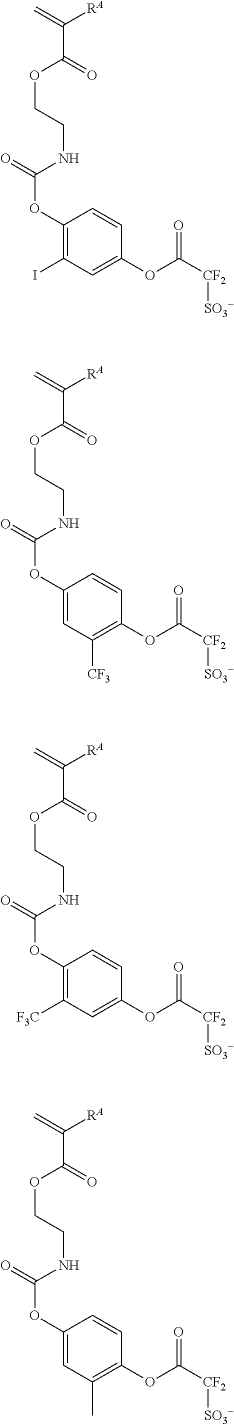

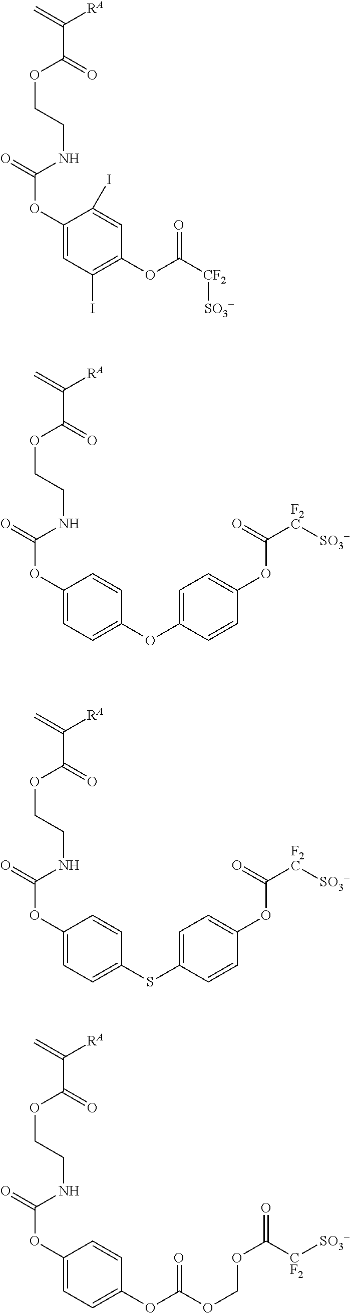

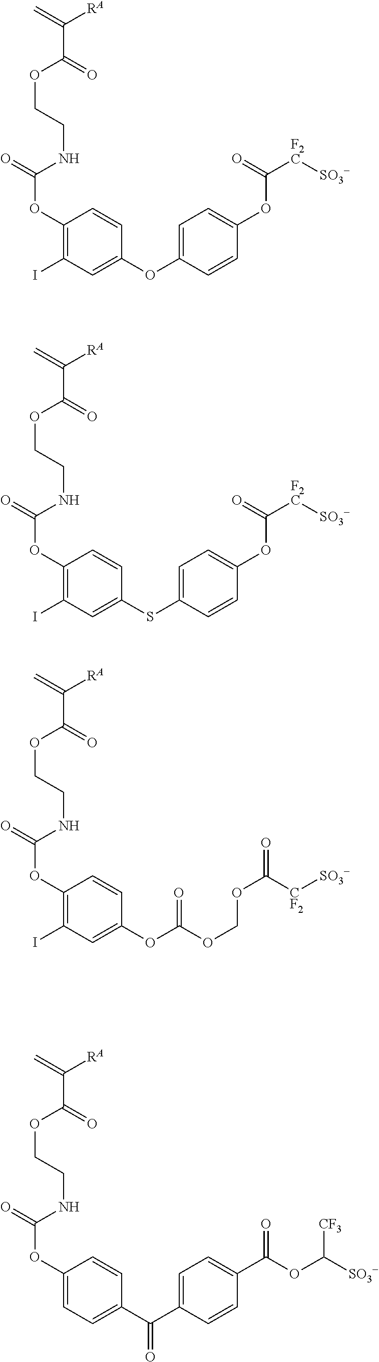

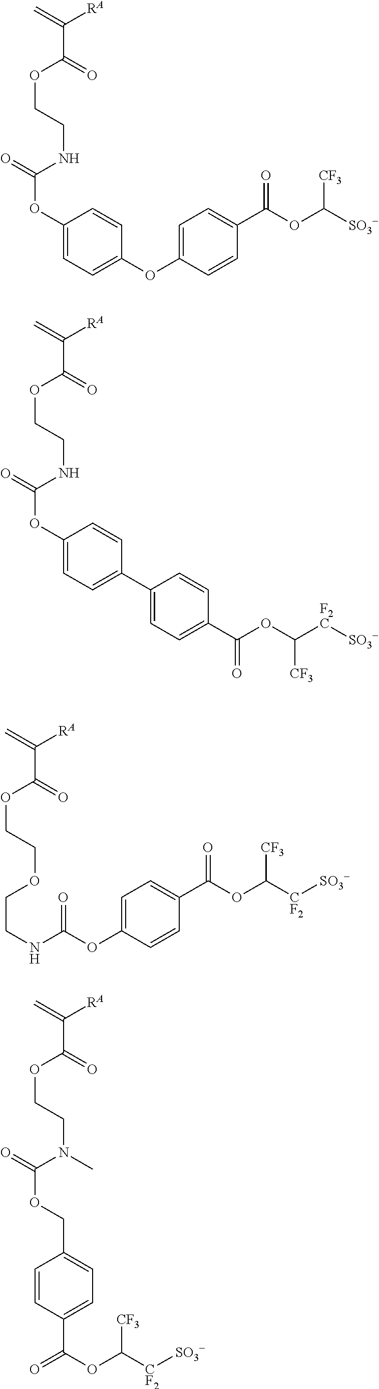

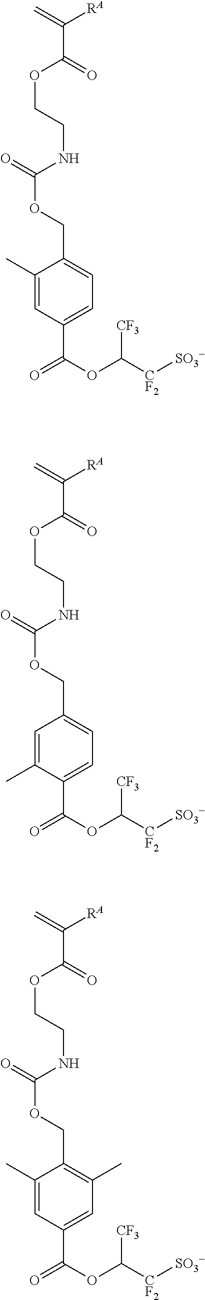

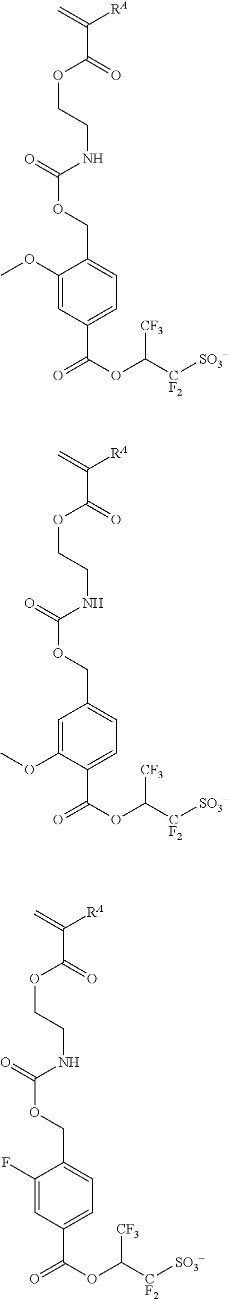

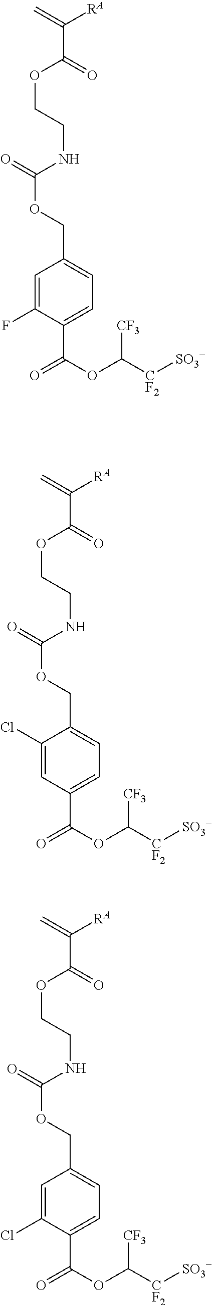

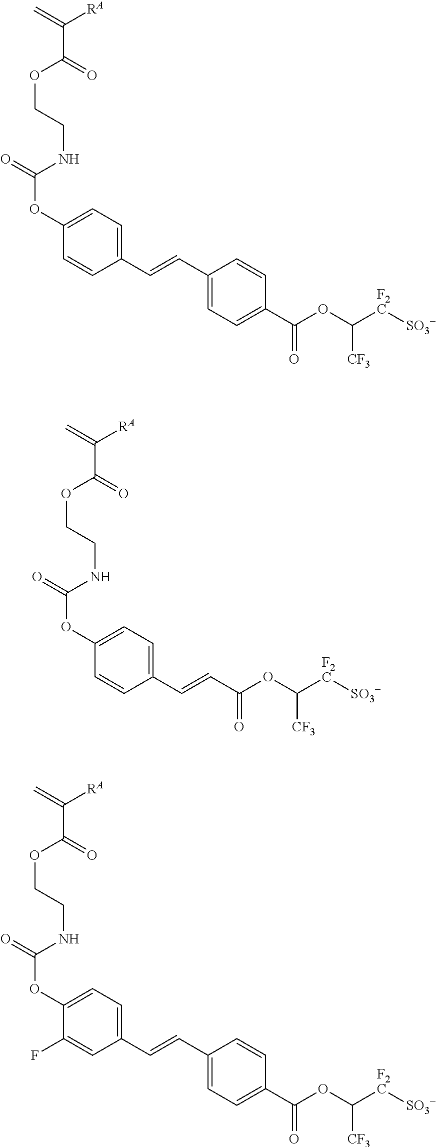

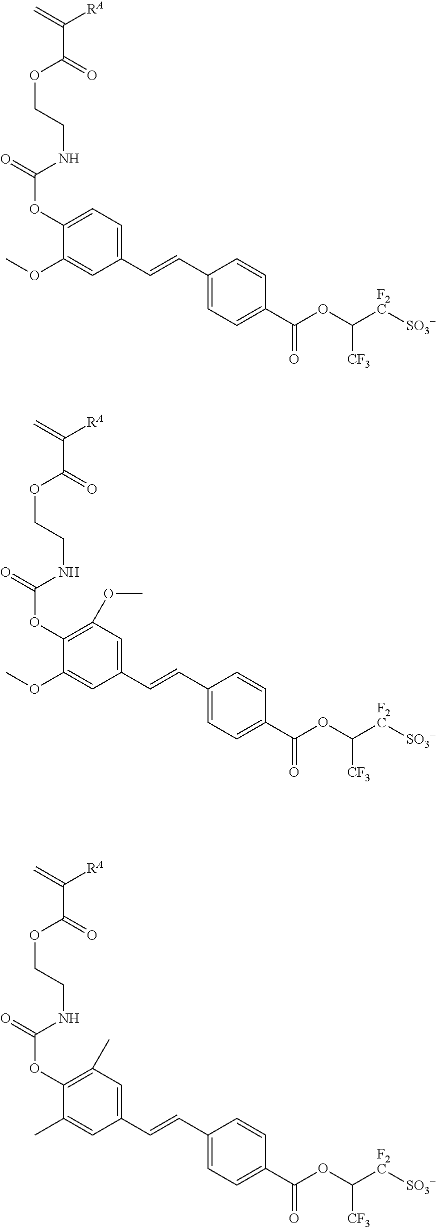

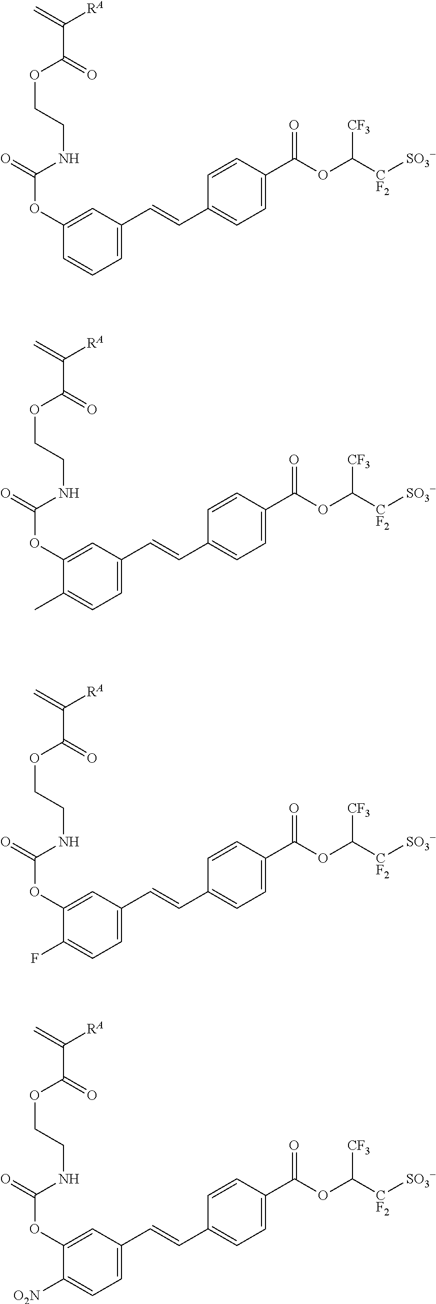

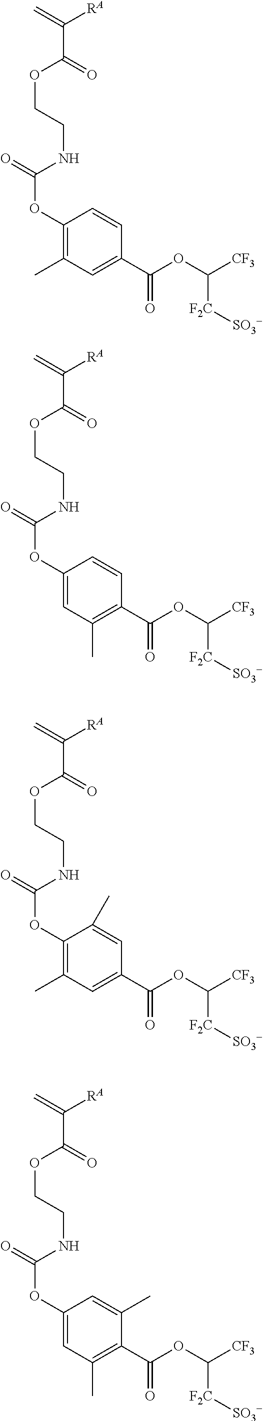

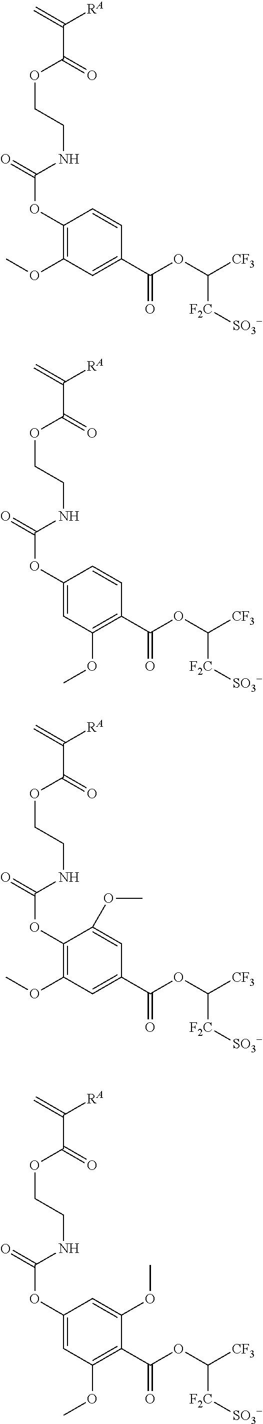

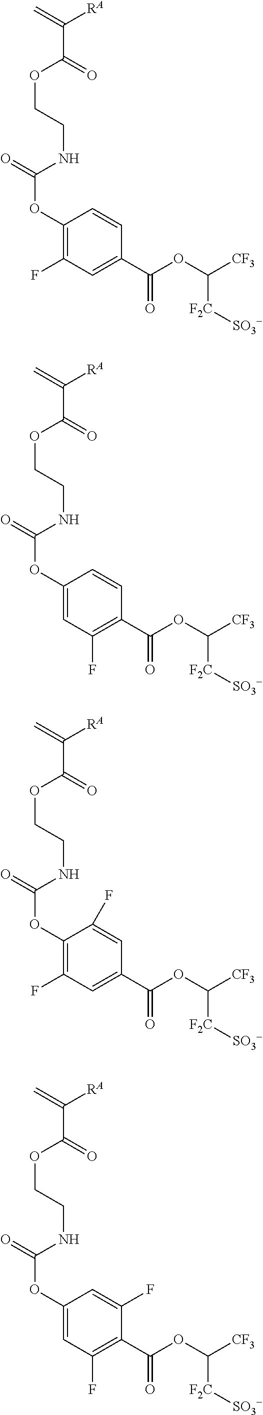

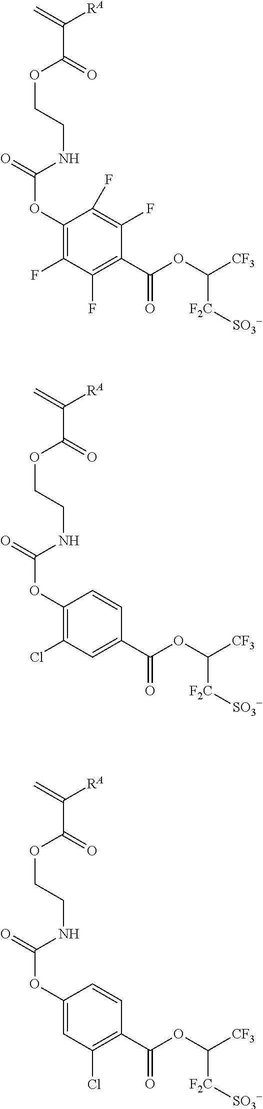

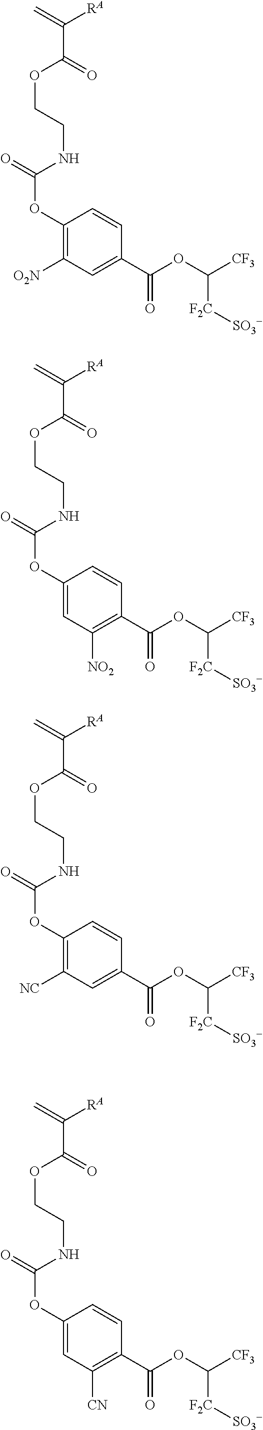

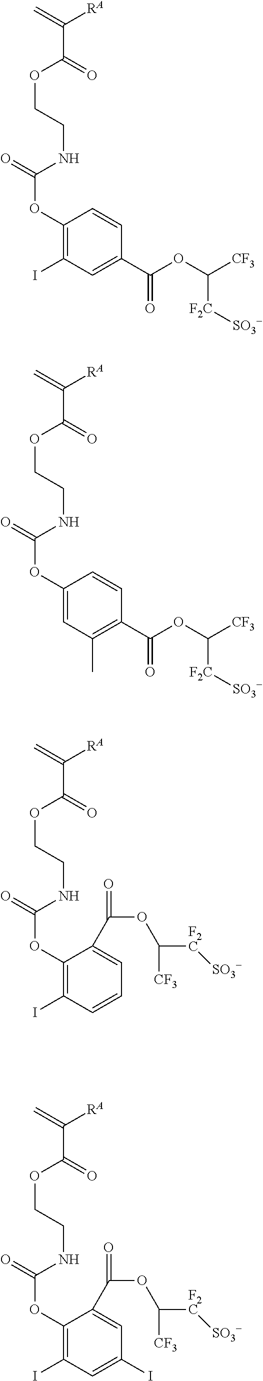

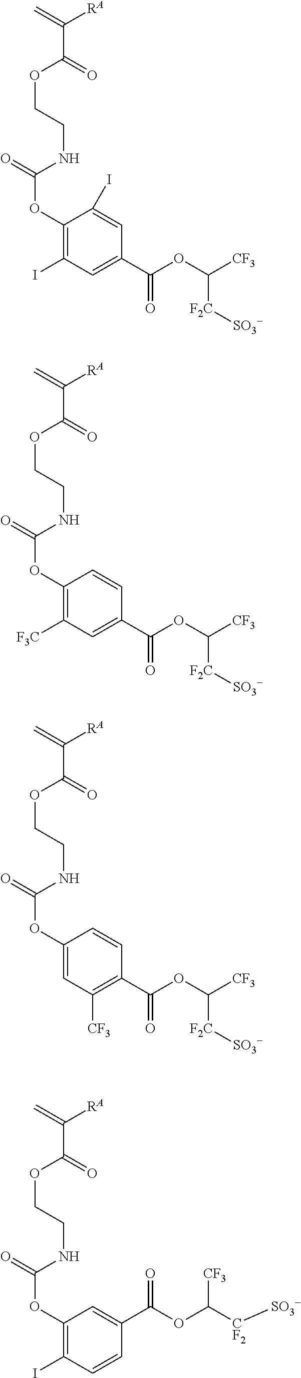

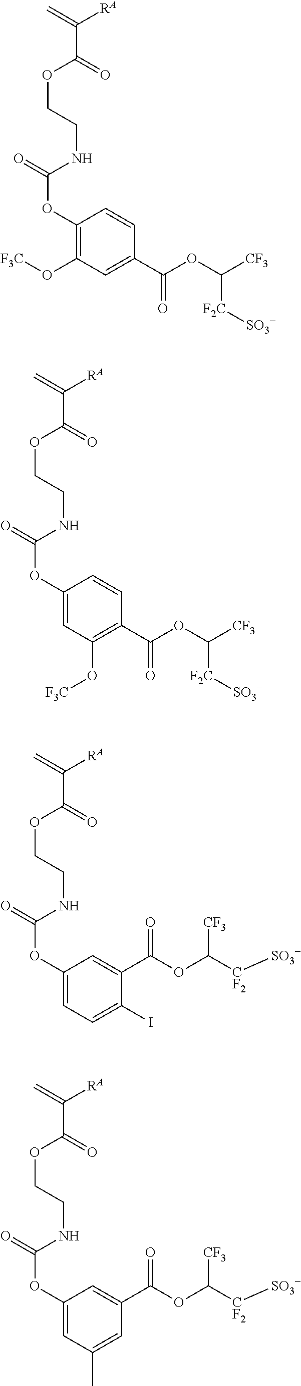

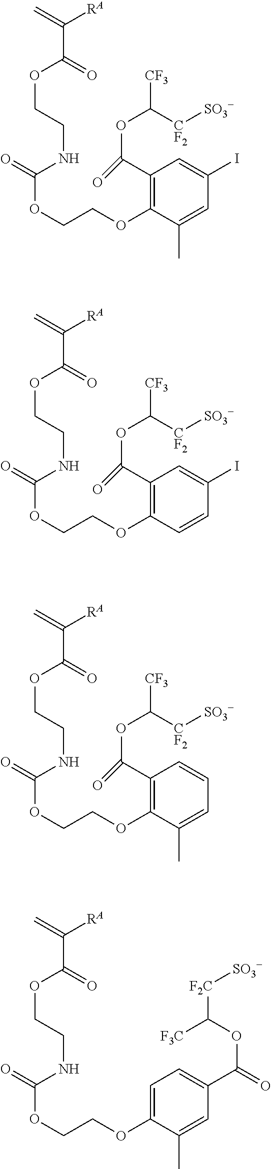

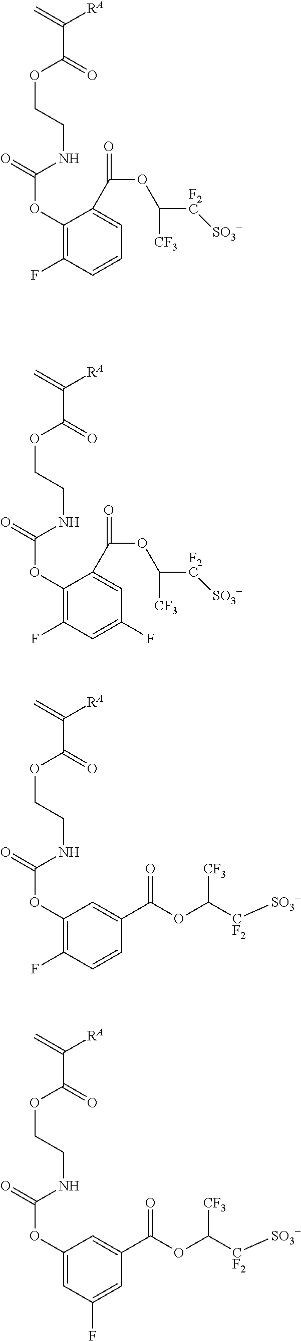

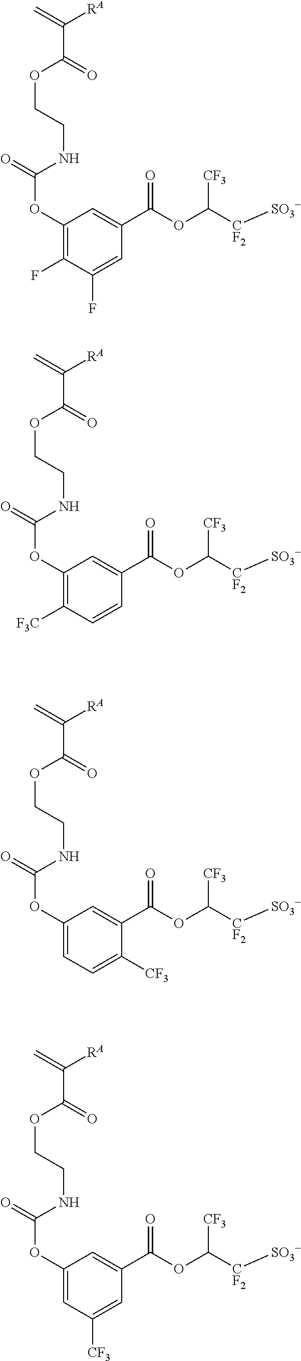

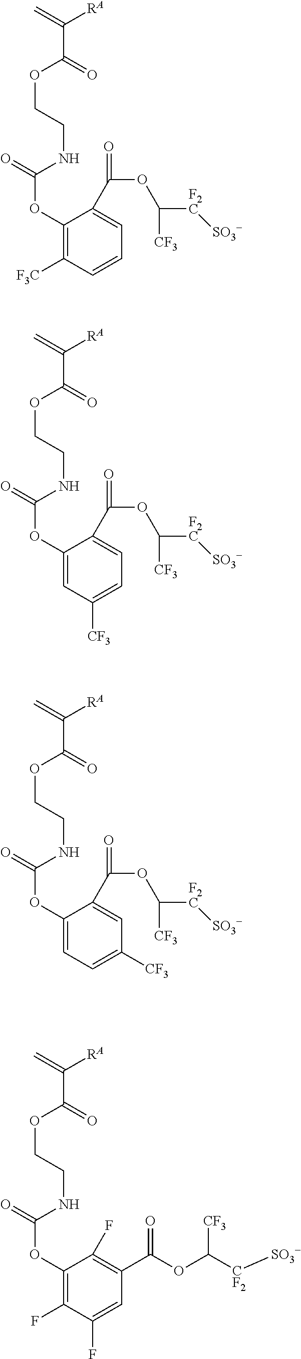

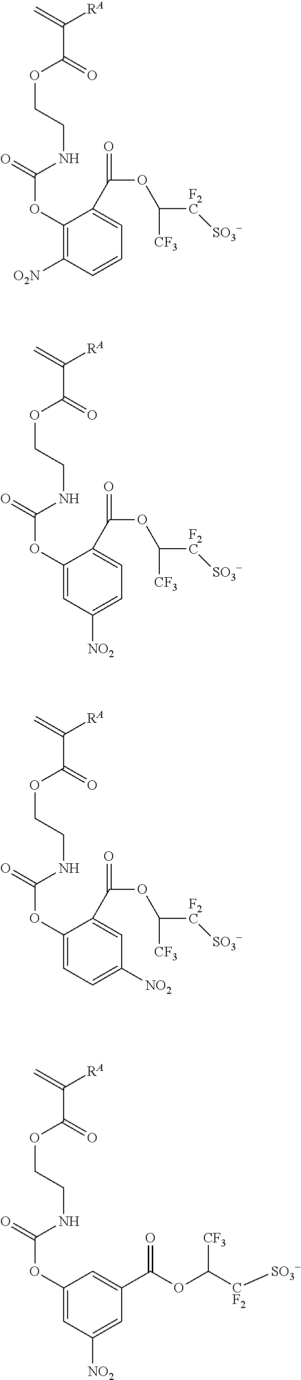

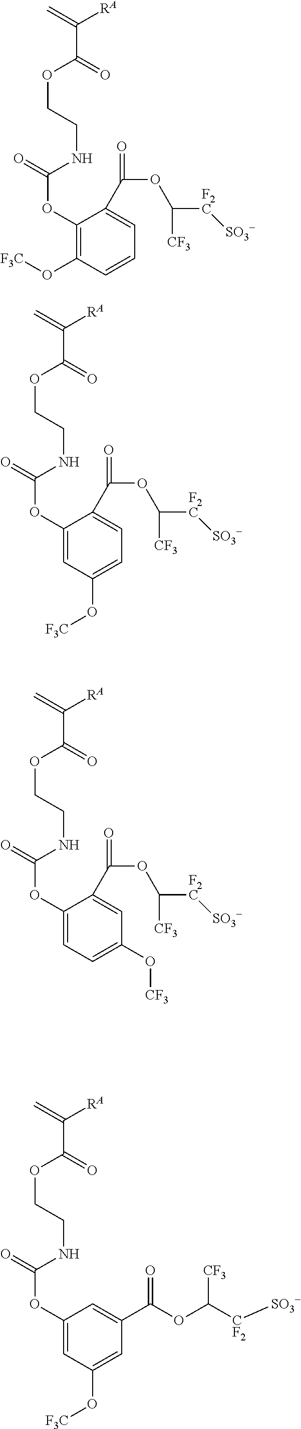

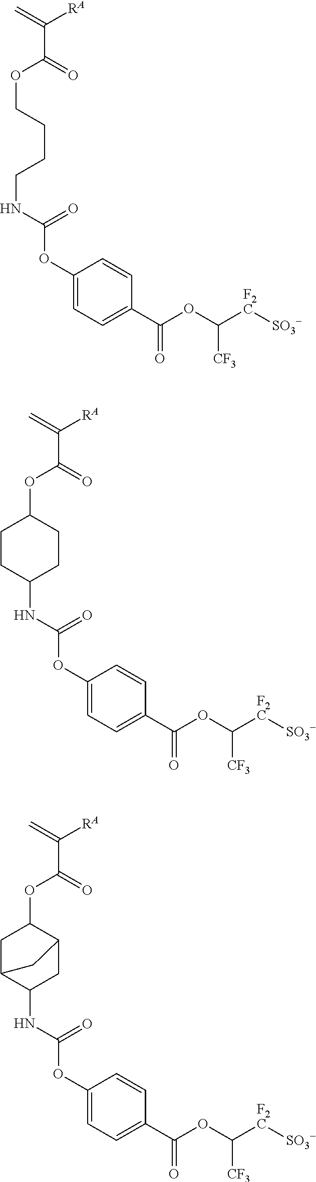

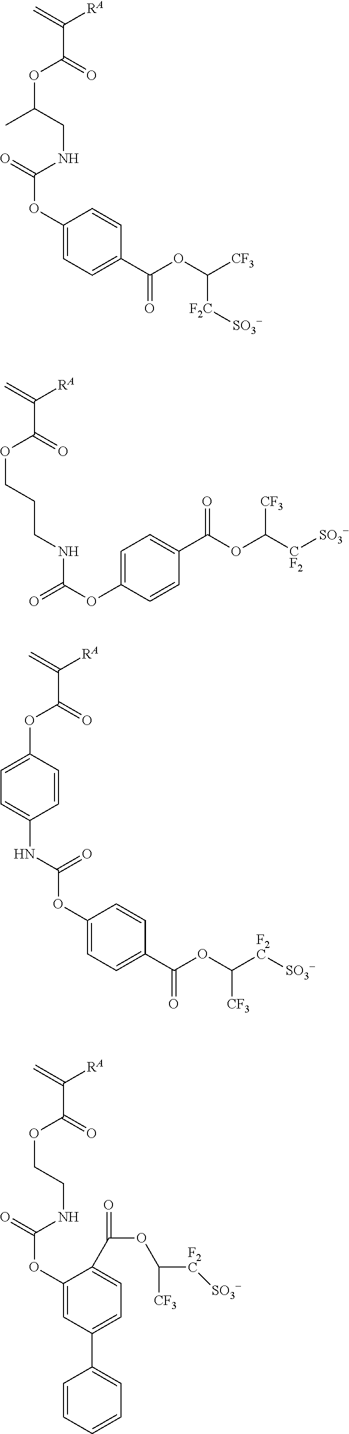

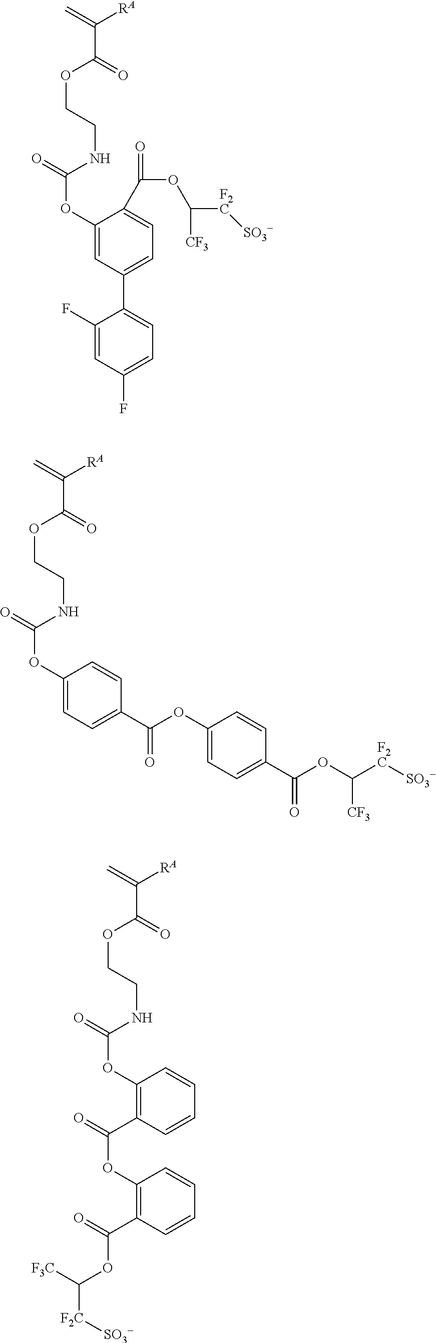

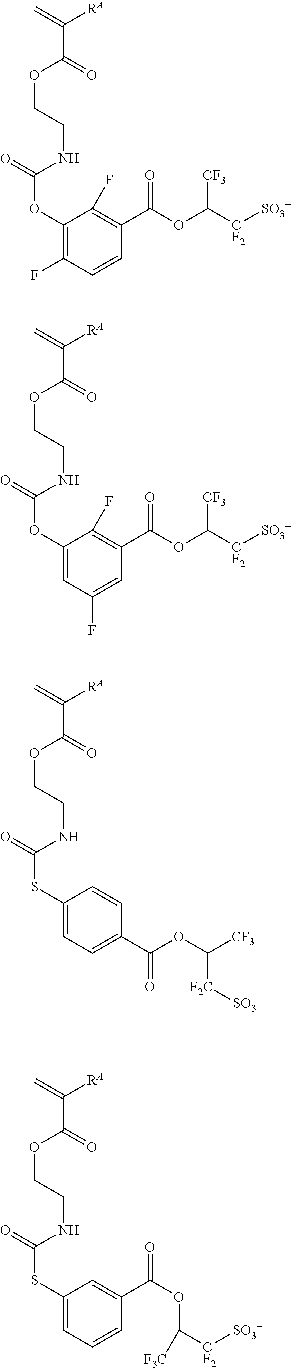

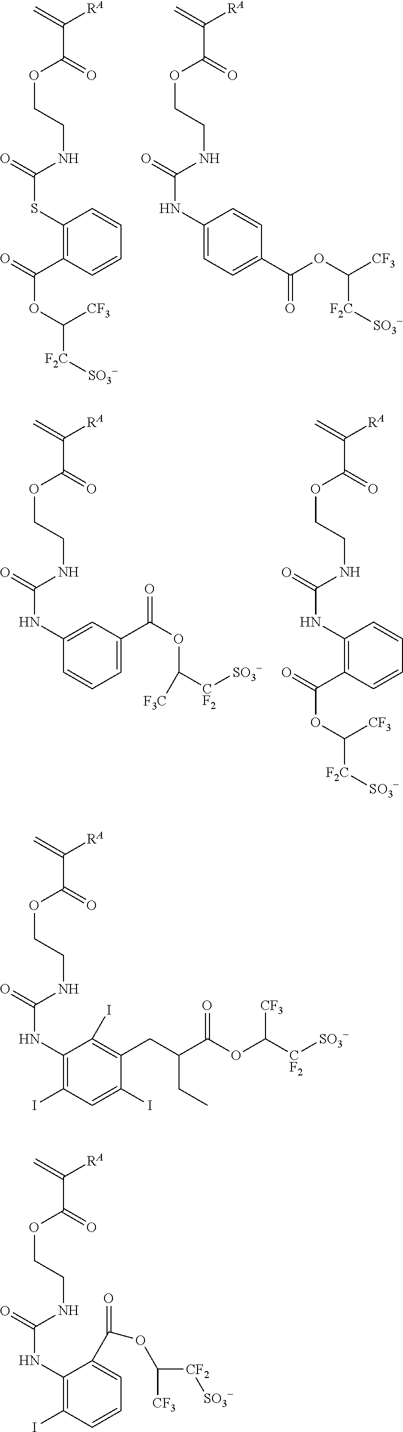

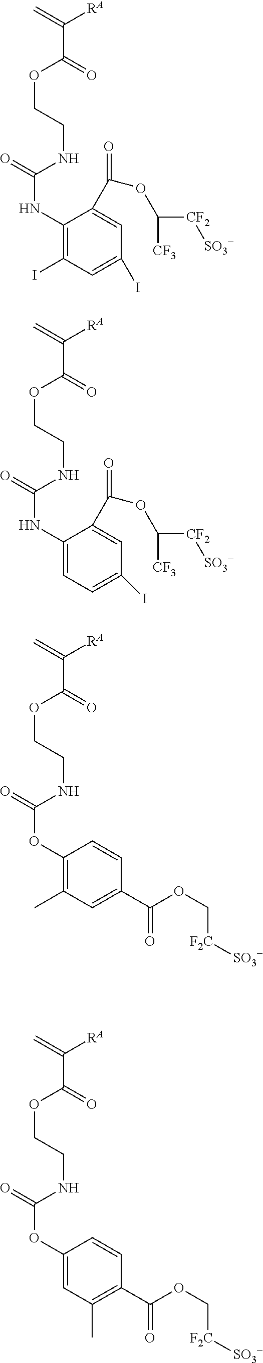

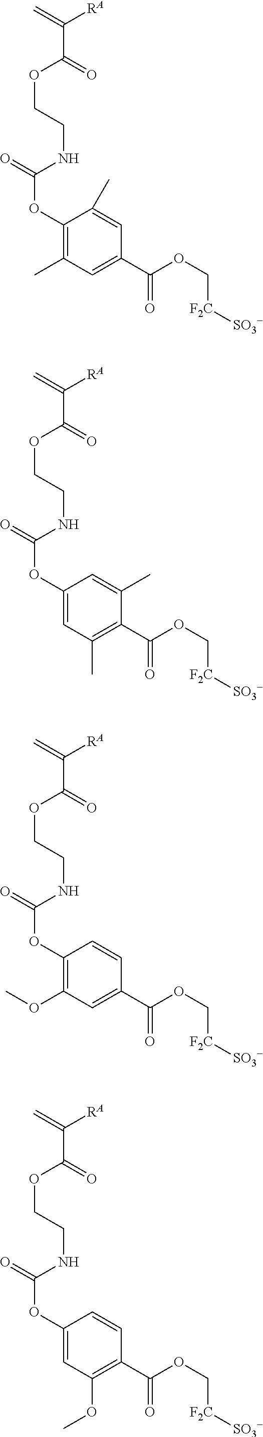

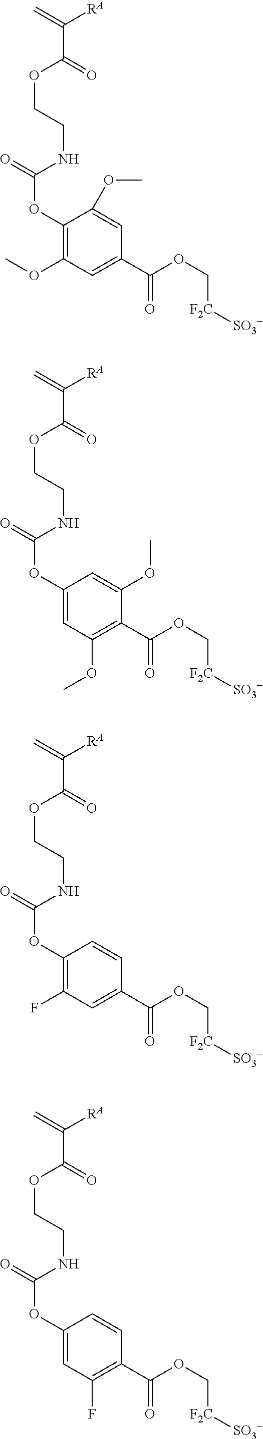

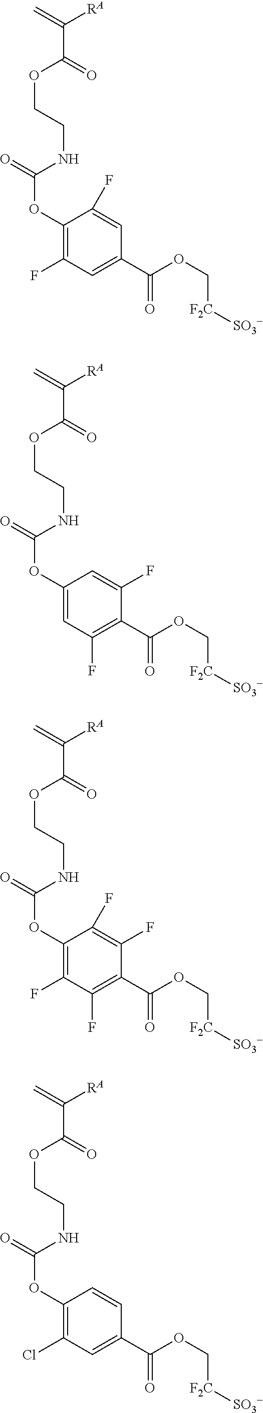

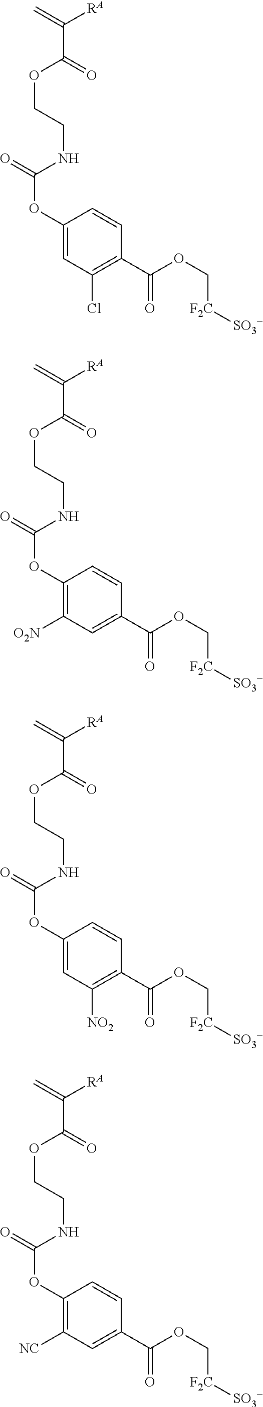

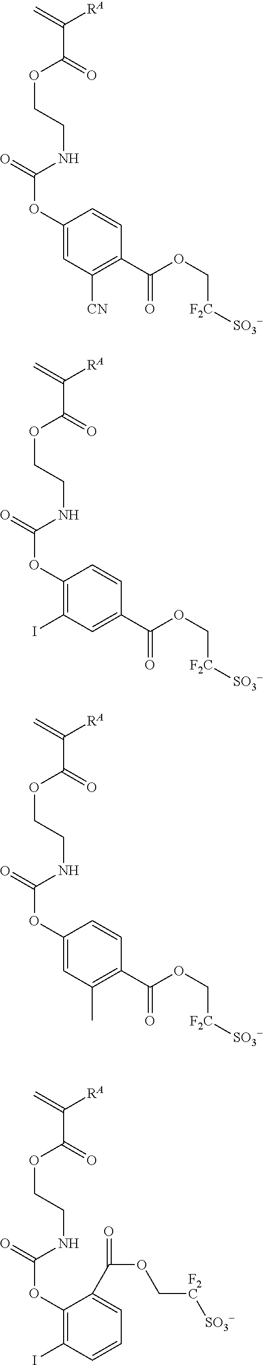

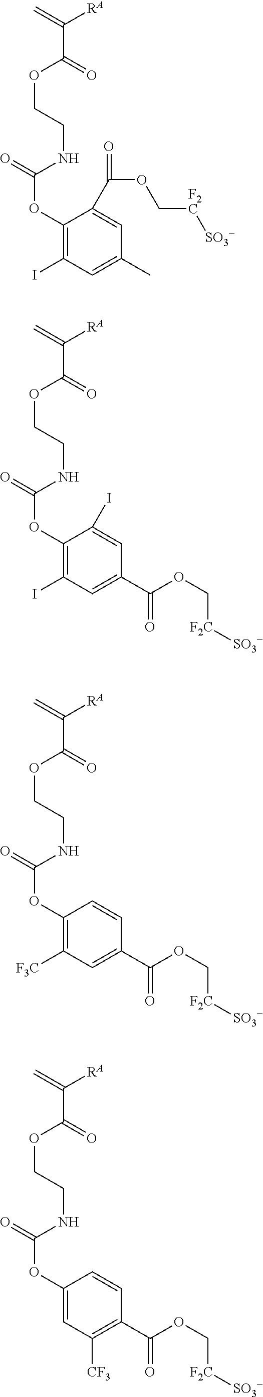

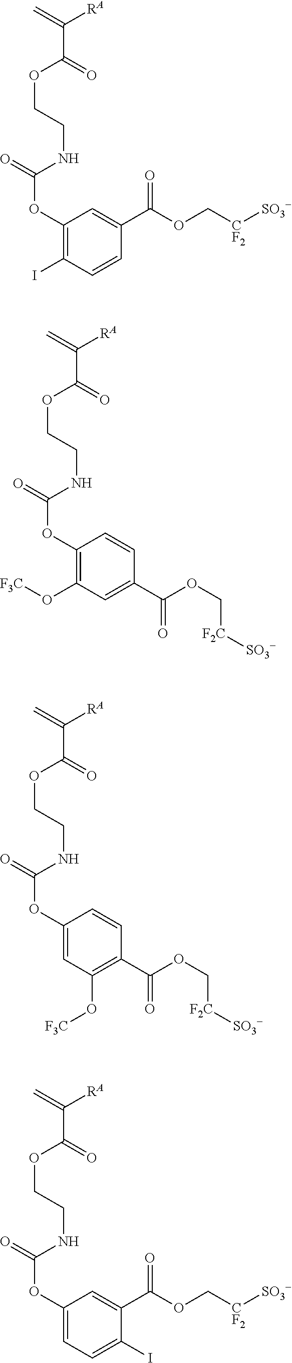

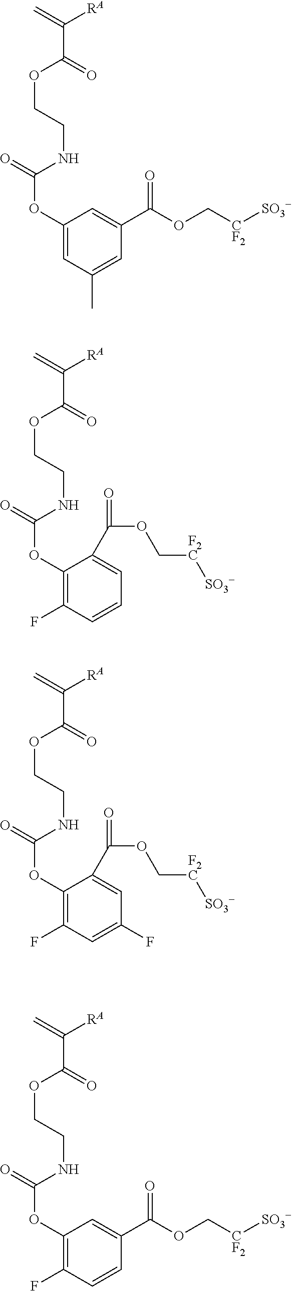

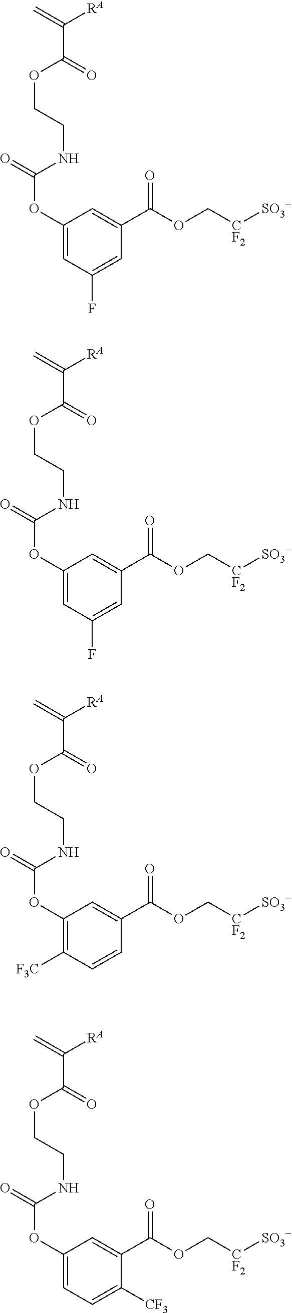

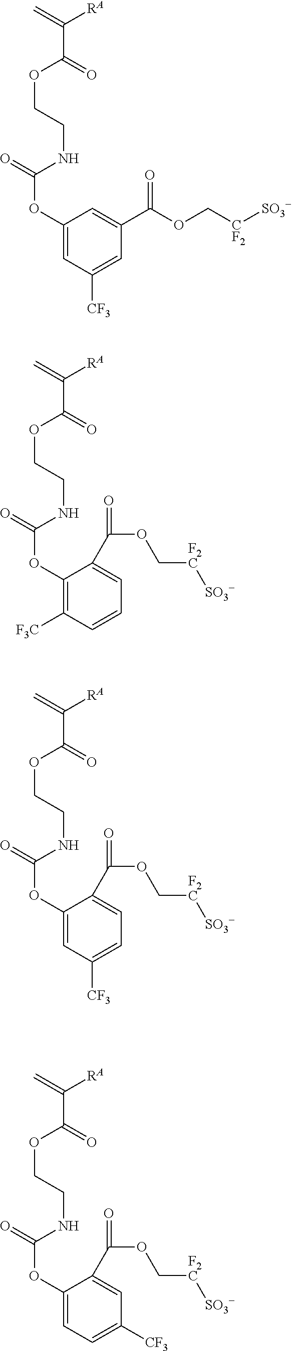

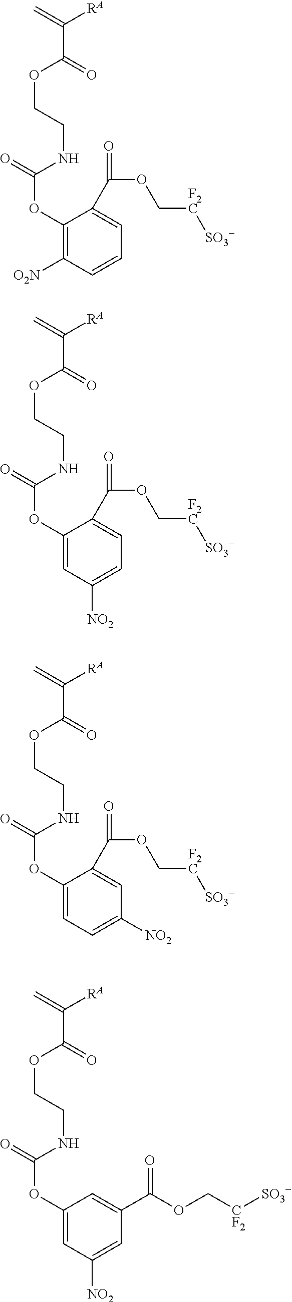

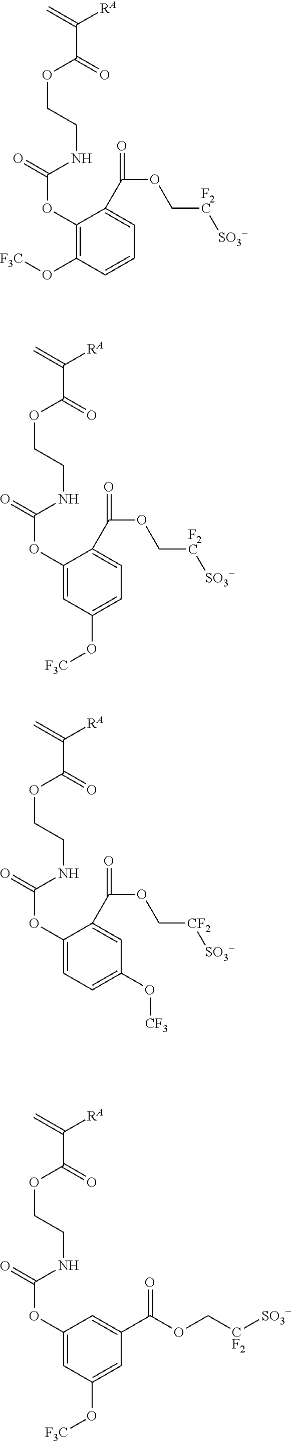

Examples of the anion in the monomer from which the repeat units (a2) are derived are shown below, but not limited thereto. Herein R^{A} is as defined above.

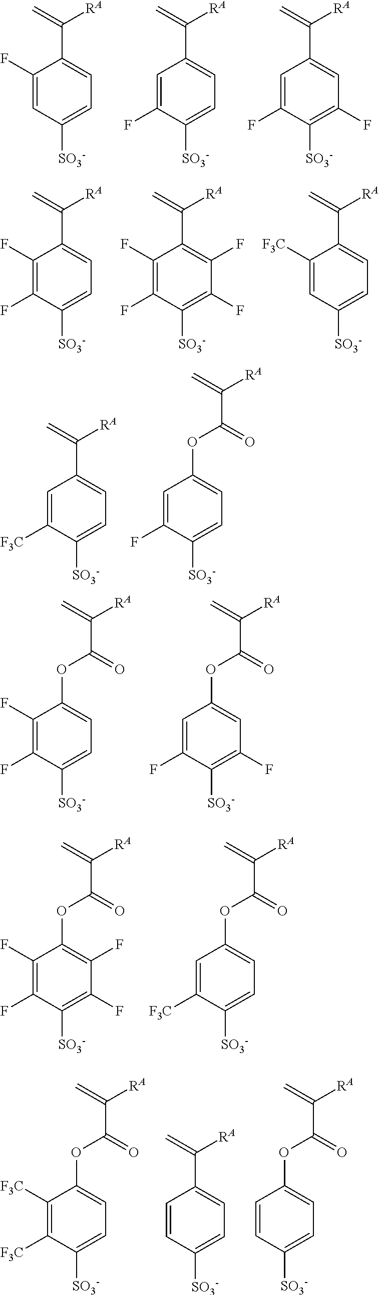

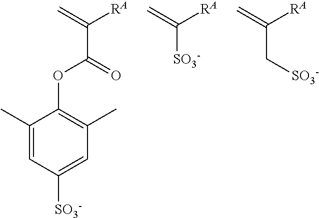

The sulfonium salt from which the repeat units (a1) or (a2) are derived may be synthesized, for example, by ion exchange between a salt containing the sulfonium cation and a weak acid anion and an ammonium salt having the foregoing anion. The sulfonium cation can be obtained, for example, by reaction of a dibenzothiophene compound having a hydrocarbylcarbonyl group or a hydrocarbyloxycarbonyl group with a diphenyliodonium salt.

When the resist composition is of positive tone, the base polymer preferably further comprises repeat units having an acid labile group. The repeat units having an acid labile group are preferably repeat units having formula (b1) (hereinafter also referred to as repeat units (b1)) or repeat units having formula (b2) (hereinafter also referred to as repeat units (b2)). In the exposed region, not only the repeat units (b1) or (b2) containing an acid labile group, but also the repeat units (a1) or (a2) containing an acid generator undergo catalytic reaction whereby the dissolution rate in the developer is accelerated. Thus, a positive tone resist composition having a very high sensitivity is constructed.

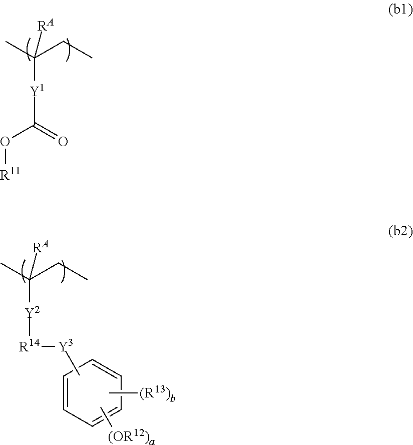

In formulae (b1) and (b2), R^{A} is each independently a hydrogen atom or a methyl group. Y¹ is a single bond, a phenylene group, a naphthylene group, or a C₁-C₁₂ linking group containing at least one moiety selected from an ester bond, an ether bond, and a lactone ring. Y² is a single bond or an ester bond. Y³ is a single bond, an ether bond, or an ester bond. R¹¹ and R¹² are each independently an acid labile group. R¹³ is a fluorine atom, a trifluoromethyl group, a cyano group, a C₁-C₆ saturated hydrocarbyl group, a C₁-C₆ saturated hydrocarbyloxy group, a C₂-C₇ saturated hydrocarbylcarbonyl group, a C₂-C₇ saturated hydrocarbylcarbonyloxy group, or a C₂-C₇ saturated hydrocarbyloxycarbonyl group. R¹⁴ is a single bond or a C₁-C₆ alkanediyl group in which some constituent —CH₂— may be substituted by an ether bond or an ester bond. a is 1 or 2, b is an integer of 0 to 4, provided that 1≤a+b≤5.

Examples of the monomer from which the repeat units (b1) are derived are shown below, but not limited thereto. Herein R^{A} and R¹¹ are as defined above.

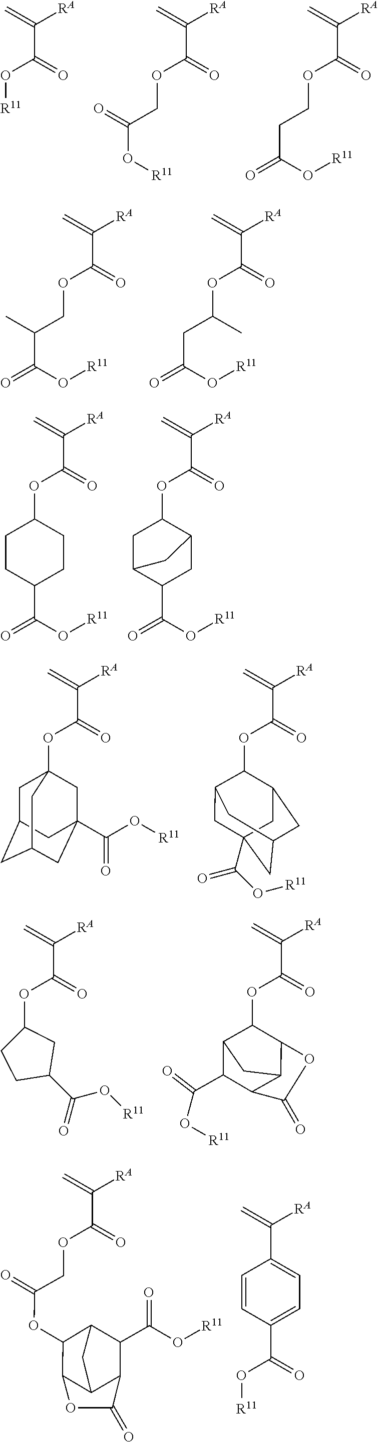

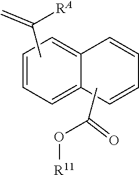

Examples of the monomer from which the repeat units (b2) are derived are shown below, but not limited thereto. Herein R^{A} and R¹² are as defined above.

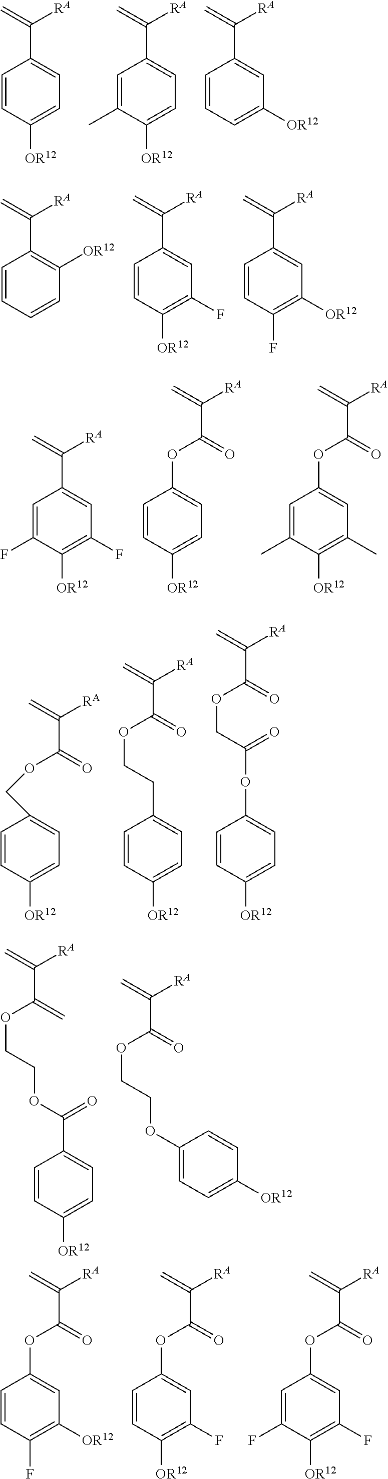

Examples of the acid labile groups represented by R¹¹ and R¹² in formulae (b1) and (b2) include those described in JP-A 2013-80033 and JP-A 2013-83821.

Typically, the acid labile groups are selected from groups having the following formulae (AL-1) to (AL-3).

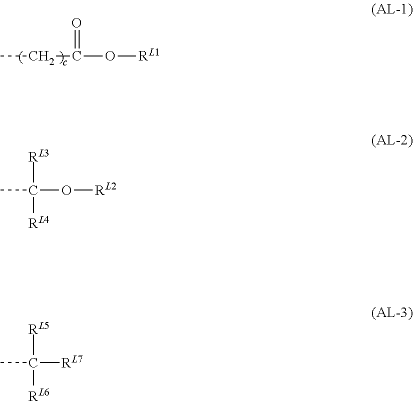

In the formulae, the dashed line is a bond.

In formulae (AL-1) and (AL-2), R^{L1} and R^{L2} are each independently a C₁-C₄₀ hydrocarbyl group which may contain a heteroatom such as an oxygen atom, a sulfur atom, a nitrogen atom, or a fluorine atom. The hydrocarbyl group may be saturated or unsaturated and straight, branched, or cyclic. Preferred are C₁-C₄₀ saturated or C₂-C₄₀ unsaturated hydrocarbyl groups, especially C₁-C₂₀ saturated or C₂-C₂₀ unsaturated hydrocarbyl groups.

In formula (AL-1), c is an integer of 0 to 10, preferably 1 to 5.

In formula (AL-2), R^{L3} and R^{L4} are each independently a hydrogen atom or a C₁-C₂₀ hydrocarbyl group which may contain a heteroatom such as an oxygen atom, a sulfur atom, a nitrogen atom, or a fluorine atom. The hydrocarbyl group may be saturated or unsaturated and straight, branched, or cyclic. Preferred are C₁-C₂₀ saturated hydrocarbyl groups. Any two of R^{L2}, R^{L3}, and R^{L4} may bond together to form a ring containing 3 to 20 carbon atoms with the carbon atom or carbon and oxygen atoms to which they are attached. The ring is preferably a ring containing 4 to 16 carbon atoms, and particularly preferably an alicyclic ring.

In formula (AL-3), R^{L5}, R^{L6}, and R^{L7} are each independently a C₁-C₂₀ hydrocarbyl group which may contain a heteroatom such as an oxygen atom, a sulfur atom, a nitrogen atom, or a fluorine atom. The hydrocarbyl group may be saturated or unsaturated and straight, branched, or cyclic. Preferred are C₁-C₂₀ saturated hydrocarbyl groups. Any two of R^{L5}, R^{L6}, and R^{L7} may bond together to form a ring containing 3 to 20 carbon atoms with the carbon atom to which they are attached. The ring is preferably a ring having 4 to 16 carbon atoms, particularly preferably an alicyclic ring, and may have a double bond or a triple bond in the ring.

Also suited as the acid labile group having formula (AL-3) are aromatic group-containing acid labile groups as described in JP 5655754, JP 5655755, JP 5655756, JP 5407941, JP 5434983, JP 5565293, and JP-A 2007-279699; triple bond-containing acid labile groups as described in JP-A 2008-268741; and double or triple bond-containing acid labile groups as described in JP-A 2021-50307.

The base polymer may further comprise repeat units (c) having a phenolic hydroxy group as an adhesive group. Examples of a suitable monomer from which the repeat units (c) are derived are given below, but not limited thereto. Herein R^{A} is as defined above.

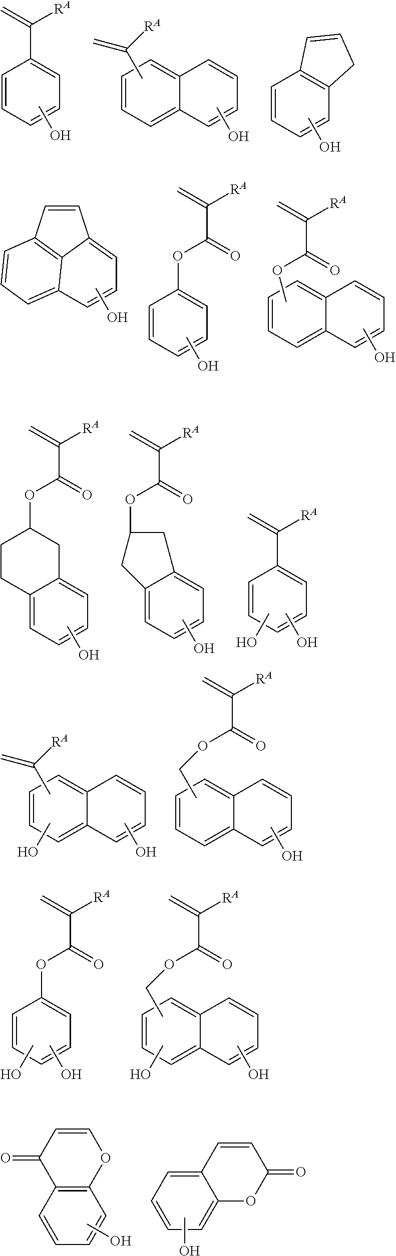

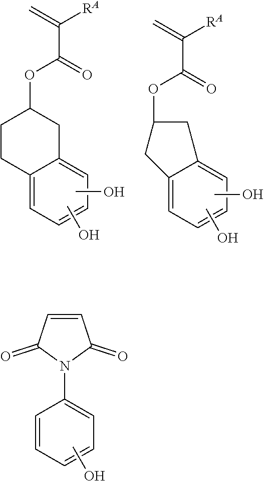

The base polymer may further comprise repeat units (d) having another adhesive group selected from a hydroxy group (other than the foregoing phenolic hydroxy group), a lactone ring, a sultone ring, an ether bond, an ester bond, a sulfonic ester bond, a carbonyl group, a sulfonyl group, a cyano group, and a carboxy group. Examples of a suitable monomer from which the repeat units (d) are derived are given below, but not limited thereto. Herein R^{A} is as defined above.

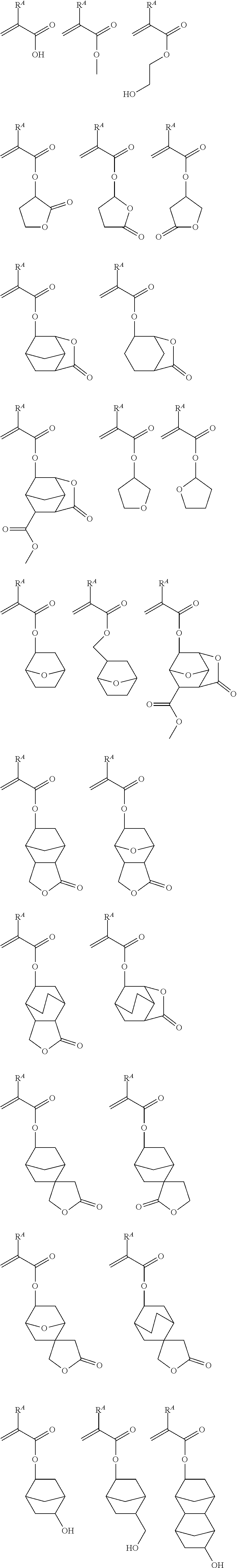

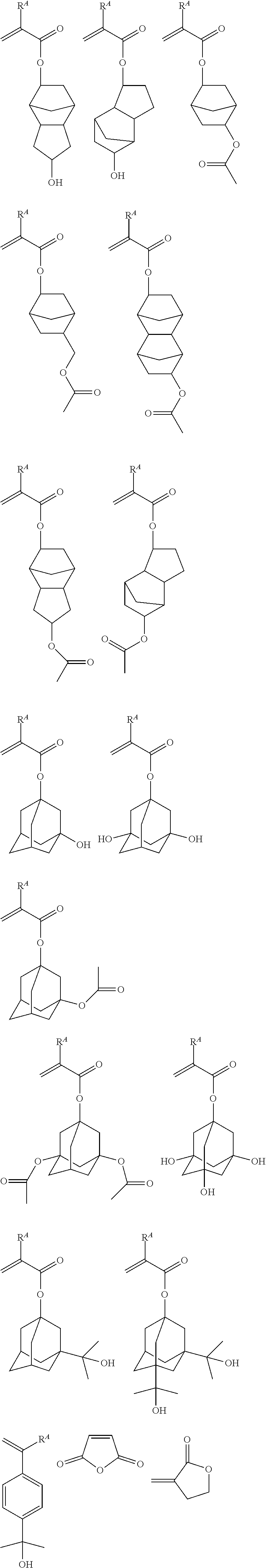

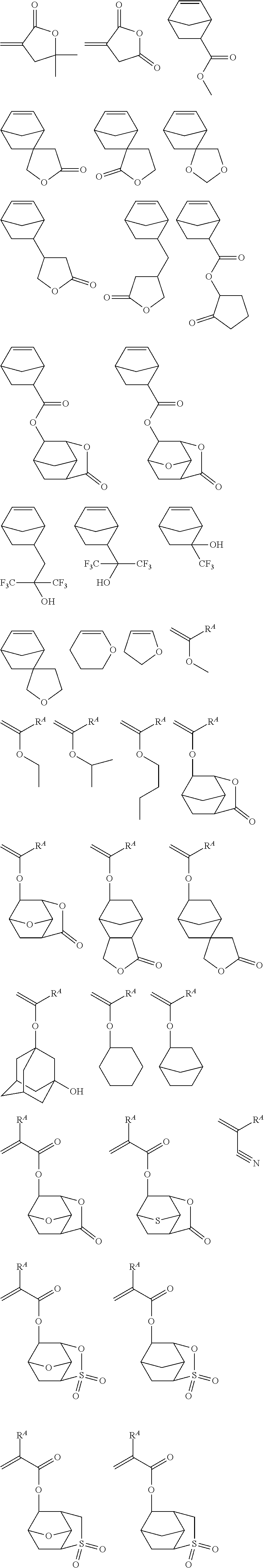

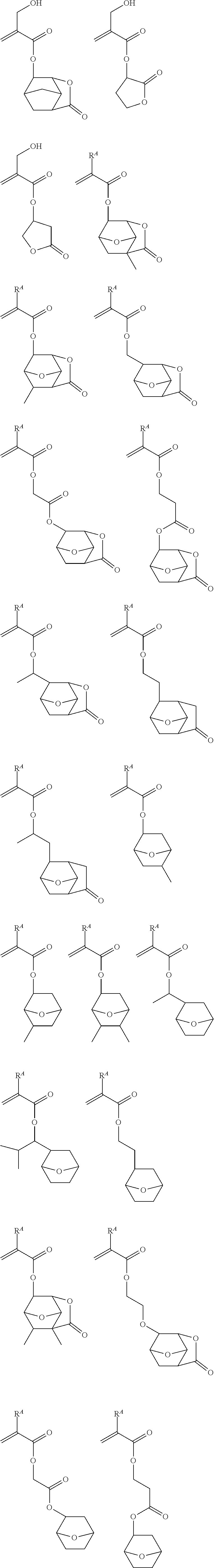

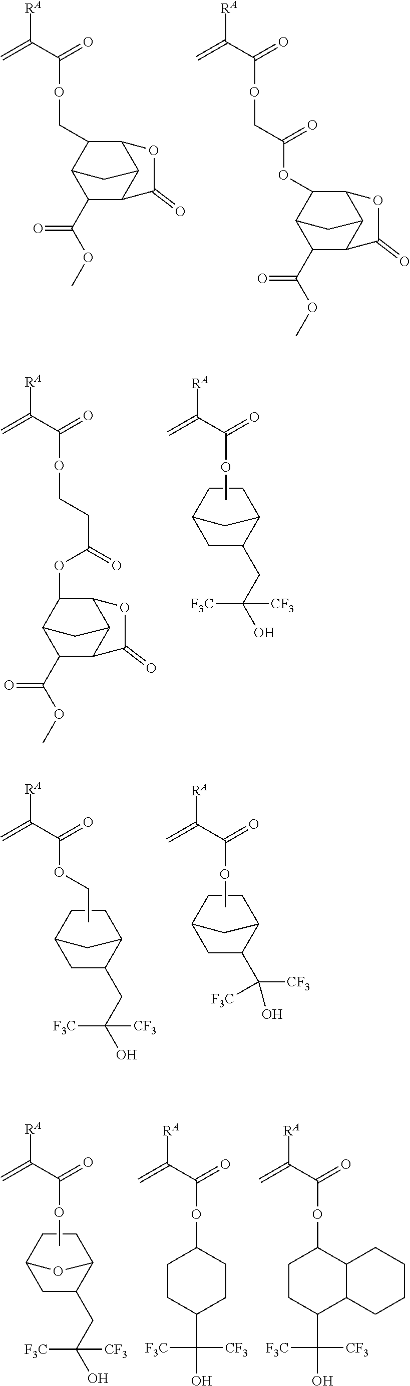

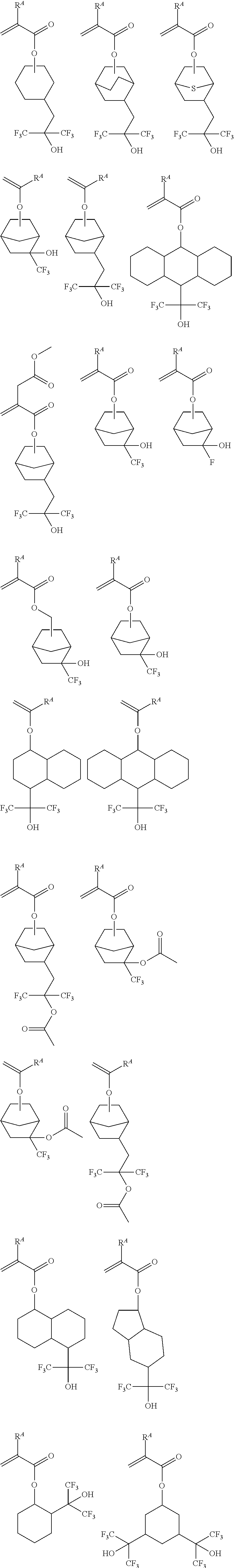

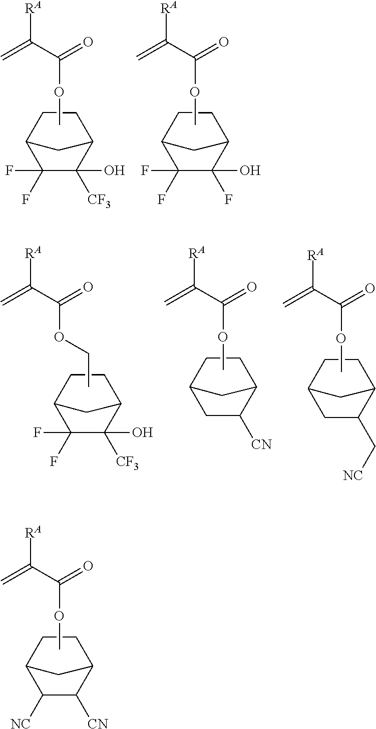

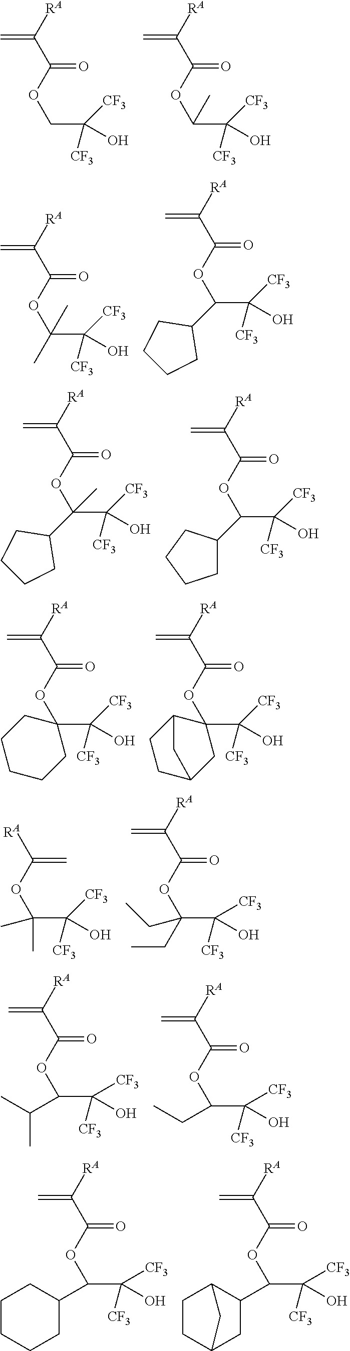

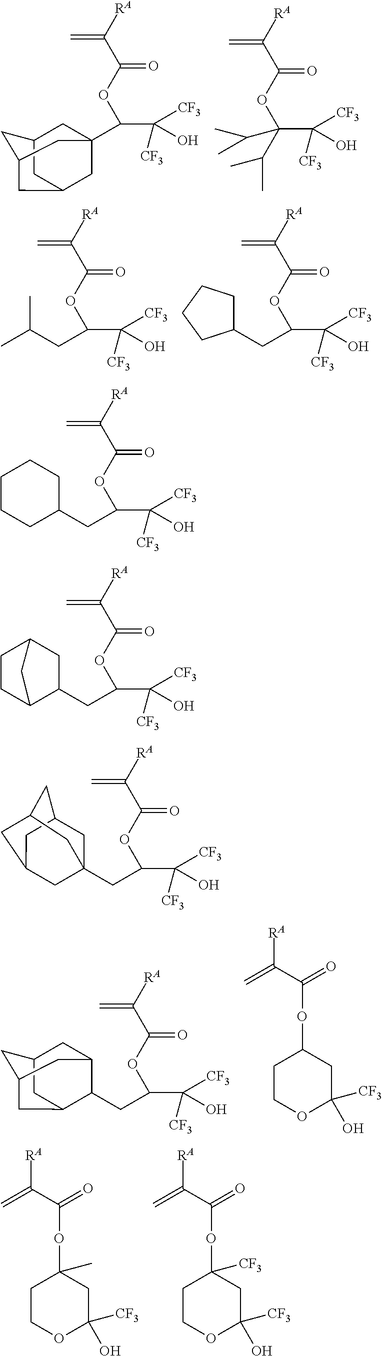

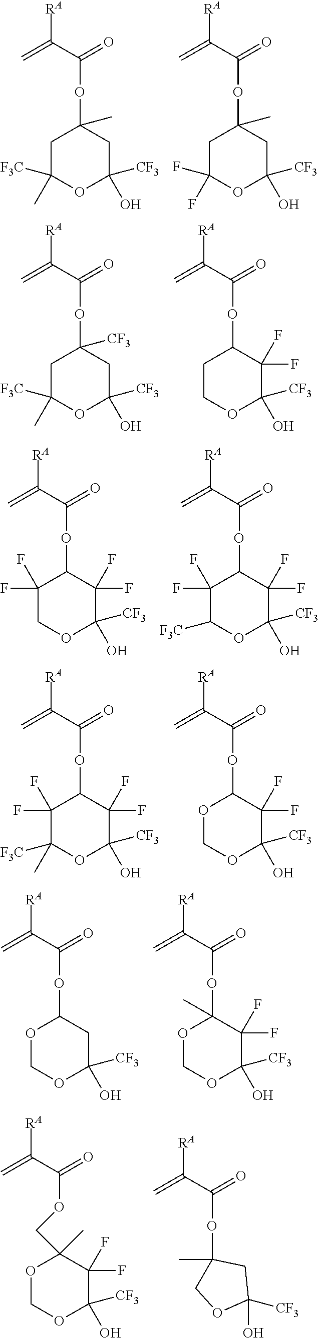

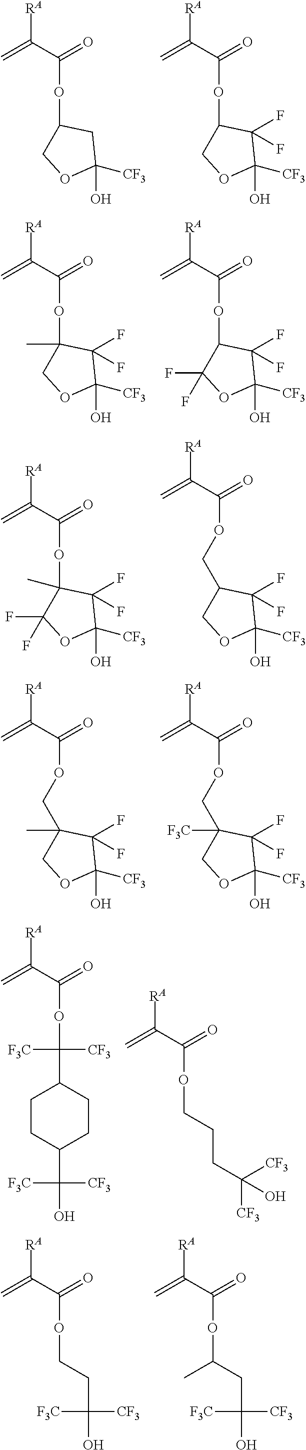

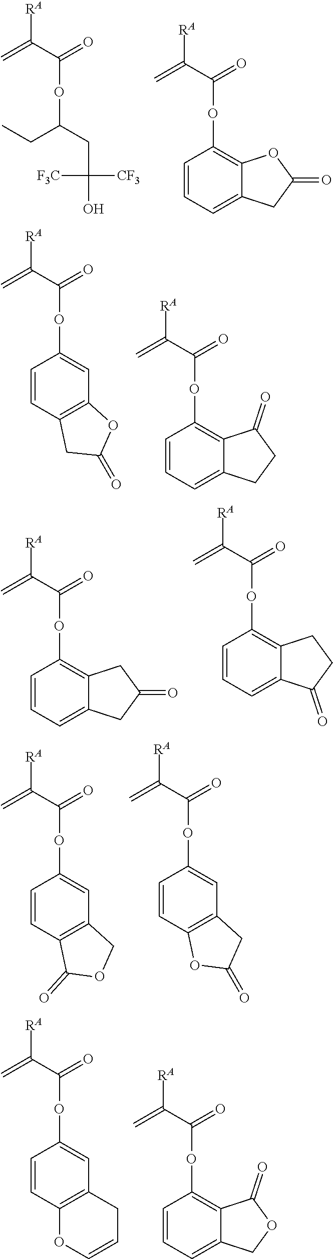

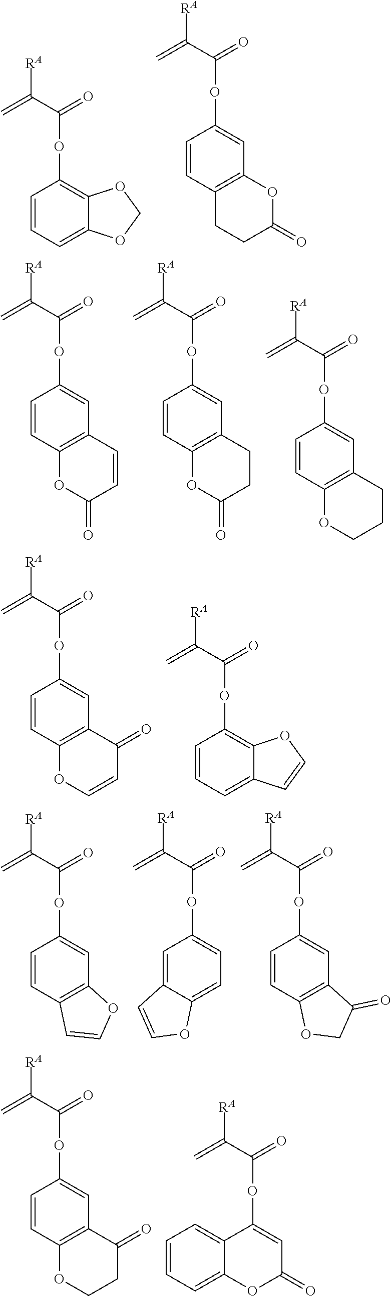

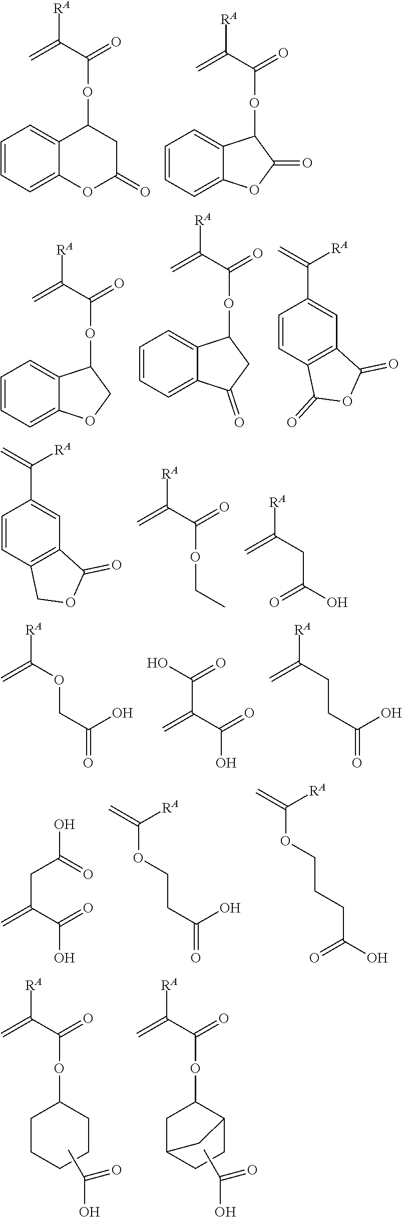

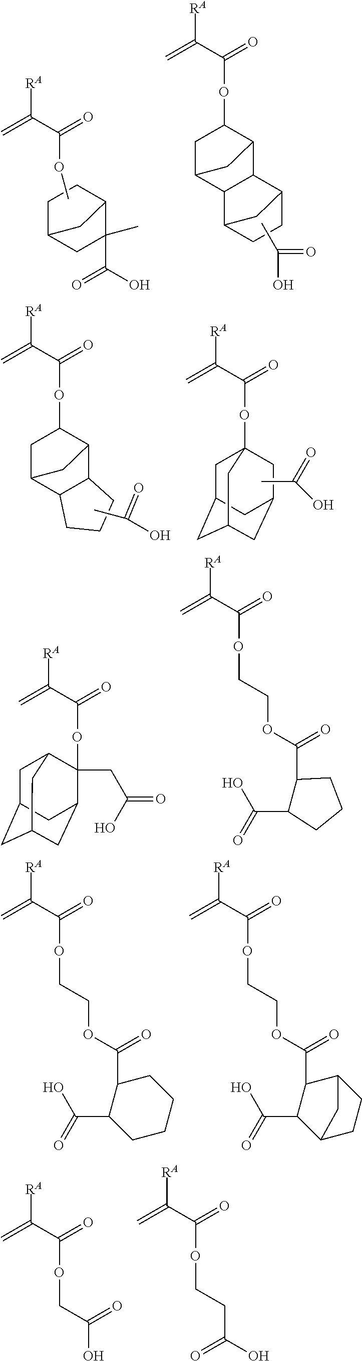

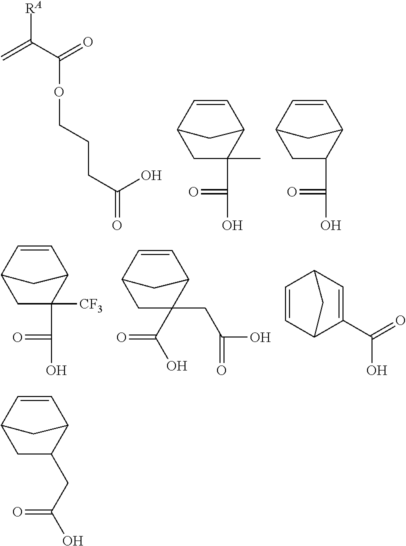

In another preferred embodiment, the base polymer may further comprise repeat units (e) derived from indene, benzofuran, benzothiophene, acenaphthylene, chromone, coumarin, norbornadiene, or a derivative thereof. Examples of a suitable monomer from which the repeat units (e) are derived are given below, but not limited thereto.

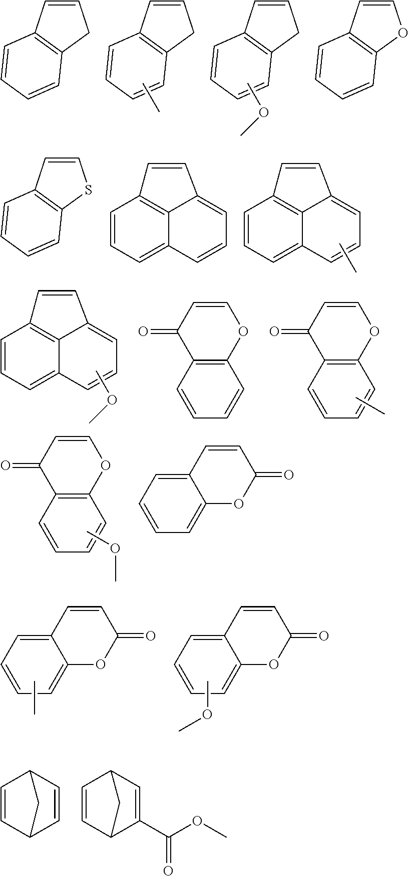

The base polymer may further comprise repeat units (f) derived from styrene, vinylnaphthalene, vinylanthracene, vinylpyrene, methyleneindane, vinylpyridine, or vinylcarbazole.

The base polymer comprises repeat units (a1) or (a2) as an essential component. A fraction of repeat units (a1), (a2), (b), (c), (d), (e), and (f) is preferably 0≤a1≤0.5, 0≤a2≤0.5, 0<a1+a2≤0.5, 0≤b1≤0.8, 0≤b2≤0.8, 0.1≤b1+b2≤0.8, 0≤c≤0.9, 0≤d≤0.8, 0≤e≤0.8, and 0≤f≤0.5, more preferably 0≤a1≤0.4, 0≤a2≤0.4, 0.01≤a1+a2≤0.4, 0≤b1≤0.7, 0≤b2≤0.7, 0.15≤b1+b2≤0.7, 0≤c≤0.8, 0≤d≤0.7, 0≤e≤0.7, and 0≤f≤0.4, and still more preferably 0≤a1≤0.35, 0≤a2≤0.35, 0.02≤a1+a2≤0.35, 0≤b1≤0.65, 0≤b2≤0.65, 0.2≤b1+b2≤0.65, 0≤c≤0.7, ≤0≤d≤0.6, 0≤e≤0.6, and 0≤f≤0.3. Note that a1+a2+b1+b2+c+d+e+f=1.0.

The base polymer may be synthesized, for example, by dissolving one or more monomers selected from the monomers corresponding to the foregoing repeat units in an organic solvent, adding a radical polymerization initiator thereto, and heating for polymerization.

Examples of the organic solvent which can be used for polymerization include toluene, benzene, tetrahydrofuran (THF), diethyl ether, and dioxane. Examples of the polymerization initiator used herein include 2,2′-azobisisobutyronitrile (AIBN), 2,2′-azobis(2,4-dimethylvaleronitrile), dimethyl 2,2-azobis(2-methylpropionate), benzoyl peroxide, and lauroyl peroxide. Preferably the polymerization temperature is 50 to 80° C. The reaction time is preferably 2 to 100 hours, more preferably 5 to 20 hours.

When a monomer having a hydroxy group is copolymerized, the hydroxy group may be substituted by an acetal group susceptible to deprotection with an acid such as an ethoxyethoxy group, prior to polymerization, and the polymerization be followed by deprotection with a weak acid and water. Alternatively, the hydroxy group may be substituted by an acetyl group, a formyl group, a pivaloyl group, or a similar group prior to polymerization, and the polymerization be followed by alkaline hydrolysis.

When hydroxystyrene or hydroxyvinylnaphthalene is copolymerized, an alternative method is possible. Specifically, acetoxystyrene or acetoxyvinylnaphthalene is used instead of hydroxystyrene or hydroxyvinylnaphthalene, and after polymerization, the acetoxy group is deprotected by alkaline hydrolysis, for thereby converting the polymer product to hydroxystyrene or hydroxyvinylnaphthalene.

For alkaline hydrolysis, a base such as aqueous ammonia or triethylamine may be used. The reaction temperature is preferably −20° C. to 100° C., more preferably 0° C. to 60° C. The reaction time is preferably 0.2 to 100 hours, more preferably 0.5 to 20 hours.

The base polymer should preferably have a weight average molecular weight (Mw) in the range of 1,000 to 500,000, and more preferably 2,000 to 30,000, as measured by gel permeation chromatography (GPC) versus polystyrene standards using THF as a solvent. A Mw in the range ensures that the resist film has heat resistance and high solubility in an alkaline developer.

If a base polymer has a wide molecular weight distribution or dispersity (Mw/Mn), which indicates the presence of lower and higher molecular weight polymer fractions, there is a possibility that foreign matter is left on the pattern or the pattern profile is degraded after exposure. The influences of Mw and Mw/Mn become stronger as the pattern rule becomes finer. Therefore, the base polymer should preferably have a narrow dispersity (Mw/Mn) of 1.0 to 2.0, especially 1.0 to 1.5, in order to provide a resist composition suitable for micropatterning to a small feature size.

It is understood that a blend of two or more polymers which differ in compositional ratio, Mw, or Mw/Mn is acceptable.

Organic Solvent

An organic solvent may be added to the resist composition of the present invention. The organic solvent used herein is not particularly limited as long as the foregoing and below-mentioned components are soluble therein. Examples of the organic solvent are described in JP-A 2008-111103, paragraphs [0144]-[0145]. Exemplary solvents include ketones such as cyclohexanone, cyclopentanone, methyl-2-n-pentyl ketone, and 2-heptanone; alcohols such as 3-methoxybutanol, 3-methyl-3-methoxybutanol, 1-methoxy-2-propanol, 1-ethoxy-2-propanol, and diacetone alcohol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol mono-tert-butyl ether acetate, methyl 2-hydroxyisobutyrate, ethyl 2-hydroxyisobutyrate, propyl 2-hydroxyisobutyrate, and butyl 2-hydroxyisobutyrate; and lactones such as γ-butyrolactone.

The organic solvent is preferably added to the resist composition of the present invention in an amount of 100 to 10,000 parts by weight, and more preferably 200 to 8,000 parts by weight per 100 parts by weight of the base polymer. The organic solvent may be used alone or in admixture.

Quencher

The resist composition of the present invention may further comprise a quencher. As used herein, the “quencher” refers to a compound capable of trapping the acid generated from the acid generator in the resist composition for thereby preventing the acid from diffusing to the unexposed region.

The quencher is typically selected from conventional basic compounds. Conventional basic compounds include primary, secondary, and tertiary aliphatic amines, mixed amines, aromatic amines, heterocyclic amines, nitrogen-containing compounds with a carboxy group, nitrogen-containing compounds with a sulfonyl group, nitrogen-containing compounds with a hydroxy group, nitrogen-containing compounds with a hydroxyphenyl group, alcoholic nitrogen-containing compounds, amide derivatives, imide derivatives, and carbamate derivatives. Also included are primary, secondary, and tertiary amine compounds, specifically amine compounds having a hydroxy group, an ether bond, an ester bond, a lactone ring, a cyano group, or a sulfonic ester bond as described in JP-A 2008-111103, paragraphs [0146]-[0164], and compounds having a carbamate group as described in JP 3790649. Addition of such a basic compound may be effective for further suppressing the diffusion rate of an acid in the resist film or correcting the pattern profile.

Suitable quenchers also include onium salts such as sulfonium salts, iodonium salts, and ammonium salts of sulfonic acids which are not fluorinated at α-position, carboxylic acids, or fluorinated alkoxides, as described in JP-A 2008-158339. While an α-fluorinated sulfonic acid, imide acid, or methide acid is necessary to deprotect the acid labile group of a carboxylic acid ester, an α-non-fluorinated sulfonic acid, carboxylic acid, or fluorinated alcohol is released by salt exchange with an α-non-fluorinated onium salt. The α-non-fluorinated sulfonic acid, carboxylic acid, and fluorinated alcohol function as a quencher because they do not induce deprotection reaction.

Exemplary such quenchers include a compound (onium salt of α-non-fluorinated sulfonic acid) having formula (2), a compound (onium salt of carboxylic acid) having formula (3), and a compound (onium salt of alkoxide) having formula (4).

R¹⁰¹—SO₃⁻Mq⁺ (2)

R¹⁰²—CO₂⁻Mq⁺ (3)

R¹⁰³—O⁻Mq⁺ (4)

In formula (2), R¹⁰¹ is a hydrogen atom or a C₁-C₄₀ hydrocarbyl group which may contain a heteroatom, exclusive of the hydrocarbyl group in which the hydrogen atom bonded to the carbon atom at α-position of the sulfo group is substituted by a fluorine atom or a fluoroalkyl group.

The C₁-C₄₀ hydrocarbyl group represented by R¹⁰¹ may be saturated or unsaturated and straight, branched, or cyclic. Specific examples thereof include C₁-C₄₀ alkyl groups such as a methyl group, an ethyl group, a n-propyl group, an isopropyl group, a n-butyl group, an isobutyl group, a sec-butyl group, a tert-butyl group, a n-pentyl group, a tert-pentyl group, a n-hexyl group, a n-octyl group, a 2-ethylhexyl group, a n-nonyl group, and a n-decyl group; C₃-C₄₀ cyclic saturated hydrocarbyl groups such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, an adamantyl group, and an adamantylmethyl group; C₂-C₄₀ alkenyl groups such as a vinyl group, an allyl group, a propenyl group, a butenyl group, and a hexenyl group; C₃-C₄₀ cyclic unsaturated aliphatic hydrocarbyl groups such as a cyclohexenyl group; C₆-C₄₀ aryl groups such as a phenyl group, a naphthyl group, alkylphenyl groups (e.g., a 2-methylphenyl group, a 3-methylphenyl group, a 4-methylphenyl group, a 4-ethylphenyl group, a 4-tert-butylphenyl group, and a 4-n-butylphenyl group), dialkylphenyl groups (e.g., a 2,4-dimethylphenyl group and a 2,4,6-triisopropylphenyl group), alkylnaphthyl groups (e.g., a methylnaphthyl group and an ethylnaphthyl group), and dialkylnaphthyl groups (e.g., a dimethylnaphthyl group and a diethylnaphthyl group); and C₇-C₄₀ aralkyl groups such as a benzyl group, a 1-phenylethyl group, and a 2-phenylethyl group.

In the hydrocarbyl group, some or all of the hydrogen atoms may be substituted by a group containing a heteroatom such as an oxygen atom, a sulfur atom, a nitrogen atom, or a halogen atom, and some constituent —CH₂— may be substituted by a group containing a heteroatom such as an oxygen atom, a sulfur atom, or a nitrogen atom, so that the group may contain a hydroxy group, a cyano group, a carbonyl group, an ether bond, an ester bond, a sulfonic ester bond, a carbonate bond, a lactone ring, a sultone ring, a carboxylic anhydride (—C(═O)—O—C(═O)—), or a haloalkyl group. Suitable heteroatom-containing hydrocarbyl groups include heteroaryl groups such as a thienyl group, alkoxyphenyl groups such as a 4-hydroxyphenyl group, a 4-methoxyphenyl group, a 3-methoxyphenyl group, a 2-methoxyphenyl group, a 4-ethoxyphenyl group, a 4-tert-butoxyphenyl group, and a 3-tert-butoxyphenyl group; alkoxynaphthyl groups such as a methoxynaphthyl group, an ethoxynaphthyl group, a n-propoxynaphthyl group, and a n-butoxynaphthyl group; dialkoxynaphthyl groups such as a dimethoxynaphthyl group and a diethoxynaphthyl group; and aryloxoalkyl groups, typically 2-aryl-2-oxoethyl groups such as a 2-phenyl-2-oxoethyl group, a 2-(1-naphthyl)-2-oxoethyl group, and a 2-(2-naphthyl)-2-oxoethyl group.

In formula (3), R¹⁰² is a C₁-C₄₀ hydrocarbyl group which may contain a heteroatom. Examples of the hydrocarbyl group R¹⁰² are as exemplified above for the hydrocarbyl group R¹⁰¹. Also included are fluorinated alkyl groups such as a trifluoromethyl group, a trifluoroethyl group, a 2,2,2-trifluoro-1-methyl-1-hydroxyethyl group, and a 2,2,2-trifluoro-1-(trifluoromethyl)-1-hydroxyethyl group, and fluorinated aryl groups such as a pentafluorophenyl group and a 4-trifluoromethylphenyl group.

In formula (4), R¹⁰³ is a C₁-C₈ saturated hydrocarbyl group containing at least 3 fluorine atoms or a C₆-C₁₀ aryl group containing at least 3 fluorine atoms, the hydrocarbyl group and the aryl group optionally containing a nitro group.

In formulae (2), (3) and (4), Mq⁺ is an onium cation. The onium cation is preferably a sulfonium cation, an iodonium cation, or an ammonium cation, and more preferably a sulfonium cation. Suitable sulfonium cations are as exemplified in JP-A 2017-219836.

A sulfonium salt of iodized benzene ring-containing carboxylic acid having formula (5) is also useful as the quencher.

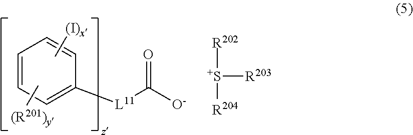

In formula (5), R²⁰¹ is a hydroxy group, a fluorine atom, a chlorine atom, a bromine atom, an amino group, a nitro group, a cyano group, or a C₁-C₆ saturated hydrocarbyl group, a C₁-C₆ saturated hydrocarbyloxy group, a C₂-C₆ saturated hydrocarbylcarbonyloxy group, or a C₁-C₄ saturated hydrocarbylsulfonyloxy group, in which some or all of the hydrogen atoms may be substituted by a halogen atom, or —N(R^{201A})—C(═O)—R^{201B}, or N(R^{201A})—C(═O)—O—R^{201B}. R^{201A} is a hydrogen atom or a C₁-C₆ saturated hydrocarbyl group. R^{201B} is a C₁-C₆ saturated hydrocarbyl group or a C₂-C₈ unsaturated aliphatic hydrocarbyl group.

In formula (5), x′ is an integer of 1 to 5. y′ is an integer of 0 to 3. z′ is an integer of 1 to 3. L¹¹ is a single bond, or a C₁-C₂₀ (z′+1)-valent linking group which may contain at least one moiety selected from an ether bond, a carbonyl group, an ester bond, an amide bond, a sultone ring, a lactam ring, a carbonate bond, a halogen atom, a hydroxy group, and a carboxy group. The saturated hydrocarbyl group, the saturated hydrocarbyloxy group, the saturated hydrocarbylcarbonyloxy group, and the saturated hydrocarbylsulfonyloxy group may be straight, branched, or cyclic. Groups R²⁰¹ may be identical or different when y′ and/or z′ is 2 or more.

In formula (5), R²⁰², R²⁰³, and R²⁰⁴ are each independently a halogen atom or a C₁-C₂₀ hydrocarbyl group which may contain a heteroatom. The hydrocarbyl group may be saturated or unsaturated and straight, branched, or cyclic. Specific examples thereof include C₁-C₂₀ alkyl groups such as a methyl group, an ethyl group, a n-propyl group, an isopropyl group, a n-butyl group, an isobutyl group, a sec-butyl group, a tert-butyl group, a n-pentyl group, a n-hexyl group, a n-octyl group, a n-nonyl group, a n-decyl group, an undecyl group, a dodecyl group, a tridecyl group, a tetradecyl group, a pentadecyl group, a heptadecyl group, an octadecyl group, a nonadecyl group, and an icosyl group; C₃-C₂₀ cyclic saturated hydrocarbyl groups such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; C₂-C₂₀ alkenyl groups such as a vinyl group, a propenyl group, a butenyl group, and a hexenyl group; C₃-C₂₀ cyclic unsaturated aliphatic hydrocarbyl groups such as a cyclohexenyl group and a norbornenyl group; C₂-C₂₀ alkynyl groups such as an ethynyl group, a propynyl group, and a butynyl group; C₆-C₂₀ aryl groups such as a phenyl group, a methylphenyl group, an ethylphenyl group, a n-propylphenyl group, an isopropylphenyl group, a n-butylphenyl group, an isobutylphenyl group, a sec-butylphenyl group, a tert-butylphenyl group, a naphthyl group, a methylnaphthyl group, an ethylnaphthyl group, a n-propylnaphthyl group, an isopropylnaphthyl group, a n-butylnaphthyl group, an isobutylnaphthyl group, a sec-butylnaphthyl group, and a tert-butylnaphthyl group; C₇-C₂₀ aralkyl groups such as a benzyl group and a phenethyl group; and groups obtained by combining these groups. In the hydrocarbyl group, some or all of the hydrogen atoms may be substituted by a hydroxy group, a carboxy group, a halogen atom, an oxo group, a cyano group, a nitro group, a sultone ring, a sulfo group, or a sulfonium salt-containing group, or some constituent —CH₂— may be substituted by an ether bond, an ester bond, a carbonyl group, an amide bond, a carbonate bond, or a sulfonic ester bond. R²⁰² and R²⁰³ may bond together to form a ring with the sulfur atom to which they are attached.

Examples of the compound having formula (5) include those described in JP-A 2017-219836 and JP-A 2021-91666.

Also useful are polymeric quenchers as described in JP-A 2008-239918. The polymeric quencher segregates at the resist film surface and thus enhances the rectangularity of resist pattern. When a protective film is applied as is often the case in the immersion lithography, the polymeric quencher is also effective for preventing a film thickness loss of resist pattern or rounding of pattern top.

Other useful quenchers include sulfonium salts of betaine structure as described in JP 6848776 and JP-A 2020-37544, fluorine-free methide acids as described in JP-A 2020-55797, sulfonium salts of sulfonamide as described in JP 5807552, and sulfonium salts of iodized sulfonamide as described in JP-A 2019-211751.

The quencher is preferably added to the resist composition of the present invention in an amount of 0 to 5 parts by weight, more preferably 0 to 4 parts by weight per 100 parts by weight of the base polymer. The quencher may be used alone or in admixture.

Other Components

In addition to the foregoing components, the resist composition of the present invention may contain other components such as an acid generator of sulfonium or iodonium salt type (referred to as another acid generator, hereinafter), a surfactant, a dissolution inhibitor, a water repellency improver, and an acetylene alcohol.

The other acid generator is typically a compound (photoacid generator) capable of generating an acid upon exposure to actinic ray or radiation. Although the photoacid generator used herein may be any compound capable of generating an acid upon exposure to high-energy radiation, acid generators capable of generating sulfonic acid, imidic acid, or methide acid are preferred. Suitable photoacid generators include sulfonium salts, iodonium salts, sulfonyldiazomethane, N-sulfonyloxyimide, and oxime-O-sulfonate acid generators. Exemplary photoacid generators are described in JP-A 2008-111103, paragraphs [0122]-[0142], JP-A 2018-5224, and JP-A 2018-25789. Especially suited for EUV resist compositions are sulfonium or iodonium salts of iodized sulfonic acid anions as described in JP 6720926 and JP 6743781. In the embodiment wherein the resist composition contains the other acid generator, the other acid generator is preferably used in an amount of 0 to 200 parts by weight, more preferably 0.1 to 100 parts by weight per 100 parts by weight of the base polymer.

Exemplary surfactants are described in JP-A 2008-111103, paragraphs [0165]-[0166]. Inclusion of a surfactant may improve or control the coating characteristics of the resist composition. In the embodiment wherein the resist composition contains the surfactant, the surfactant is preferably added in an amount of 0.0001 to 10 parts by weight per 100 parts by weight of the base polymer. The surfactant may be used alone or in admixture.

In the embodiment wherein the resist composition is of positive tone, the inclusion of a dissolution inhibitor may lead to an increased difference in dissolution rate between exposed and unexposed regions and a further improvement in resolution. The dissolution inhibitor is typically a compound having at least two phenolic hydroxy groups in the molecule, in which an average of from 0 to 100 mol % of all the hydrogen atoms in the phenolic hydroxy groups are substituted by an acid labile group or a compound having at least one carboxy group in the molecule, in which an average of 50 to 100 mol % of all the hydrogen atoms in the carboxy groups are substituted by an acid labile group, both the compounds preferably having a molecular weight of 100 to 1,000, and more preferably 150 to 800. Typical are bisphenol A, trisphenol, phenolphthalein, cresol novolac, naphthalenecarboxylic acid, adamantanecarboxylic acid, and cholic acid derivatives in which the hydrogen atom in the hydroxy or carboxy group is substituted by an acid labile group, as described in JP-A 2008-122932, paragraphs [0155]-[0178].

In the embodiment wherein the resist composition is of positive tone and contains the dissolution inhibitor, the dissolution inhibitor is preferably added in an amount of 0 to 50 parts by weight, more preferably 5 to 40 parts by weight per 100 parts by weight of the base polymer. The dissolution inhibitor may be used alone or in admixture.

To the resist composition, a water repellency improver may also be added for improving the water repellency on surface of a resist film. The water repellency improver may be used in topcoatless immersion lithography. Suitable water repellency improvers include polymers having a fluoroalkyl group and polymers having a specific structure with a 1,1,1,3,3,3-hexafluoro-2-propanol residue, and more suitable water repellency improvers are described in JP-A 2007-297590 and JP-A 2008-111103. The water repellency improver to be added to the resist composition should be soluble in an alkaline developer and an organic solvent developer. The water repellency improver having a specific structure with a 1,1,1,3,3,3-hexafluoro-2-propanol residue is well soluble in the developer. A polymer comprising repeat units having an amino group or an amine salt may serve as the water repellency improver and is effective for preventing evaporation of an acid during PEB, thus preventing any hole pattern opening failure after development. In the embodiment wherein the resist composition contains the water repellency improver, the water repellency improver is preferably added in an amount of 0 to 20 parts by weight, more preferably 0.5 to 10 parts by weight per 100 parts by weight of the base polymer. The water repellency improver may be used alone or in admixture.

Exemplary acetylene alcohols are described in JP-A 2008-122932, paragraphs [0179]-[0182]. In the embodiment wherein the resist composition contains the acetylene alcohol, the acetylene alcohol is preferably added in an amount of 0 to 5 parts by weight per 100 parts by weight of the base polymer. The acetylene alcohol may be used alone or in admixture.

The resist composition of the invention may be prepared by intimately mixing the selected components to form a solution, adjusting so as to meet a predetermined range of sensitivity and film thickness, and filtering the solution. The filtering step is important for reducing the number of defects in a resist pattern after development. The membrane for filtration or filter preferably has a pore size of up to 1 μm, more preferably up to 10 nm, even more preferably up to 5 nm. As the filter pore size is smaller, the number of defects in a small size pattern is reduced. The membrane is typically made of such materials as tetrafluoroethylene, polyethylene, polypropylene, nylon, polyurethane, polycarbonate, polyimide, polyamide-imide, and polysulfone. Membranes of tetrafluoroethylene, polyethylene, and polypropylene which have been surface-modified so as to increase an adsorption ability are also useful. Unlike the membranes of nylon, polyurethane, polycarbonate, and polyimide possessing an ability to adsorb gel and metal ions due to their polarity, membranes of tetrafluoroethylene, polyethylene, and polypropylene which are non-polar do not possess an ability to adsorb gel and metal ions in themselves, but can be endowed with the adsorption ability by surface modification with a functional group having polarity. In particular, filters obtained from surface modification of membranes of polyethylene and polypropylene in which pores of a smaller size can be made are effective for removing not only submicron particles, but also polar particles and metal ions. A laminate of membranes of different materials or a laminate of membranes having different pore sizes is also useful.

A membrane having an ion exchange ability may also be used as the filter. For example, an ion-exchange membrane capable of adsorbing cations acts to adsorb metal ions for thereby reducing metal impurities.

In the practice of filtration, a plurality of filters may be connected. The type and pore size of membranes in the plurality of filters may be the same or different. Filtration may be performed in a pipe connecting a plurality of vessels, or a pipe may be connected to an outlet port and an inlet port provided in a single vessel, and filtration may be performed while the solution is circulated. The filters for filtration may be connected through serial or parallel pipes.

Pattern Forming Process

When the resist composition of the present invention is used in the fabrication of various integrated circuits, a well-known lithography process may be applied. The pattern forming process generally involves the steps of applying the resist composition onto a substrate to form a resist film thereon, exposing the resist film to high-energy radiation, and developing the exposed resist film in a developer.

Specifically, the resist composition of the present invention is first applied onto a substrate on which an integrated circuit is to be formed (e.g., Si, SiO₂, SiN, SiON, TiN, WSi, BPSG, SOG, or organic antireflective coating) or a substrate on which a mask circuit is to be formed (e.g., Cr, CrO, CrON, CrN, MoSi₂, SiO₂, MoSi₂ multilayer film, Ta, TaN, TaCN, Ru, Nb, Mo, Mn, Co, Ni, or alloys thereof) by a suitable coating technique such as spin coating, roll coating, flow coating, dipping, spraying, or doctor coating, so as to have a coating film thickness of 0.01 to 2 μm. The coating is prebaked on a hotplate preferably at a temperature of 60 to 150° C. for 10 seconds to 30 minutes, more preferably at 80 to 120° C. for 30 seconds to 20 minutes to form a resist film.

The resist film is then exposed to high-energy radiation. The high-energy radiation is UV, deep-UV, EB, EUV with a wavelength of 3 to 15 nm, x-ray, soft x-ray, excimer laser light, γ-ray, or synchrotron radiation. When UV, deep-UV, EUV, x-ray, soft x-ray, excimer laser light, γ-ray, or synchrotron radiation is used as the high-energy radiation, the resist film is exposed thereto through a mask having a desired pattern preferably at a dose of about 1 to 200 mJ/cm², more preferably about 10 to 100 mJ/cm². When EB is used as the high-energy radiation, the resist film is exposed thereto directly or through a mask having a desired pattern preferably at a dose of about 0.1 to 300 μC/cm², more preferably about 0.5 to 200 μC/cm². It is appreciated that the resist composition of the present invention is suited in micropatterning using KrF excimer laser, ArF excimer laser, EB, EUV, x-ray, soft x-ray, γ-ray, or synchrotron radiation, especially in micropatterning using EB or EUV.

After the exposure, PEB may be performed on a hotplate or in an oven preferably at 30 to 150° C. for 10 seconds to 30 minutes, more preferably at 50 to 120° C. for 30 seconds to 20 minutes.

After the exposure or PEB, the resist film is developed in a developer in the form of an alkaline aqueous solution for 3 seconds to 3 minutes, preferably 5 seconds to 2 minutes by conventional techniques such as dip, puddle, and spray techniques to form a desired pattern. A typical developer is a 0.1 to 10 wt %, preferably 2 to 5 wt % aqueous solution of tetramethylammonium hydroxide (TMAH), tetraethylammonium hydroxide (TEAH), tetrapropylammonium hydroxide (TPAH), or tetrabutylammonium hydroxide (TBAH). When the resist composition is of positive tone, the resist film in the exposed region is dissolved in the developer whereas the resist film in the unexposed region is not dissolved. In this way, the desired positive pattern is formed on the substrate. When the resist composition is of negative tone, inversely the resist film in the exposed region is insolubilized whereas the resist film in the unexposed region is dissolved away.

In an alternative embodiment, a negative pattern can be obtained from the positive resist composition comprising a base polymer containing an acid labile group by effecting organic solvent development. The developer used herein is preferably selected from among 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. The organic solvents may be used alone or in admixture.

At the end of development, the resist film is rinsed. As the rinsing liquid, a solvent which is miscible with the developer and does not dissolve the resist film is preferred. Suitable solvents include alcohols of 3 to 10 carbon atoms, ether compounds of 8 to 12 carbon atoms, alkanes, alkenes, and alkynes of 6 to 12 carbon atoms, and aromatic solvents.

Specifically, suitable alcohols of 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Suitable ether compounds of 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Suitable alkanes of 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Suitable alkenes of 6 to 12 carbon atoms include hexene, heptene, octene, cyclohexene, methylcyclohexene, dimethylcyclohexene, cycloheptene, and cyclooctene. Suitable alkynes of 6 to 12 carbon atoms include hexyne, heptyne, and octyne.

Suitable aromatic solvents include toluene, xylene, ethylbenzene, isopropylbenzene, tert-butylbenzene, and mesitylene.

Rinsing is effective for reducing resist pattern collapse and defect formation. However, rinsing is not essential. If rinsing is omitted, the amount of solvent used may be reduced.

A hole or trench pattern after development may be shrunk by the thermal flow, RELACS® or DSA process. A hole pattern is shrunk by applying a shrink agent thereto, and baking such that the shrink agent may undergo crosslinking at the resist film surface as a result of the acid catalyst diffusing from the resist film during bake, and the shrink agent may attach to the sidewall of the hole pattern. The bake is preferably performed at a temperature of 70 to 180° C., more preferably 80 to 170° C., for a time of 10 to 300 seconds. The extra shrink agent is stripped and the hole pattern is shrunk.

### Examples

Examples of the invention are given below by way of illustration and not by way of limitation.

Monomers PM-1 to PM-21, cPM-1, cPM-2, AM-1 to AM-4, and FM-1 used in the synthesis of base polymers are shown below. Monomers PM-1 to PM-16 were synthesized by ion exchange between an ammonium salt of fluorinated sulfonic acid providing the anion shown below and a sulfonium chloride providing the cation shown below. The Mw of a polymer is determined versus polystyrene standards by GPC using THF as a solvent.

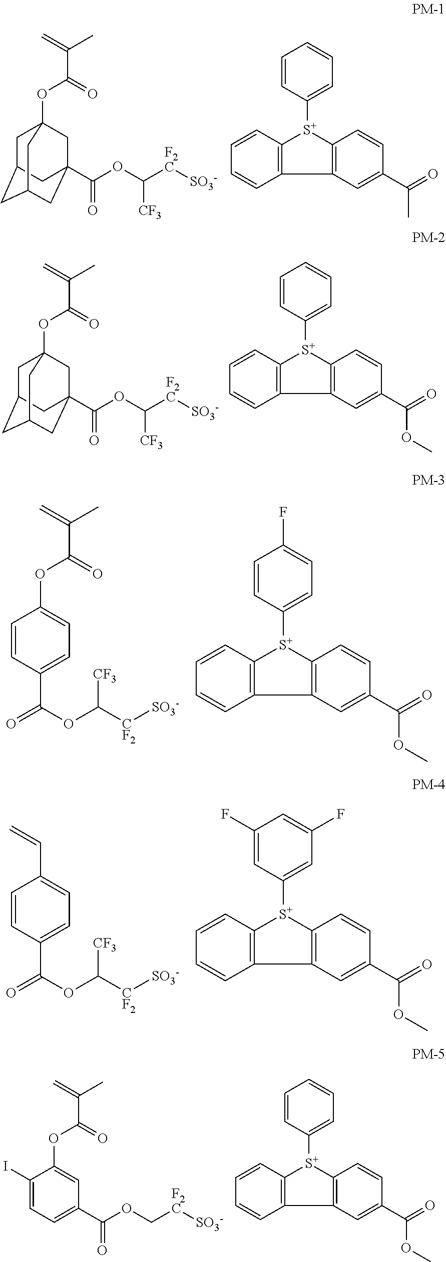

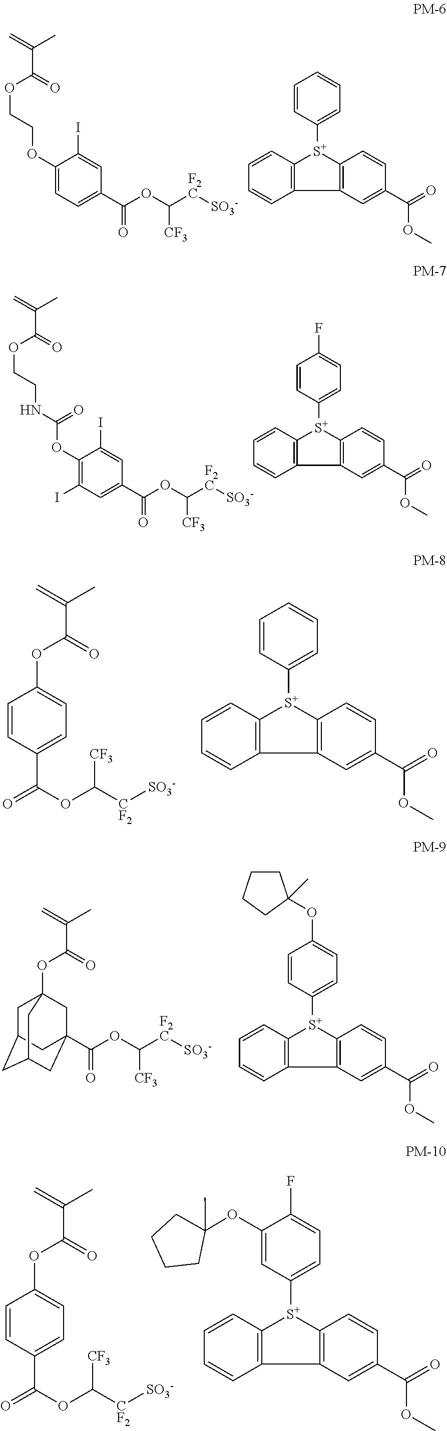

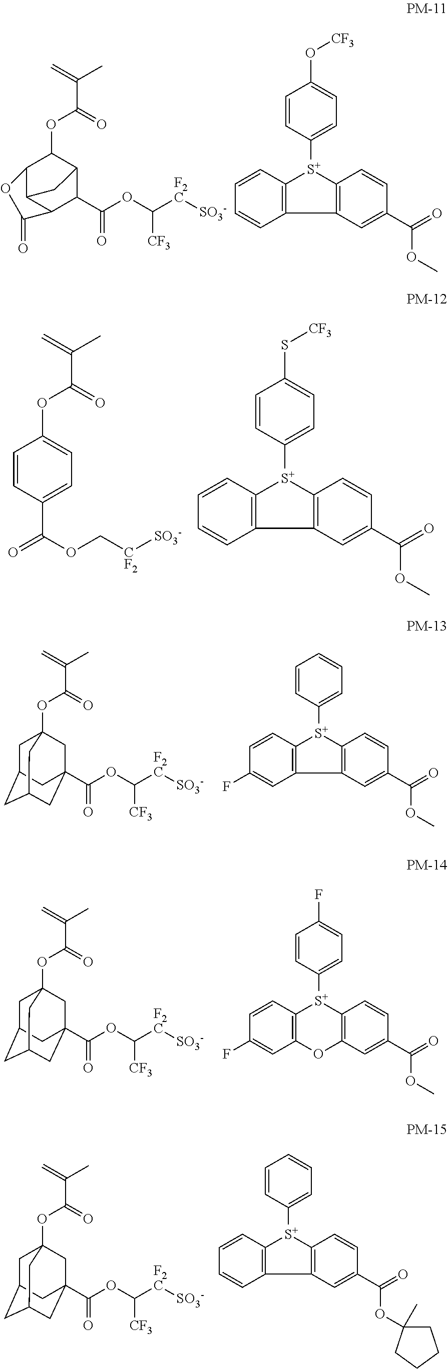

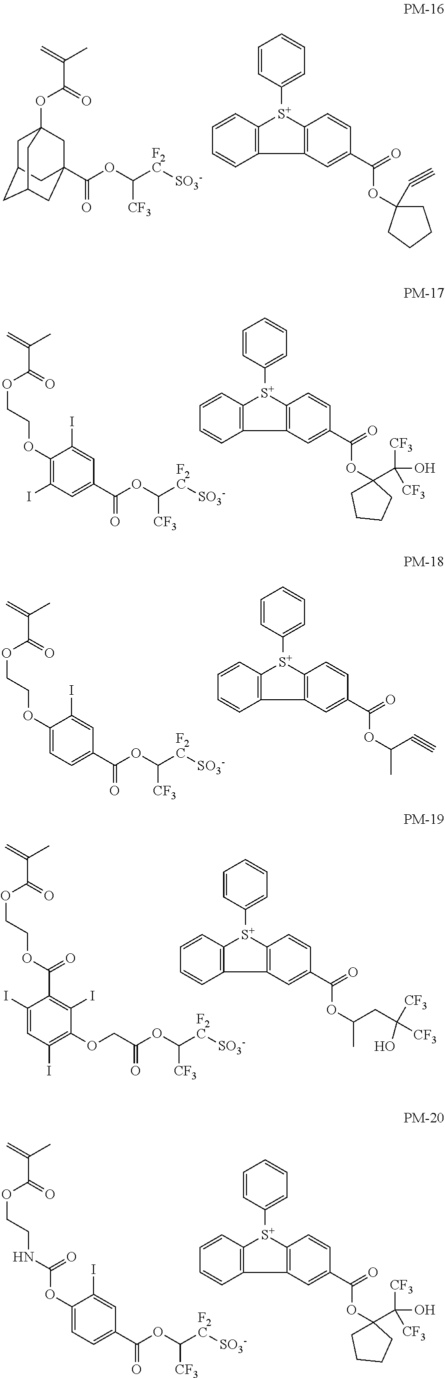

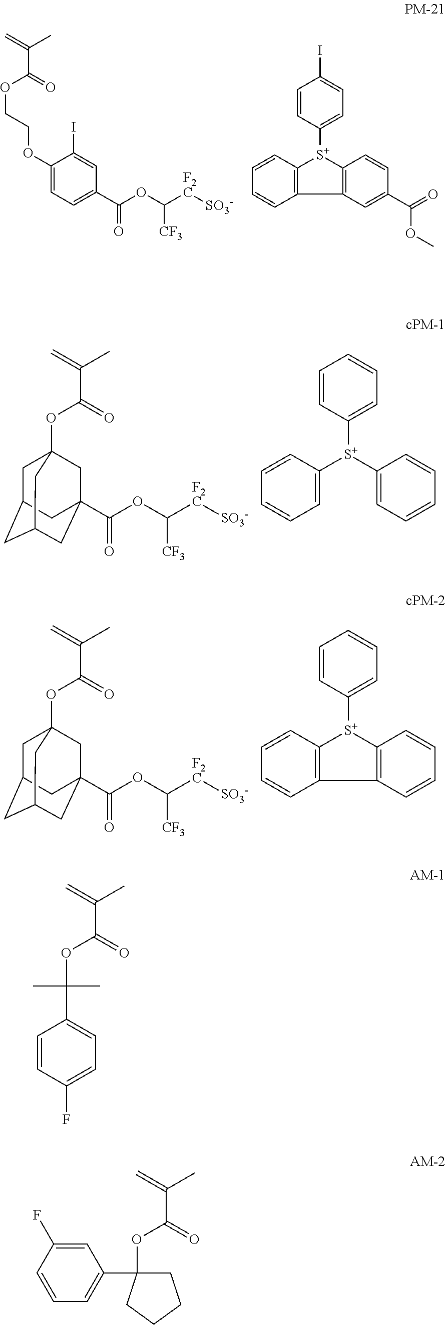

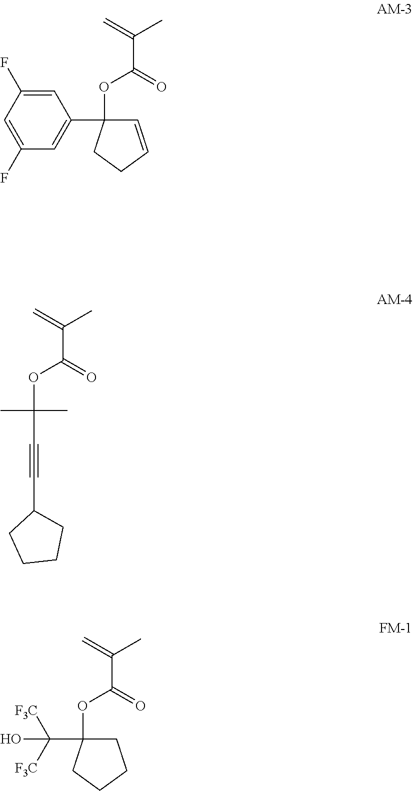

### Synthesis Example 1 Synthesis of Polymer P-1

A 2-L flask was charged with 8.4 g of 1-methyl-1-cyclopentyl methacrylate, 4.8 g of 4-hydroxystyrene, 7.8 g of PM-1, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-1. Polymer P-1 was analyzed for composition by ¹³C-NMR and ¹H-NMR and for Mw and Mw/Mn by GPC.

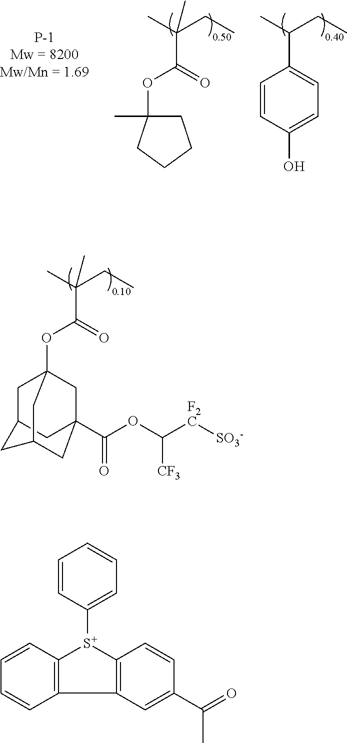

### Synthesis Example 2 Synthesis of Polymer P-2

A 2-L flask was charged with 11.1 g of AM-1, 4.8 g of 3-hydroxystyrene, 7.9 g of PM-2, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-2. Polymer P-2 was analyzed for composition by ¹³C-NMR and ¹H-NMR and for Mw and Mw/Mn by GPC.

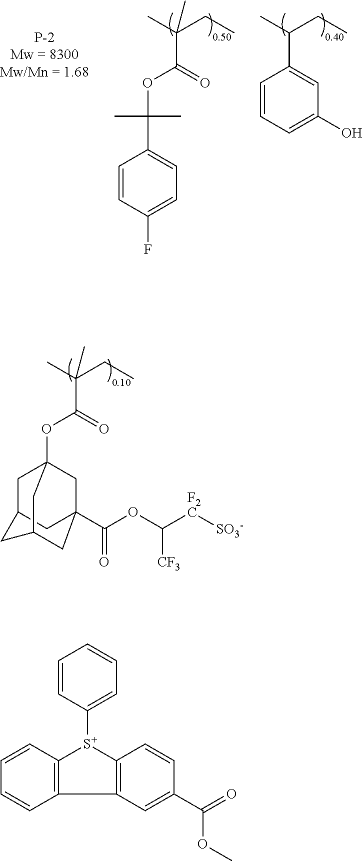

### Synthesis Example 3 Synthesis of Polymer P-3

A 2-L flask was charged with 11.1 g of AM-1, 4.8 g of 3-hydroxystyrene, 7.5 g of PM-3, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-3. Polymer P-3 was analyzed for composition by ¹³C-NMR and ¹H-NMR and for Mw and Mw/Mn by GPC.

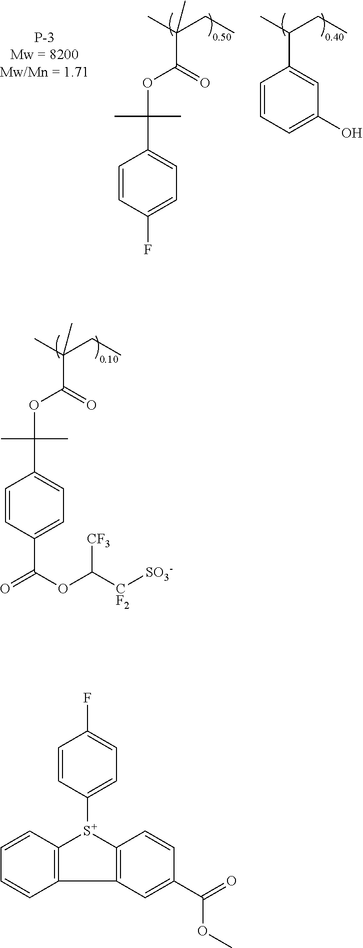

### Synthesis Example 4 Synthesis of Polymer P-4

A 2-L flask was charged with 8.7 g of AM-2, 4.0 g of AM-4, 4.8 g of 3-hydroxystyrene, 7.1 g of PM-4, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-4. Polymer P-4 was analyzed for composition by ¹³C-NMR and ¹H-NMR and for Mw and Mw/Mn by GPC.

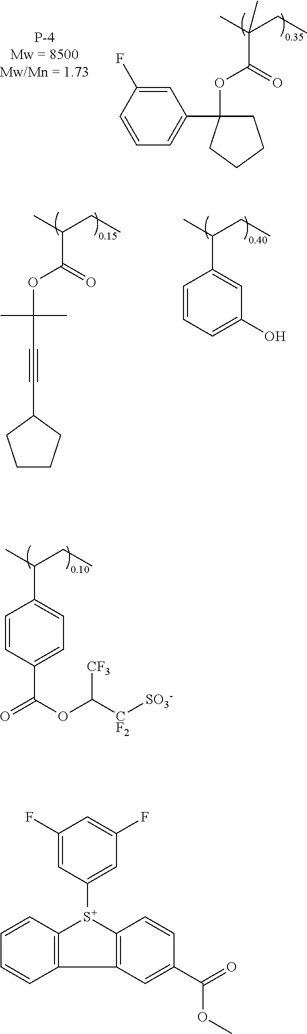

### Synthesis Example 5 Synthesis of Polymer P-5

A 2-L flask was charged with 12.7 g of AM-3, 5.2 g of 3-hydroxystyrene, 7.2 g of PM-5, and 40 g of THF solvent. The reactor was cooled at −70° C. in nitrogen atmosphere, was after which vacuum pumping and nitrogen blow were repeated three times. The reactor warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-5. Polymer P-5 was analyzed for composition by ¹³C-NMR and ¹H-NMR and for Mw and Mw/Mn by GPC.

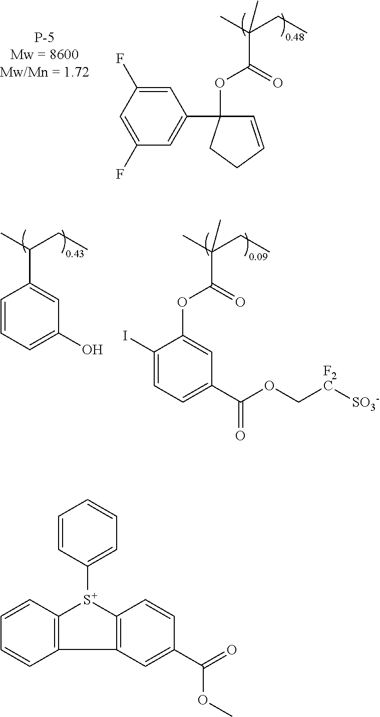

### Synthesis Example 6 Synthesis of Polymer P-6

A 2-L flask was charged with 11.1 g of AM-1, 4.8 g of 3-hydroxystyrene, 9.1 g of PM-6, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-6. Polymer P-6 was analyzed for composition by ¹³C-NMR and ¹H-NMR and for Mw and Mw/Mn by GPC.

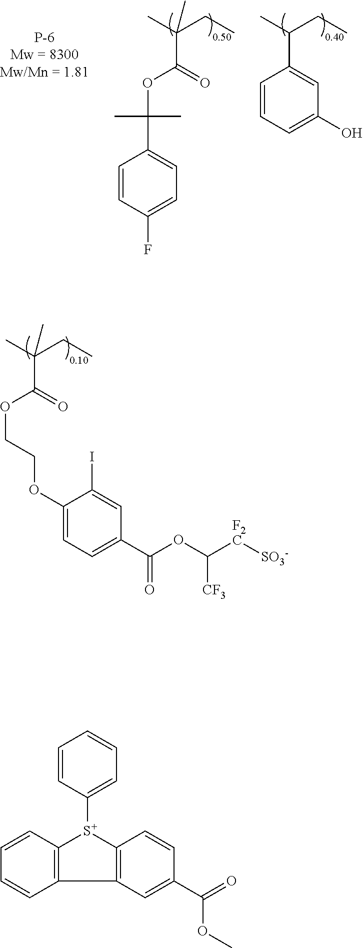

### Synthesis Example 7 Synthesis of Polymer P-7

A 2-L flask was charged with 11.1 g of AM-1, 3.4 g of 3-hydroxystyrene, 3.2 g of monomer FM-1, 13.1 g of PM-7, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-7. Polymer P-7 was analyzed for composition by ¹³C-NMR and ¹H-NMR and for Mw and Mw/Mn by GPC.

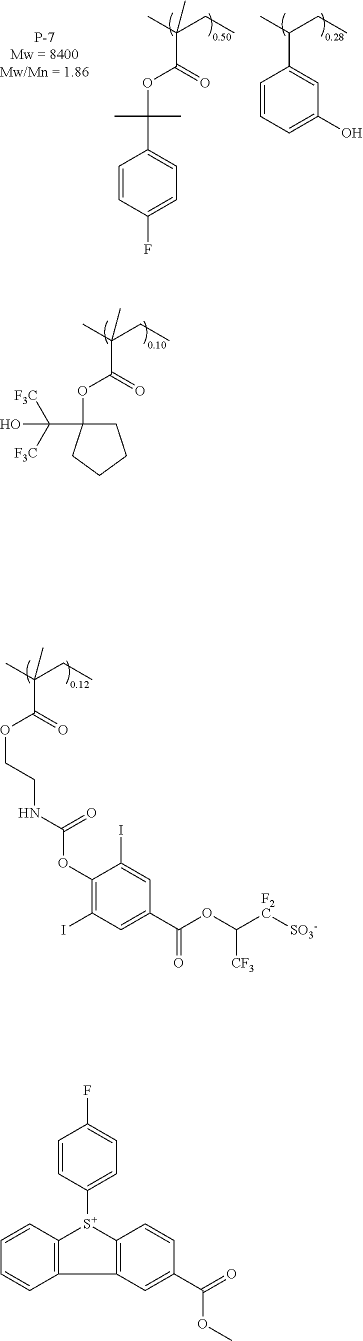

### Synthesis Example 8 Synthesis of Polymer P-8

A 2-L flask was charged with 11.1 g of AM-1, 4.8 g of 3-hydroxystyrene, 7.4 g of PM-8, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-8. Polymer P-8 was analyzed for composition by ¹³C-NMR and ¹H-NMR and for Mw and Mw/Mn by GPC.

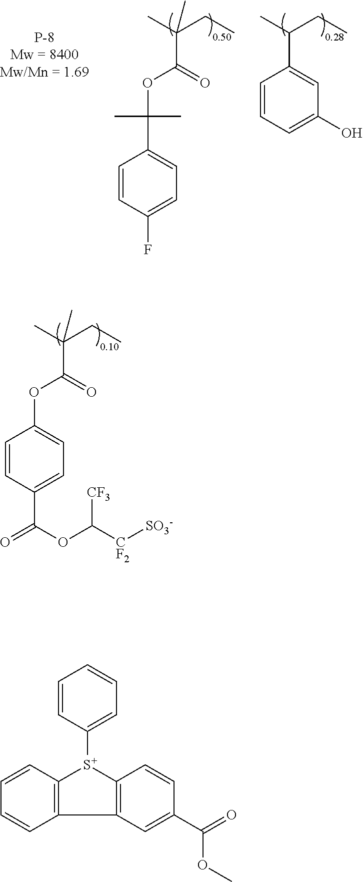

### Synthesis Example 9 Synthesis of Polymer P-9

A 2-L flask was charged with 11.1 g of AM-1, 4.8 g of 3-hydroxystyrene, 8.9 g of PM-9, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-9. Polymer P-9 was analyzed for composition by ¹³C-NMR and ¹H-NMR and for Mw and Mw/Mn by GPC.

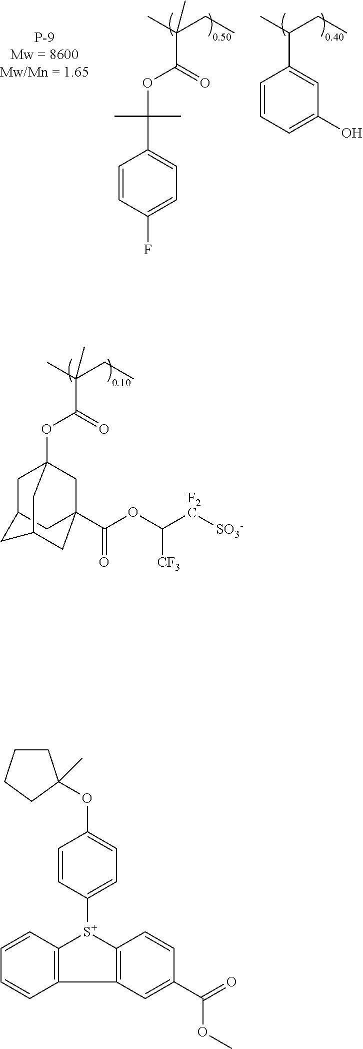

### Synthesis Example 10 Synthesis of Polymer P-10

A 2-L flask was charged with 11.1 g of AM-1, 4.8 g of 3-hydroxystyrene, 8.5 g of PM-10, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-10. Polymer P-10 was analyzed for composition by ¹³C-NMR and ¹H-NMR and for Mw and Mw/Mn by GPC.

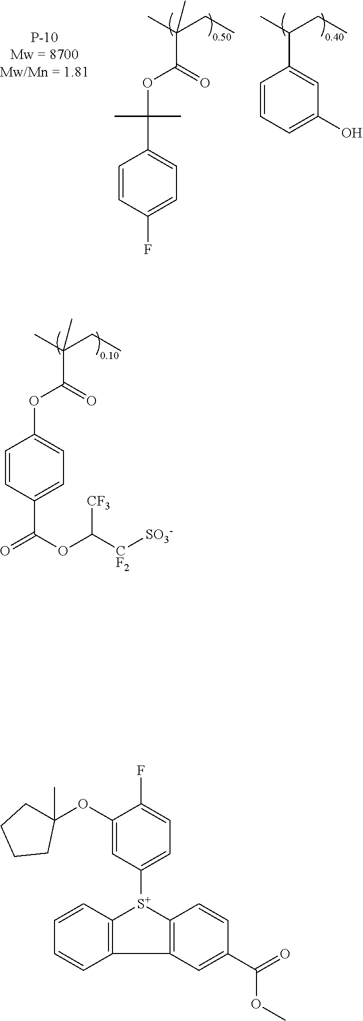

### Synthesis Example 11 Synthesis of Polymer P-11

A 2-L flask was charged with 11.1 g of AM-1, 4.8 g of 3-hydroxystyrene, 8.8 g of PM-11, and 40 g of THE solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-11. Polymer P-11 was analyzed for composition by ¹³C-NMR and ¹H-NMR and for Mw and Mw/Mn by GPC.

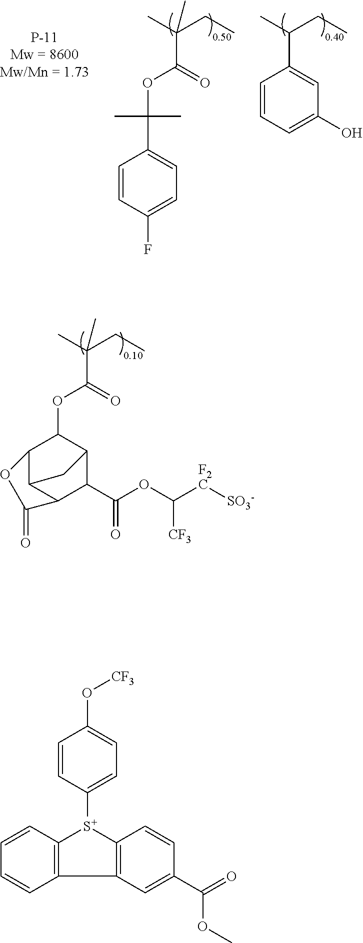

### Synthesis Example 12 Synthesis of Polymer P-12

A 2-L flask was charged with 11.1 g of AM-1, 4.8 g of 3-hydroxystyrene, 7.7 g of PM-12, and 40 g of THE solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-12. Polymer P-12 was analyzed for composition by ¹³C-NMR and ¹H-NMR and for Mw and Mw/Mn by GPC.

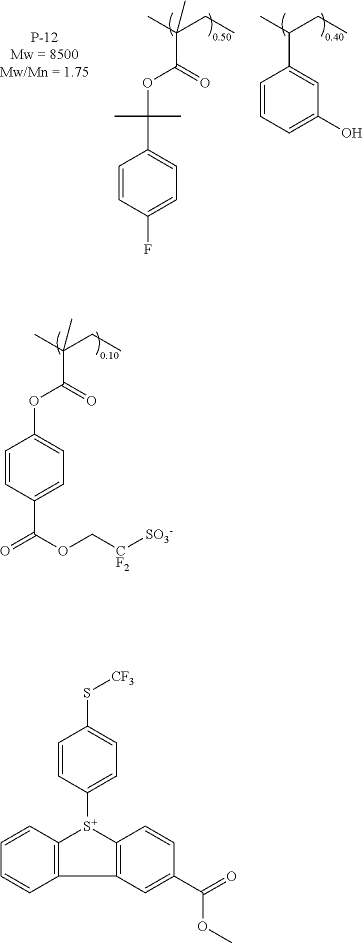

### Synthesis Example 13 Synthesis of Polymer P-13

A 2-L flask was charged with 11.1 g of AM-1, 4.8 g of 3-hydroxystyrene, 8.1 g of PM-13, and 40 g of THE solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-13. Polymer P-13 was analyzed for composition by ¹³C-NMR and ¹H-NMR and for Mw and Mw/Mn by GPC.

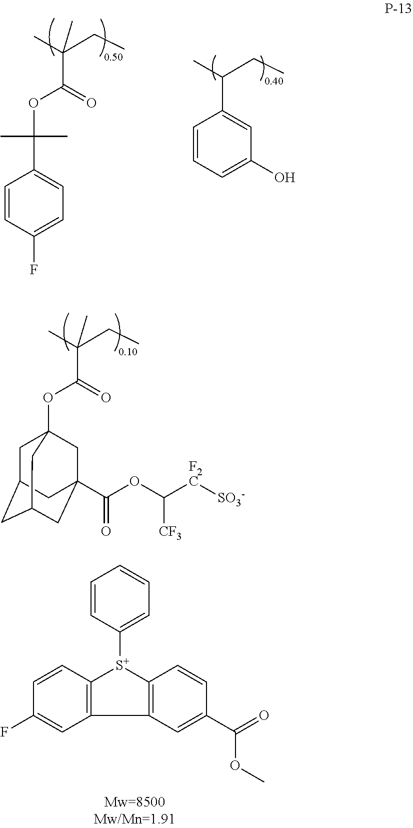

### Synthesis Example 14 Synthesis of Polymer P-14

A 2-L flask was charged with 11.1 g of AM-1, 4.8 g of 3-hydroxystyrene, 7.7 g of PM-14, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-14. Polymer P-14 was analyzed for composition by ¹³C-NMR and ¹H-NMR and for Mw and Mw/Mn by GPC.

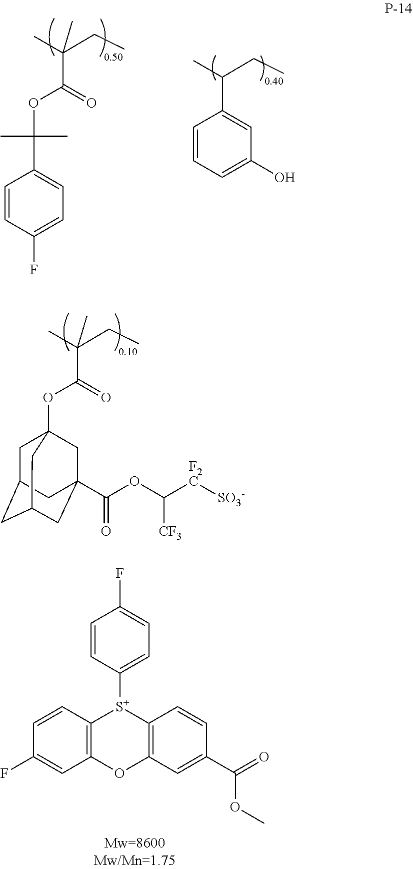

### Synthesis Example 15 Synthesis of Polymer P-15

A 2-L flask was charged with 11.1 g of AM-1, 4.8 g of 3-hydroxystyrene, 8.6 g of PM-15, and 40 g of THE solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-15. Polymer P-15 was analyzed for composition by ¹³C-NMR and ¹H-NMR and for Mw and Mw/Mn by GPC.

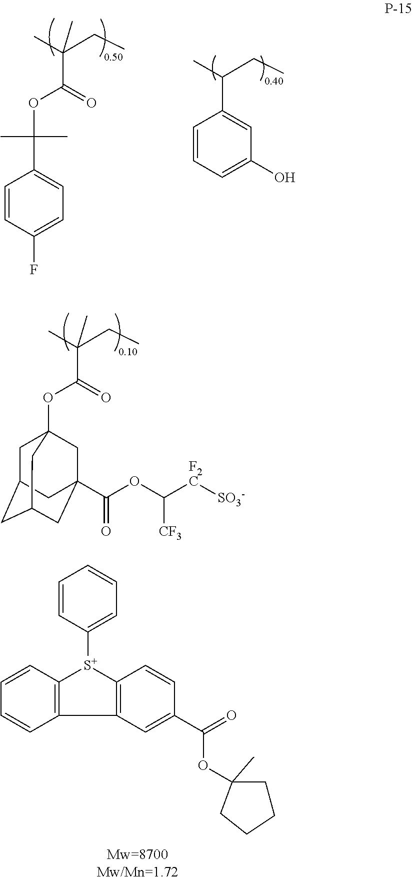

### Synthesis Example 16 Synthesis of Polymer P-16

A 2-L flask was charged with 11.1 g of AM-1, 4.8 g of 3-hydroxystyrene, 8.7 g of PM-16, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-16. Polymer P-16 was analyzed for composition by ¹³C-NMR and ¹H-NMR and for Mw and Mw/Mn by GPC.

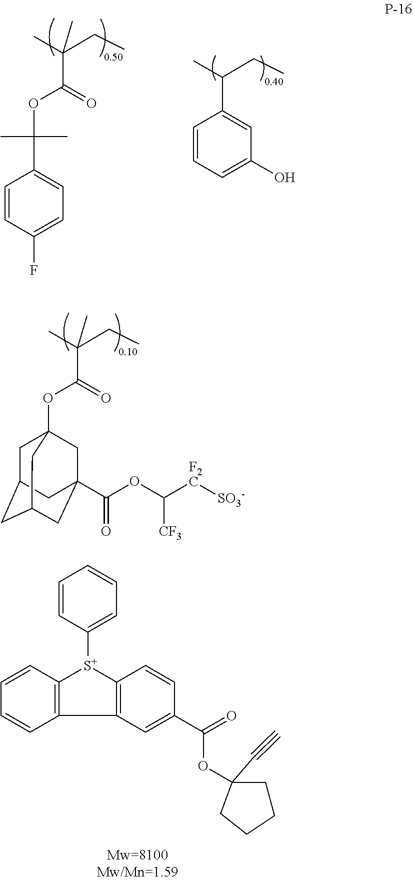

### Synthesis Example 17 Synthesis of Polymer P-17

A 2-L flask was charged with 11.1 g of AM-1, 4.8 g of 3-hydroxystyrene, 12.5 g of PM-17, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-17. Polymer P-17 was analyzed for composition by ¹³C-NMR and ¹H-NMR and for Mw and Mw/Mn by GPC.

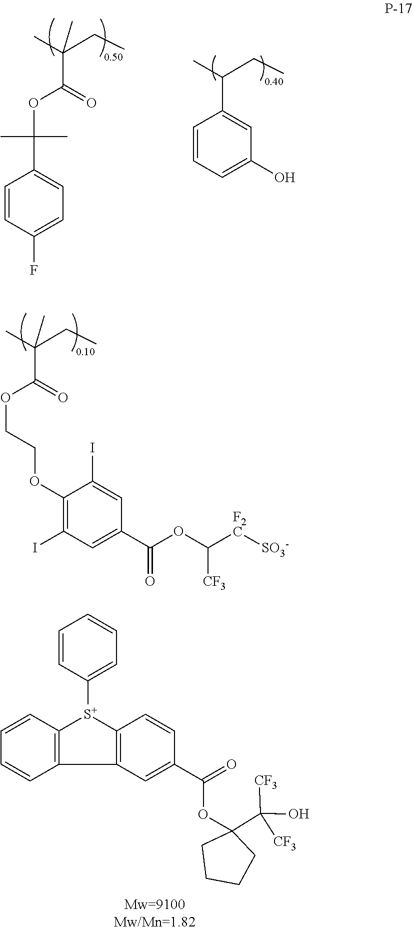

### Synthesis Example 18 Synthesis of Polymer P-18

A 2-L flask was charged with 11.1 g of AM-1, 4.8 g of 3-hydroxystyrene, 9.4 g of PM-18, and 40 g of THE solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-18. Polymer P-18 was analyzed for composition by ¹³C-NMR and ¹H-NMR and for Mw and Mw/Mn by GPC.

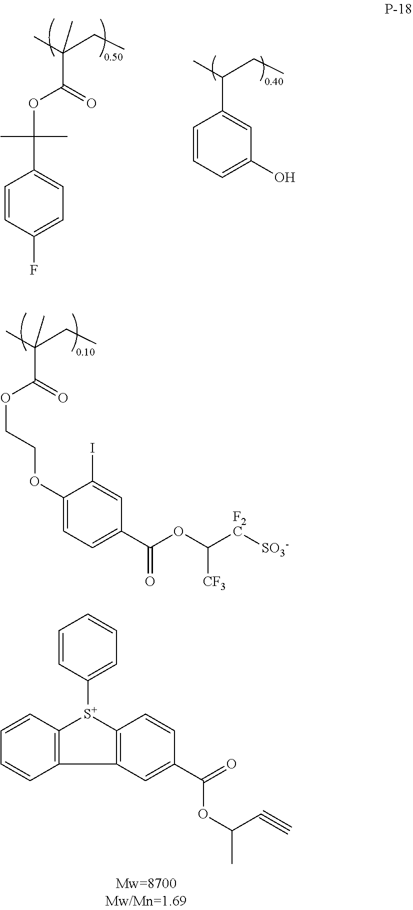

### Synthesis Example 19 Synthesis of Polymer P-19

A 2-L flask was charged with 11.1 g of AM-1, 4.8 g of 4-hydroxystyrene, 14.1 g of PM-19, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-19. Polymer P-19 was analyzed for composition by ¹³C-NMR and ¹H-NMR and for Mw and Mw/Mn by GPC.

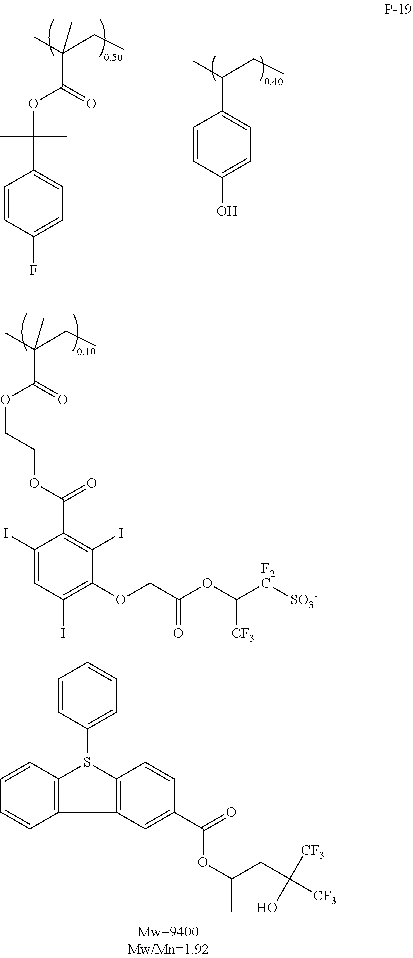

### Synthesis Example 20 Synthesis of Polymer P-20

A 2-L flask was charged with 11.1 g of AM-1, 4.8 g of 3-hydroxystyrene, 11.6 g of PM-20, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-20. Polymer P-20 was analyzed for composition by ¹³C-NMR and ¹H-NMR and for Mw and Mw/Mn by GPC.

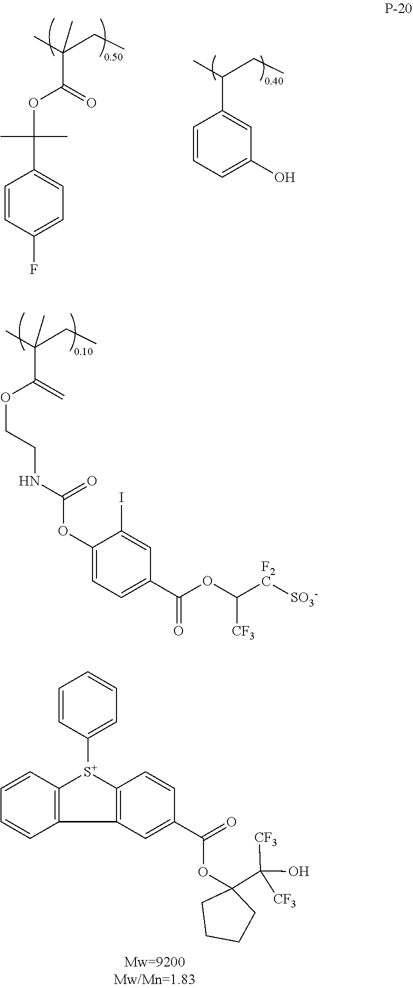

### Synthesis Example 21 Synthesis of Polymer P-21

A 2-L flask was charged with 11.1 g of AM-1, 4.8 g of 4-hydroxystyrene, 10.3 g of PM-21, and 40 g of THF solvent. The reactor was cooled at −70° C. in nitrogen atmosphere, after which vacuum pumping and nitrogen blow were repeated three times. The reactor was warmed up to room temperature, whereupon 1.2 g of AIBN as a polymerization initiator was added, and the reactor was heated at 60° C., whereupon reaction ran for 15 hours. The reaction solution was poured into 1 L of isopropyl alcohol for precipitation, and the resulting white solid was collected by filtration. The resulting white solid was vacuum dried at 60° C., yielding Polymer P-21. Polymer P-21 was analyzed for composition by ¹³C-NMR and ¹H-NMR and for Mw and Mw/Mn by GPC.

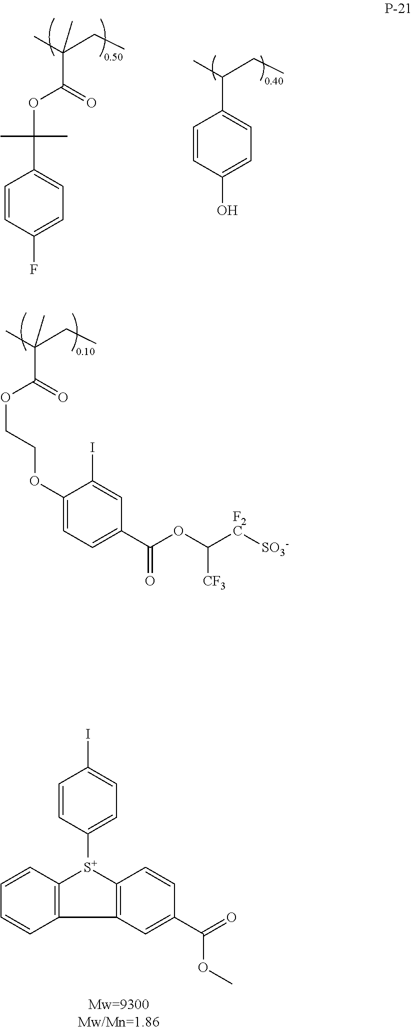

### Comparative Synthesis Example 1 Synthesis of Comparative Polymer cP-1

Comparative Polymer cP-1 was synthesized by the same procedure as in Synthesis Example 1 aside from using cPM-1 instead of PM-1.

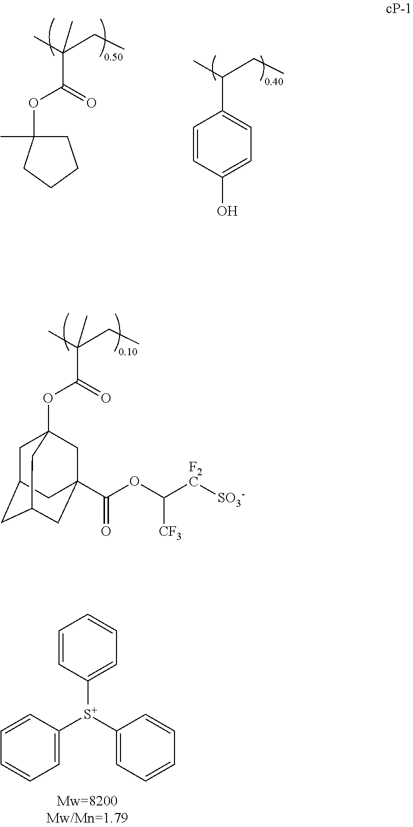

### Comparative Synthesis Example 2 Synthesis of Comparative Polymer cP-2

Comparative Polymer cP-2 was synthesized by the same procedure as in Synthesis Example 1 aside from using cPM-2 instead of PM-1.

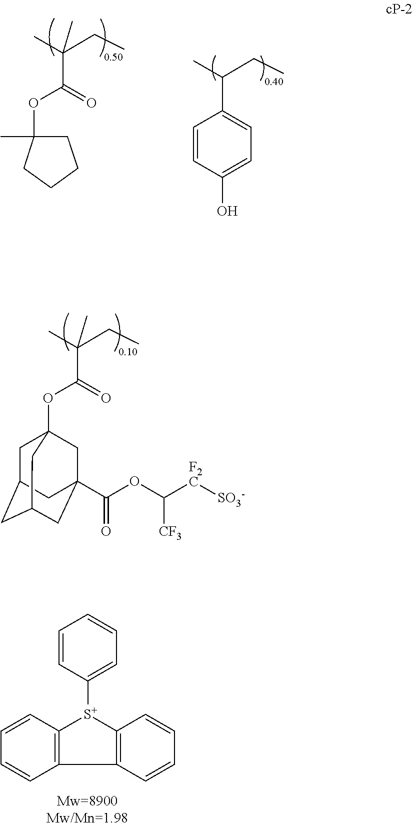

### Examples 1 to 23 and Comparative Examples 1 and 2 Preparation and Evaluation of Resist Compositions

(1) Preparation of Resist Compositions

Resist compositions were prepared by dissolving components in a solvent in accordance with the recipe shown in Table 1, and filtering the solution through a filter having a pore size of 0.2 μm. The solvent contained 100 ppm of surfactant Polyfox PF-636 (Omnova Solutions, Inc.).

The components in Table 1 are identified below.

Organic Solvents:
PGMEA (propylene glycol monomethyl ether acetate)
EL (ethyl lactate)
DAA (diacetone alcohol)

Acid Generator: PAG-1

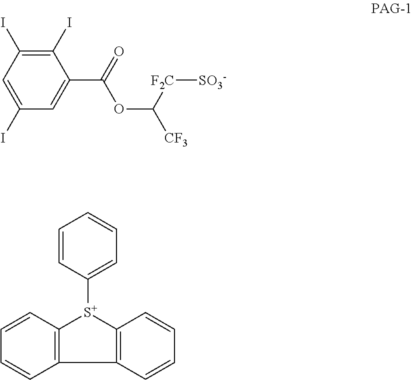

Quenchers: Q-1 to Q-5

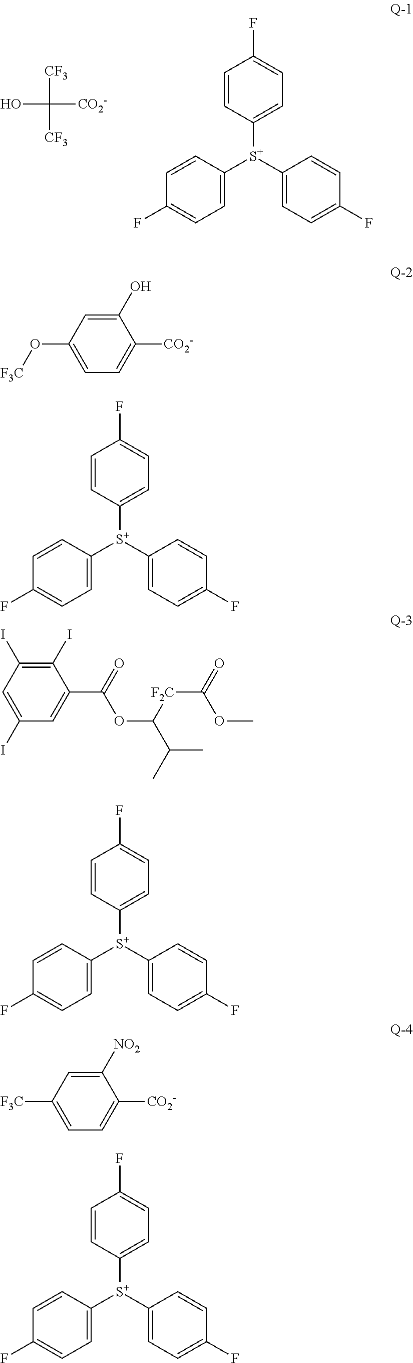

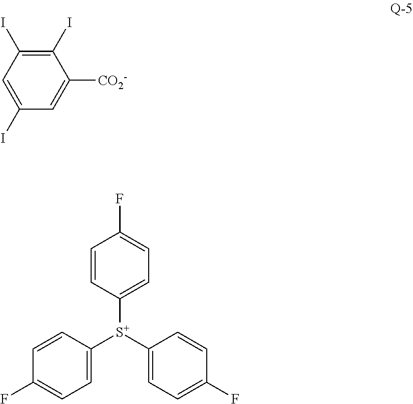

(2) EUV Lithography Test

Each of the resist compositions in Table 1 was applied by spin coating to a silicon substrate having a 20-nm coating of silicon-containing spin-on hard mask SHB-A940 (Shin-Etsu Chemical Co., Ltd., Si content 43 wt %) and prebaked on a hotplate at 105° C. for 60 seconds to form a resist film of 60 nm thick. The resist film was exposed using an EUV scanner NXE3400 (ASML, NA 0.33, a 0.9/0.6, quadrupole illumination, a mask bearing a hole pattern at a pitch of 40 nm (on-wafer size) and +20% bias), PEB was performed at a temperature shown in Table 1 for 60 seconds on a hot plate, and development was performed in a 2.38 wt % TMAH aqueous solution for 30 seconds to form a hole pattern having a size of 20 nm.

The resist pattern was observed under CD-SEM (CG6300, Hitachi High-Technologies Corp.). The exposure dose that provides a hole pattern having a size of 20 nm is reported as sensitivity. The size of 50 holes printed at that dose was measured, from which a 3-fold value (3σ) of the standard deviation (σ) was computed and reported as CDU. The results are shown in Table 1.

TABLE 1

| | | Polymer | Acid generator | Quencher | Organic solvent | PEB temp. | Sensitivity | CDU |
|---|---|---|---|---|---|---|---|---|
| | | (pbw) | (pbw) | (pbw) | (pbw) | (° C.) | (mJ/cm²) | (nm) |
| Example | 1 | P-1 | — | Q-1 | PGMEA (500) | 90 | 28 | 2.8 |
| | | (100) | | (5.28) | EL (2000) | | | |
| | 2 | P-2 | — | Q-1 | PGMEA (500) | 90 | 29 | 2.6 |
| | | (100) | | (5.28) | EL (2000) | | | |
| | 3 | P-3 | — | Q-1 | PGMEA (500) | 90 | 27 | 2.6 |
| | | (100) | | (5.28) | EL (2000) | | | |
| | 4 | P-4 | — | Q-1 | PGMEA (2000) | 90 | 26 | 2.7 |
| | | (100) | | (5.28) | DAA (500) | | | |
| | 5 | P-5 | — | Q-1 | PGMEA (2000) | 80 | 28 | 2.5 |
| | | (100) | | (5.28) | DAA (500) | | | |
| | 6 | P-6 | — | Q-1 | PGMEA (2000) | 90 | 26 | 2.8 |
| | | (100) | | (5.28) | DAA (500) | | | |
| | 7 | P-7 | — | Q-1 | PGMEA (2000) | 90 | 25 | 2.7 |
| | | (100) | | (5.28) | DAA (500) | | | |
| | 8 | P-8 | — | Q-2 | PGMEA (2000) | 90 | 27 | 2.6 |
| | | (100) | | (5.38) | DAA (500) | | | |
| | 9 | P-9 | — | Q-2 | PGMEA (2000) | 90 | 28 | 2.5 |
| | | (100) | | (5.38) | DAA (500) | | | |
| | 10 | P-10 | — | Q-3 | PGMEA (2000) | 90 | 27 | 2.4 |
| | | (100) | | (9.66) | DAA (500) | | | |
| | 11 | P-11 | — | Q-3 | PGMEA (2000) | 90 | 24 | 2.6 |
| | | (100) | | (9.66) | DAA (500) | | | |
| | 12 | P-12 | — | Q-4 | PGMEA (2000) | 85 | 27 | 2.5 |
| | | (100) | | (5.51) | DAA (500) | | | |
| | 13 | P-13 | — | Q-5 | PGMEA (2000) | 90 | 25 | 2.5 |
| | | (100) | | (8.16) | DAA (500) | | | |
| | 14 | P-1 | PAG-1 | Q-1 | PGMEA (2000) | 85 | 24 | 2.8 |
| | | (100) | (5.0) | (5.28) | DAA (500) | | | |
| | 15 | P-14 | — | Q-3 | PGMEA (2000) | 90 | 24 | 2.7 |
| | | (100) | | (9.66) | DAA (500) | | | |
| | 16 | P-15 | — | Q-3 | PGMEA (2000) | 90 | 27 | 2.6 |
| | | (100) | | (9.66) | DAA (500) | | | |
| | 17 | P-16 | — | Q-3 | PGMEA (2000) | 90 | 26 | 2.5 |
| | | (100) | | (9.66) | DAA (500) | | | |
| | 18 | P-17 | — | Q-3 | PGMEA (2000) | 90 | 26 | 2.7 |
| | | (100) | | (9.66) | DAA (500) | | | |
| | 19 | P-18 | — | Q-3 | PGMEA (2000) | 90 | 27 | 2.6 |
| | | (100) | | (9.66) | DAA (500) | | | |
| | 20 | P-19 | — | Q-3 | PGMEA (2000) | 90 | 26 | 2.6 |
| | | (100) | | (9.66) | DAA (500) | | | |
| | 21 | P-20 | — | Q-3 | PGMEA (2000) | 90 | 28 | 2.6 |
| | | (100) | | (9.66) | DAA (500) | | | |
| | 22 | P-21 | — | Q-3 | PGMEA (2000) | 90 | 29 | 2.7 |
| | | (100) | | (9.66) | DAA (500) | | | |
| | 23 | P-6 | PAG-1 | Q-3 | PGMEA (2000) | 90 | 22 | 2.7 |
| | | (100) | (9.7) | (9.66) | DAA (500) | | | |
| Comparative | 1 | cP-1 | — | Q-1 | PGMEA (2000) | 90 | 32 | 3.2 |
| Example | | (100) | | (5.28) | DAA (500) | | | |
| | 2 | cP-2 | — | Q-1 | PGMEA (2000) | 90 | 30 | 3.0 |
| | | (100) | | (5.28) | DAA (500) | | | |

It is demonstrated in Table 1 that resist compositions of the present invention comprising a base polymer comprising repeat units having a salt structure consisting of a sulfonic acid anion bonded to a polymer backbone and a sulfonium cation having formula (1) as the acid generator offer excellent CDU.

Japanese Patent Application No. 2022-162323 is incorporated herein by reference. Although some preferred embodiments have been described, many modifications and variations may be made thereto in light of the above teachings. It is therefore to be understood that the invention may be practiced otherwise than as specifically described without departing from the scope of the appended claims.

1. A resist composition comprising a base polymer comprising repeat units (a) having a salt structure consisting of a sulfonic acid anion bonded to a polymer backbone and a sulfonium cation having formula (1): 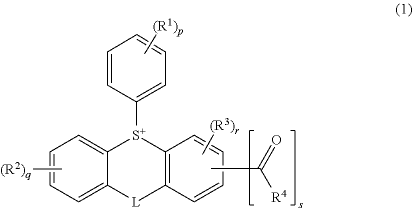
wherein p, q, and r are each independently an integer of 0 to 3, and s is 1 or 2, provided that 1≤r+s≤3,
R¹ and R² are each independently a halogen atom, a trifluoromethyl group, a trifluoromethoxy group, a trifluoromethylthio group, a nitro group, a cyano group, —C(═O)—R⁴, —O—C(═O)—R⁵, or —O—R⁵,
R³ is a halogen atom, a trifluoromethyl group, a trifluoromethoxy group, a trifluoromethylthio group, a nitro group, a cyano group, —O—C(═O)—R⁵, or —O—R⁵,
R⁴ is a C₁-C₁₀ hydrocarbyl group, a C₁-C₁₀ hydrocarbyloxy group, or —O—R^{4A}, and the hydrocarbyl group and the hydrocarbyloxy group may be substituted by a fluorine atom or a hydroxy group, R^{4A} is an acid labile group,
R⁵ is a C₁-C₁₀ hydrocarbyl group, and
L is a single bond, an ether bond, a carbonyl group, —N(R)—, a sulfide bond, or a sulfonyl group, and R is a hydrogen atom or a C₁-C₆ saturated hydrocarbyl group.

2. The resist composition of claim 1 wherein the repeat units (a) have formula (a1) or (a2): 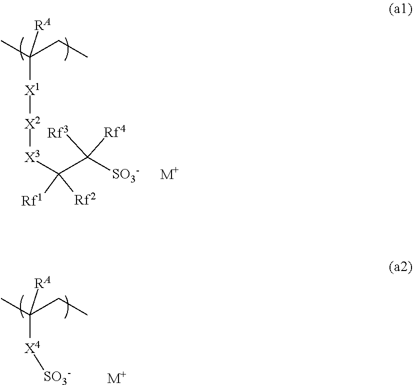
wherein R^{A} is each independently a hydrogen atom or a methyl group,
X¹ is a single bond or an ester bond,
X² is a single bond, —X²¹—C(═O)—O—, or —X²¹—O—, wherein X²¹ is a C₁-C₁₂ hydrocarbylene group, a phenylene group, or a C₇-C₁₈ group obtained by combining the foregoing, which may contain a carbonyl group, a nitro group, a cyano group, an ester bond, an ether bond, a urethane bond, a fluorine atom, an iodine atom, or a bromine atom,
X³ is a single bond, a methylene group, or an ethylene group,
X⁴ is a single bond, a methylene group, an ethylene group, a phenylene group, a methylphenylene group, a dimethylphenylene group, a fluorinated phenylene group, a phenylene group substituted by a trifluoromethyl group, —O—X⁴¹—, —C(═O)—O—X⁴¹—, or —C(═O)—NH—X⁴¹— wherein X⁴¹ is a C₁-C₆ aliphatic hydrocarbylene group, a phenylene group, a methylphenylene group, a dimethylphenylene group, a fluorinated phenylene group, or a phenylene group substituted by a trifluoromethyl group, and may contain a carbonyl group, an ester bond, an ether bond, a hydroxy group, or a halogen atom,
Rf¹ to Rf⁴ are each independently a hydrogen atom, a fluorine atom, or a trifluoromethyl group, at least one of Rf¹ to Rf⁴ is a fluorine atom or a trifluoromethyl group, and Rf¹ and Rf² may together form a carbonyl group, and
M⁺ is a sulfonium cation having formula (1).

3. The resist composition of claim 1 wherein the base polymer further comprises repeat units having formula (b1) or repeat units having formula (b2): 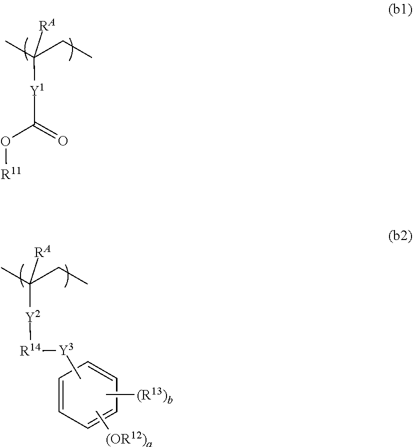
wherein R^{A} is each independently a hydrogen atom or a methyl group,
Y¹ is a single bond, a phenylene group, a naphthylene group, or a C₁-C₁₂ linking group containing at least one moiety selected from an ester bond, an ether bond, and a lactone ring,
Y² is a single bond or an ester bond,
Y³ is a single bond, an ether bond, or an ester bond,
R¹¹ and R¹² are each independently an acid labile group,
R¹³ is a fluorine atom, a trifluoromethyl group, a cyano group, a C₁-C₆ saturated hydrocarbyl group, a C₁-C₆ saturated hydrocarbyloxy group, a C₂-C₇ saturated hydrocarbylcarbonyl group, a C₂-C₇ saturated hydrocarbylcarbonyloxy group, or a C₂-C₇ saturated hydrocarbyloxycarbonyl group,
R¹⁴ is a single bond or a C₁-C₆ alkanediyl group in which some constituent —CH₂— may be substituted by an ether bond or an ester bond, and
a is 1 or 2, and b is an integer of 0 to 4, provided that 1≤a+b≤5.

4. The resist composition of claim 3 which is a chemically amplified positive resist composition.

5. The resist composition of claim 1 further comprising an organic solvent.

6. The resist composition of claim 1 further comprising a surfactant.

7. A pattern forming process comprising the steps of applying the resist composition of claim 1 onto a substrate to form a resist film thereon, exposing the resist film to high-energy radiation, and developing the exposed resist film in a developer.

8. The pattern forming process of claim 7 wherein the high-energy radiation is KrF excimer laser, ArF excimer laser, electron beam, or extreme ultraviolet with a wavelength of 3 to 15 nm.
